(19) United States
(12) Patent Application Publication
(10) Pub. No.: US 2012/0193726 A1
(43) Pub. Date: Aug. 2, 2012

(54) SEMICONDUCTOR DEVICE AND METHOD OF MANUFACTURING THE SAME

(76) Inventors: Tomohiro Yamashita, Kanagawa (JP); Yukio Nishida, Kanagawa (JP); Takashi Hayashi, Kanagawa (JP); Yoshiki Yamamoto, Kanagawa (JP); Masao Inoue, Kanagawa (JP)

(21) Appl. No.: 13/500,863

(22) PCT Filed: Oct. 6, 2009
(86) PCT No.: PCT/JP2009/067421

§ 371 Date: Apr. 6, 2012

(51) Int. Cl. H01L 27/092; H01L 21/8238; H01L 21/336

(52) U.S. Cl. 257/369; 438/301; 438/199; 257/E27.062; 257/E21.409; 257/E21.632

(57) ABSTRACT

A semiconductor device including an n-channel-type MISFET (Qn) having an Hf-containing insulating film (5), which is a high dielectric constant gate insulating film containing hafnium, a rare-earth element, and oxygen as main components, and a gate electrode (GE1), which is a metal gate electrode, is manufactured. The Hf-containing insulating film (5) is formed by forming a first Hf-containing film containing hafnium and oxygen as main components, a rare-earth containing film containing a rare-earth element as a main component, and a second Hf-containing film containing hafnium and oxygen as main components sequentially from below and then causing these to react with one another.

### TECHNICAL FIELD

The present invention relates to a semiconductor device and its manufacturing method, and more particularly to a technology effectively applied to a semiconductor device including a MISFET having a high dielectric constant gate insulating film and a metal gate electrode and its manufacturing technology.

### BACKGROUND ART

A MISFET (Metal Insulator Semiconductor Field Effect Transistor) can be formed by forming a gate insulating film on a semiconductor substrate, forming a gate electrode on the gate insulating film, and forming source and drain regions by ion implantation or the like. As a gate electrode, a polysilicon film is used in general.

In recent years, however, the thickness of the gate insulating film has been reduced with the microfabrication of MISFET elements, and an influence of depletion of the gate electrode when a polysilicon film is used as the gate electrode has become more and more unignorable. To get around this, there is a technology of suppressing a depletion phenomenon of the gate electrode by using a metal gate electrode as the gate electrode.

Also, when the thickness of the gate insulating film has been reduced with the microfabrication of MISFET elements, if a thin silicon oxide film is used as a gate insulating film, a so-called tunnel current occurs, that is, electrons flowing through a channel of the MISFET tunnel through a barrier formed by the silicon oxide film to flow to the gate electrode. To get around this, there is a technology of reducing a leakage current by using a material with a dielectric constant higher than that of the silicon oxide film (high dielectric constant material) as a gate insulating film to increase a physical film thickness without changing the capacity.

Japanese Unexamined Patent Application Publication No. 2005-191341 (Patent Document 1) describes a technology of forming a high dielectric constant insulating film having a stacked structure by stacking an AlO film, an HfAlO film, and an AlO film. Japanese Unexamined Patent Application Publication No. 2005-191341 (Patent Document 1) also describes a high dielectric constant insulating film formed by stacking an AlO film, an LaO film, and an AlO film. In Japanese Unexamined Patent Application Publication No. 2005-191341 (Patent Document 1), Al and oxygen are taken as main components of a high dielectric constant insulating film, but the application thereof as a high dielectric constant gate insulating film for a 32-22 nm node has problems because a leakage current increases too much.

Japanese Unexamined Patent Application Publication No. 2003-8005 (Patent Document 2) describes a structure in which a Si nitride film is present at an interface between a High-k film and a Si substrate and a CVD-HfO₂ film containing nitrogen is present at an interface between the High-k film and a TiN/Al metal gate film.

### PRIOR ART DOCUMENTS

### Patent Documents

Patent Document 1: Japanese Unexamined Patent Application Publication No. 2005-191341
Patent Document 2: Japanese Unexamined Patent Application Publication No. 2003-8005

### SUMMARY OF THE INVENTION

### Problems to be Solved by the Invention

According to studies by the inventors of the present invention, the following has been found.

When a metal gate electrode is used, a problem of depletion of the gate electrode can be solved, but the absolute value of a threshold voltage (threshold) of the MISFET is increased compared with the case in which a polysilicon gate electrode is used, and in the case of a CMISFET, the absolute values of the threshold voltages in both of the n-channel-type MISFET and the p-channel-type MISFET are increased. For this reason, a decrease in threshold (decrease of the absolute value of the threshold voltage) is desired when a metal gate electrode is used.

As a high dielectric constant film (High-k film) for a gate insulating film, an Hf-based gate insulating film, which is a high dielectric constant film containing Hf, is excellent. If a rare-earth element (particularly preferably, lanthanum) is introduced to the Hf-based gate insulating film in the n-channel-type MISFET, the threshold of the n-channel-type MISFET can be decreased. Also, if aluminum is introduced to the Hf-based gate insulating film in a p-channel-type MISFET, the threshold of the p-channel-type MISFET can be decreased.

However, when a rare-earth element is introduced to an Hf-based gate insulating film, this rare-earth element tends to be diffused to a metal gate electrode and a semiconductor substrate side, and therefore various inconveniences may possibly occur. For example, if the rare-earth element is diffused into the metal gate electrode, the effective work function of the metal gate electrode is changed. As a result, the threshold of the n-channel-type MISFET is shifted from a designed value (desired value), which invites the variations (fluctuations) of the threshold and the decrease in performance of the semiconductor device having the MISFET. Also, since the rare-earth element has a high reactivity and also tends to be crystallized, if a rare-earth element is present at an interface between the Hf-based gate insulating film and the metal gate electrode with a high concentration, an oxidizer such as oxygen, moisture, or an OH radical tends to be immersed from a side surface of the gate electrode through the interface between the Hf-based gate insulating film and the metal gate electrode, which invites the oxidization of the metal gate electrode. If the metal gate electrode is oxidized, since the effective work function of the metal gate electrode is changed, the threshold of the n-channel-type MISFET is shifted from a designed value (desired value), which invites the variations (fluctuations) of the threshold and the decrease in performance of the semiconductor device having the MISFET. On the other hand, if the rare-earth element is diffused into the semiconductor substrate, for example, the mobility of a channel is decreased and the characteristics of the MISFET are degraded, which invites the decrease in performance of the semiconductor device having the MISFET. For this reason, in order to further improve the performance of a semiconductor device including a MISFET having a high dielectric constant gate insulating film and a metal gate electrode, it is desired to suppress these inconveniences due to the diffusion of the rare-earth element to the metal gate electrode and the semiconductor substrate side.

An object of the present invention is to provide a technology capable of achieving an improvement in performance of a semiconductor device including a MISFET having a high dielectric constant gate insulating film and a metal gate electrode.

The above and other objects and novel characteristics of the present invention will be apparent from the description of the present specification and the accompanying drawings.

### Means for Solving the Problems

The following is a brief description of an outline of the typical invention disclosed in the present application.

A semiconductor device according to a typical embodiment is a semiconductor device including an n-channel-type MISFET having a gate insulating film containing hafnium, a rare-earth element, and oxygen as main components and a metal gate electrode, and in a concentration distribution of the rare-earth element in a thickness direction of the gate insulating film, the concentration of the rare-earth element near a lower surface and an upper surface of the gate insulating film is lower than a concentration in a center region of the gate insulating film.

Also, a method of manufacturing a semiconductor device according to a typical embodiment is a method of manufacturing a semiconductor device including an n-channel-type MISFET having a gate insulating film containing hafnium, a rare-earth element, and oxygen as main components and a metal gate electrode. In this method, the gate insulating film is formed by sequentially forming a first Hf-containing film containing hafnium and oxygen as main components, a rare-earth-containing film containing a rare-earth element as a main component, and a second Hf-containing film containing hafnium and oxygen as main components from below and then causing them to react with each other.

### Effects of the Invention

The effects obtained by typical embodiments of the invention disclosed in the present application will be briefly described below.

According to a typical embodiment, the performance of the semiconductor device can be improved.

### BRIEF DESCRIPTIONS OF THE DRAWINGS

FIG. 1 is a sectional view of main parts of a semiconductor device of an embodiment of the present invention;

FIG. 2 is a manufacturing process flow diagram showing part of a manufacturing process of the semiconductor device of the embodiment of the present invention;

FIG. 3 is a sectional view of main parts of the semiconductor device of the embodiment of the present invention in a manufacturing process;

FIG. 4 is a sectional view of main parts of the semiconductor device in the manufacturing process continued from FIG. 3;

FIG. 5 is a sectional view of main parts of the semiconductor device in the manufacturing process continued from FIG. 4;

FIG. 6 is a sectional view of main parts of the semiconductor device in the manufacturing process continued from FIG. 5;

FIG. 7 is a sectional view of main parts of the semiconductor device in the manufacturing process continued from FIG. 6;

FIG. 8 is a sectional view of main parts of the semiconductor device in the manufacturing process continued from FIG. 7;

FIG. 9 is a sectional view of main parts of the semiconductor device in the manufacturing process continued from FIG. 8;

FIG. 10 is a sectional view of main parts of the semiconductor device in the manufacturing process continued from FIG. 9;

FIG. 11 is a sectional view of main parts of the semiconductor device in the manufacturing process continued from FIG. 10;

FIG. 12 is a sectional view of main parts of the semiconductor device in the manufacturing process continued from FIG. 11;

FIG. 13 is a sectional view of main parts of the semiconductor device in the manufacturing process continued from FIG. 12;

FIG. 14 is a sectional view of main parts of the semiconductor device in the manufacturing process continued from FIG. 13;

FIG. 15 is a sectional view of main parts of the semiconductor device in the manufacturing process continued from FIG. 14;

FIG. 16 is a sectional view of main parts of the semiconductor device in the manufacturing process continued from FIG. 15;

FIG. 17 is a manufacturing process flow diagram showing part of another manufacturing process of a semiconductor device of an embodiment of the present invention;

FIG. 18 is a sectional view of main parts of the semiconductor device in the manufacturing process continued from FIG. 6;

FIG. 19 is a sectional view of main parts of the semiconductor device in the manufacturing process continued from FIG. 18;

FIG. 20 is a sectional view of main parts of the semiconductor device in the manufacturing process continued from FIG. 19;

FIG. 21 is a sectional view of main parts of the semiconductor device in the manufacturing process continued from FIG. 20;

FIG. 22 is a sectional view of main parts of the semiconductor device in the manufacturing process continued from FIG. 21;

FIG. 23 is an explanatory diagram of an n-channel-type MISFET of the semiconductor device of FIG. 1;

FIG. 24 is a graph showing a rare-earth concentration distribution of an Hf-containing film, a rare-earth-containing film, and an Hf-containing film in a thickness direction before reaction;

FIG. 25 is a graph showing a Hf concentration distribution of an Hf-containing film, a rare-earth-containing film, and an Hf-containing film in a thickness direction before reaction;

FIG. 26 is a graph showing a rare-earth concentration distribution and an Hf concentration distribution in a thickness direction near a gate insulating film of a p-channel-type MISFET of the semiconductor device of FIG. 1;

FIG. 27 is an explanatory diagram of a semiconductor device of an embodiment of the present invention;

FIG. 28 is an explanatory diagram of a semiconductor device of a first comparative example;

FIG. 29 is an explanatory diagram of a semiconductor device of a second comparative example;

FIG. 30 is a graph showing narrow channel characteristics of an n-channel-type MISFET;

FIG. 31 is an explanatory diagram of a gate width;

FIG. 32 is a sectional view of main parts of a semiconductor device of another embodiment of the present invention;

FIG. 33 is a manufacturing process flow diagram showing part of a manufacturing process of the semiconductor device of the embodiment of the present invention;

FIG. 34 is a sectional view of main parts of the semiconductor device of the embodiment of the present invention in the manufacturing process;

FIG. 35 is a sectional view of main parts of the semiconductor device in the manufacturing process continued from FIG. 34;

FIG. 36 is a sectional view of main parts of the semiconductor device in the manufacturing process continued from FIG. 35;

FIG. 37 is a sectional view of main parts of the semiconductor device in the manufacturing process continued from FIG. 36;

FIG. 38 is a sectional view of main parts of the semiconductor device in the manufacturing process continued from FIG. 37;

FIG. 39 is a sectional view of main parts of the semiconductor device in the manufacturing process continued from FIG. 38;

FIG. 40 is a sectional view of main parts of the semiconductor device in the manufacturing process continued from FIG. 39;

FIG. 41 is a sectional view of main parts of the semiconductor device in the manufacturing process continued from FIG. 40;

FIG. 42 is a sectional view of main parts of the semiconductor device in the manufacturing process continued from FIG. 41;

FIG. 43 is a sectional view of main parts of the semiconductor device in the manufacturing process continued from FIG. 42;

FIG. 44 is a sectional view of main parts of the semiconductor device in the manufacturing process continued from FIG. 43;

FIG. 45 is a sectional view of main parts of the semiconductor device in the manufacturing process continued from FIG. 44;

FIG. 46 is a sectional view of main parts of the semiconductor device in the manufacturing process continued from FIG. 45;

FIG. 47 is a sectional view of main parts of the semiconductor device in the manufacturing process continued from FIG. 46;

FIG. 48 is a sectional view of main parts of the semiconductor device in the manufacturing process continued from FIG. 47;

FIG. 49 is an explanatory diagram of a p-channel-type MISFET of the semiconductor device of FIG. 32;

FIG. 50 is a graph showing an Al concentration distribution and an Hf concentration distribution in a thickness direction near a gate insulating film of the p-channel-type MISFET of the semiconductor device of FIG. 32;

FIG. 51 is a sectional view of main parts of the semiconductor device of FIG. 32 in another manufacturing process;

FIG. 52 is a sectional view of main parts of the semiconductor device in the manufacturing process continued from FIG. 51;

FIG. 53 is a sectional view of main parts of the semiconductor device in the manufacturing process continued from FIG. 52;

FIG. 54 is a sectional view of main parts of the semiconductor device in the manufacturing process continued from FIG. 53; and

FIG. 55 is a sectional view of main parts of the semiconductor device in the manufacturing process continued from FIG. 54.

### BEST MODE FOR CARRYING OUT THE INVENTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference symbols throughout the drawings for describing the embodiments, and the repetitive description thereof will be omitted.

Also, in some drawings used in the embodiments, hatching is omitted even in a sectional view so as to make the drawings easy to see. On the other hand, hatching is used even in a plan view so as to make the drawings easy to see.

### First Embodiment

A semiconductor device of the present embodiment is described with reference to the drawings.

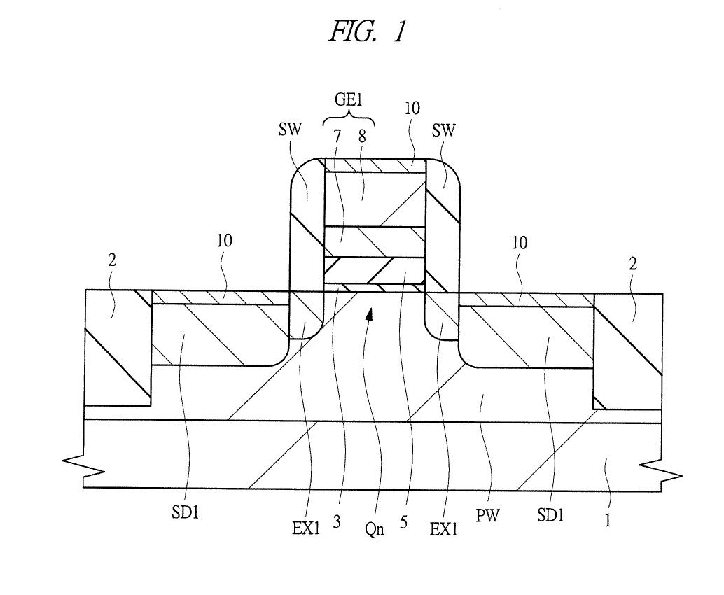

FIG. 1 is a sectional view of main parts of a semiconductor device of an embodiment of the present invention, here, a semiconductor device having an n-channel-type MISFET.

As shown in FIG. 1, the semiconductor device of the present embodiment has an n-channel-type MISFET (Metal Insulator Semiconductor Field Effect Transistor: MIS-type field effect transistor) Qn formed on a semiconductor substrate 1.

More specifically, the semiconductor substrate 1 made of p-type single crystal silicon or the like has an active region defined by isolation regions 2, and a p-type well PW is formed in this active region. On a surface of the p-type well PW, a gate electrode (metal gate electrode) GE1 of an n-channel-type MISFET Qn is formed via an Hf-containing insulating film (first gate insulating film) 5 functioning as a gate insulating film of the n-channel-type MISFET Qn.

The Hf-containing insulating film 5 can be formed directly on a surface (silicon surface) of the semiconductor substrate 1 (p-type well PW) (that is, an interface layer 3 can be omitted), but it is more preferable to provide the insulating interface layer (insulating layer, insulating film) 3 formed of a thin silicon oxide film or silicon oxynitride film at an interface between the Hf-containing insulating film 5 and the semiconductor substrate 1 (p-type well PW). By providing the interface layer 3 made of silicon oxide or silicon oxynitride between the Hf-containing insulating film 5 and the semiconductor substrate 1 (p-type well PW), an interface between the gate insulating film and (the silicon surface of) the semiconductor substrate is configured to have a SiO₂/Si (or SiON/Si) structure, and the number of defects such as traps can be decreased to improve driving capability and reliability.

The Hf-containing insulating film 5 is an insulating material film with a dielectric constant (relative permittivity) higher than that of silicon oxide, that is, a so-called High-k film (high dielectric constant film). Note that, when the High-k film, the high dielectric constant film, or a high dielectric constant gate insulating film is mentioned in the present application, it means a film with a dielectric constant (relative permittivity) higher than that of silicon oxide (SiOₓ, typically SiO₂).

The Hf-containing insulating film 5 functioning as a gate insulating film (high dielectric constant gate insulating film) of the n-channel-type MISFET Qn has a feature of being made of an insulating material containing Hf (hafnium) and O (oxygen) as main components and further containing a rare-earth element (particularly preferably, La (lanthanum)). This Hf-containing insulating film 5 contains Hf (hafnium), O (oxygen), and a rare-earth element as essential constituent elements, and it can further contain one or both of N (nitrogen) and Si (silicon) other than those. The reason why the Hf-containing insulating film 5 contains a rare-earth element is to decrease the threshold of the n-channel-type MISFET Qn. Note that decreasing the threshold of the MISFET corresponds to decreasing (lowering) the absolute value of the threshold (threshold voltage) of that MISFET.

Note that a rare earth or a rare-earth element in the present application refers to those obtained by adding scandium (Sc) and yttrium (Y) to lanthanoids from lanthanum (La) to lutetium (Lu). Also, in the present application, a gate insulating film containing Hf may be referred to as an Hf-based gate insulating film.

Therefore, when the rare-earth element contained in the Hf-containing insulating film 5 is represented as Ln, an HfLnO film, an HfLnON film, an HfLnSiON film, or an HfLnSiO film can be suitably used as the Hf-containing insulating film 5. Also, La (lanthanum) is particularly preferable as a rare-earth element contained in the Hf-containing insulating film 5 to decrease the threshold of the n-channel-type MISFET Qn. Therefore, the Hf-containing insulating film 5 is particularly preferably an HfLaO film, an HfLaON film, an HfLaSiON film, or an HfLaSiO film.

Here, the HfLnO film is an insulating material film made of hafnium (Hf), the rare-earth element (Ln), and oxygen (O), and the HfLnON film is an insulating material film made of hafnium (Hf), the rare-earth element (Ln), oxygen (O), and nitrogen (N). Also, the HfLnSiON film is an insulating material film made of hafnium (Hf), the rare-earth element (Ln), silicon (Si), oxygen (O), and nitrogen (N), and the HfLnSiO film is an insulating material film made of hafnium (Hf), the rare-earth element (Ln), silicon (Si), and oxygen (O). Also, the HfLaO film is an insulating material film made of hafnium (Hf), lanthanum (La), and oxygen (O), and the HfLaON film is an insulating material film made of hafnium (Hf), lanthanum (La), oxygen (O), and nitrogen (N). Also, the HfLaSiON film is an insulating material film made of hafnium (Hf), lanthanum (La), silicon (Si), oxygen (O), and nitrogen (N), and the HfLaSiO film is an insulating material film made of hafnium (Hf), lanthanum (La), silicon (Si), and oxygen (O).

Note that when a film is represented as an HfLaSiON film, the atomic ratio among Hf, La, Si, O, and N in the HfLaSiON film is not limited to 1:1:1:1:1. The same goes for an HfLnO film, an HfLnON film, an HfLnSiON film, an HfLnSiO film, an HfLaO film, an HfLaON film, an HfLaSiON film, an HfLaSiO film, an HfO film, an HfON film, an HfSiON film, an HfSiO film, an HfAlO film, an HfAlON film, an HfAlSiON film, an HfAlSiO film, and others.

The gate electrode GE1 is configured of a stacked film (stacked structure) of a metal film (metal gate film, metal layer) 7 formed on the Hf-containing insulating film 5 and being in contact with the Hf-containing insulating film 5 and a silicon film 8 on this metal film 7. The gate electrode GE1 has the metal film 7 in contact with the Hf-containing insulating film 5, which is a gate insulating film (high dielectric constant gate insulating film), and is a so-called metal gate electrode.

Note that the metal film (the metal layer) in the present application refers to a conductive film (conductive layer) showing metal conductivity, and is assumed to include not only a single metal film (pure metal film) and an alloy film but also a metal compound film (such as metal nitride film and metal carbide film) showing metal conductivity. Therefore, the metal film 7 is a conductive film showing metal conductivity and has a resistivity as low as metal. A particularly preferable film as the metal film 7 is a titanium nitride (TiN) film, a tantalum nitride (TaN) film, a tungsten nitride (WN) film, a titanium carbide (TiC) film, a tantalum carbide (TaC) film, or a tungsten carbide (WC) film.

The Hf-containing insulating film 5, which is an Hf-based gate insulating film, contains a rare-earth element, but the concentration (content) of the rare-earth element of the Hf-containing insulating film 5 is not uniform (constant) in a film thickness direction of the Hf-containing insulating film 5. The concentration (content) of the rare-earth element is low in a region on a semiconductor substrate 1 side (that is, region in contact with the interface layer 3) and a region on a gate electrode GE1 side (that is, region in contact with the metal film 7), and the concentration (content) of the rare-earth element is high in a center region (center part) in the film thickness direction. This will be described below in more detail.

In the p-type well PW, as source and drain regions with an LDD (Lightly doped Drain) structure of the n-channel-type MISFET Qn, n⁻-type semiconductor regions (extension region, LDD region) EX1 and n⁺-type semiconductor regions (source and drain regions) SD1 with a higher impurity concentration are formed. The n⁺-type semiconductor region SD1 has an impurity concentration higher than that of the n⁻-type semiconductor region EX1, and has a junction depth deeper than that of the n⁻-type semiconductor region EX1.

On a sidewall of the gate electrode GE1, a sidewall (sidewall spacer, sidewall insulating film) SW made of an insulator is formed. The n⁻-type semiconductor region EX1 is formed so as to be aligned with the gate electrode GE1, and the n⁺-type semiconductor region SD1 is formed so as to be aligned with the sidewall SW provided on the sidewall of the gate electrode GE1. More specifically, the n⁻-type semiconductor region EX1 is positioned under the sidewall SW formed on the sidewall of the gate electrode GE1 and is interposed between a channel region of the n-channel-type MISFET Qn and the n⁺-type semiconductor region SD1.

On the surfaces of the n⁺-type semiconductor regions SD1 and the silicon film 8, a metal silicide layer (metal silicide film) 10 is formed. The metal silicide layer 10 is made of silicide, for example, Co (cobalt), Ni (nickel), or Pt (platinum), and can be formed by a salicide process. Although the formation of the metal silicide layer 10 can be omitted, if the metal silicide layer 10 is formed on the surfaces of the n⁺-type semiconductor region SD1 and the silicon film 8, diffusion resistance and contact resistance can be reduced. When the metal silicide layer 10 is formed on the surface of the silicon film 8, it can be regarded that the metal silicide layer 10 is formed on the gate electrode GE1 formed of a stacked film of the metal film 7 and the silicon film 8 on the metal film 7, and it can also be regarded that the gate electrode GE1 is configured of a stacked film (stacked structure) of the metal film 7, the silicon film 8 on the metal film 7, and the metal silicide layer 10 on the silicon film 8 by including the metal silicide layer 10 into the gate electrode GE1.

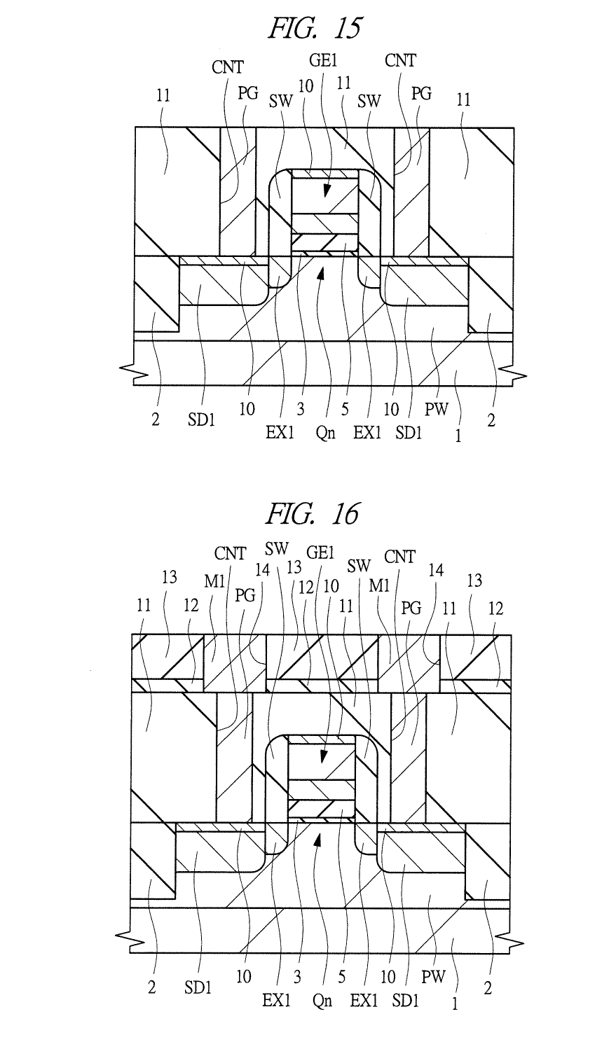

Furthermore, although an insulating film (interlayer insulating film) 11, a contact hole CNT, a plug PG, a stopper insulating film 12, an insulating film 13 and a wiring M1 (refer to FIG. 15 and FIG. 16 described below) described below and further a multilayer wiring structure of an upper layer are formed, the illustration and the description thereof are omitted here.

Next, a process of manufacturing the semiconductor device of the present embodiment as shown in FIG. 1 is described with reference to the drawings.

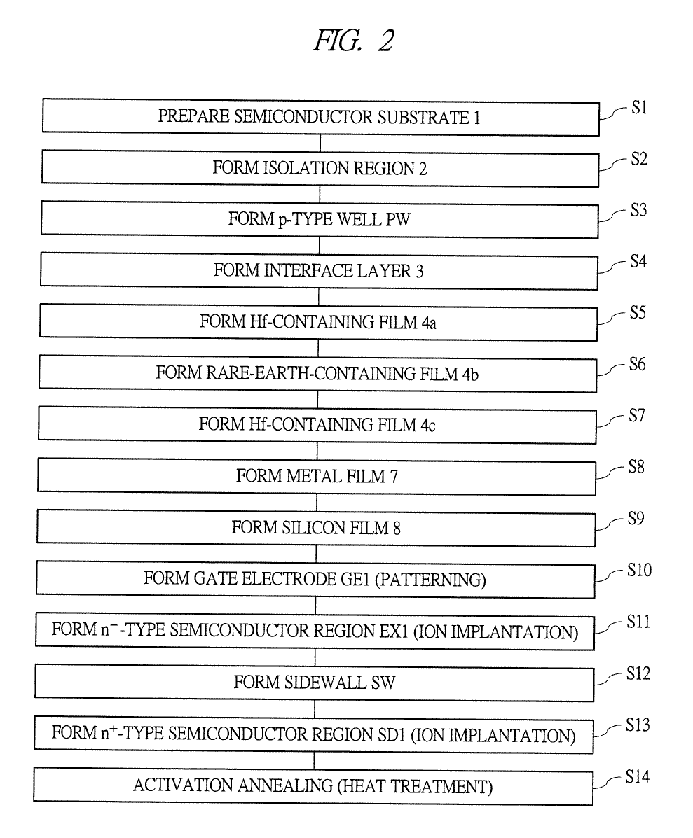

FIG. 2 is a manufacturing process flow diagram showing part of the process of manufacturing the semiconductor device of the present embodiment, here, a semiconductor device having an n-channel-type MISFET. FIG. 3 to FIG. 16 are sectional views of main parts in a manufacturing process of the semiconductor device of the present embodiment, here, a semiconductor device having an n-channel-type MISFET.

First, as shown in FIG. 3, the semiconductor substrate (semiconductor wafer) 1 made of, for example, p-type single crystal silicon or the like having a specific resistance of about 1 to 10 Ωcm is prepared (made available) (step S1 of FIG. 2). Then, the isolation regions 2 are formed on a main surface of the semiconductor substrate 1 (step S2 of FIG. 2). The isolation region 2 is made of an insulator such as silicon oxide, and is formed by, for example, a STI (Shallow Trench Isolation) method. For example, the isolation region 2 can be formed of an insulating film buried in a trench (isolation trench) formed in the semiconductor substrate 1.

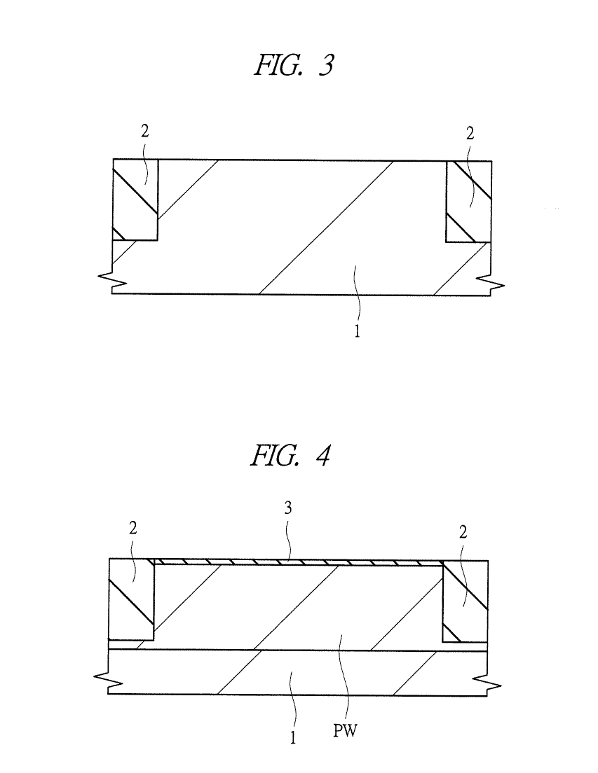

Next, as shown in FIG. 4, the p-type well PW is formed in a region where the n-channel-type MISFET of the semiconductor substrate 1 is to be formed (step S3 of FIG. 2). In this step S3, the p-type well PW is formed by, for example, ion implantation of p-type impurities such as boron (B). Also, before or after forming the p-type well PW, ion implantation (so-called channel-dope ion implantation) for adjusting the threshold of the MISFET to be formed later can be performed if necessary on an upper layer part of the semiconductor substrate 1.

Next, a surface of the semiconductor substrate 1 is purified (cleaned) by removing a natural oxide film on the surface of the semiconductor substrate 1 by wet etching using, for example, hydrofluoric acid (HF) solution, or the like. By this means, the surface (silicon surface) of the semiconductor substrate 1 (p-type well PW) is exposed.

Next, on the surface of the semiconductor substrate 1 (that is, the surface of the p-type well PW), the interface layer (insulating layer, insulating film) 3 made of a silicon oxide film or a silicon oxynitride film is formed (step S4 of FIG. 2).

It is also possible to form an Hf-containing film 4a, which will be described below, directly on the surface (silicon surface) of the semiconductor substrate 1 (p-type well PW) without forming the interface layer 3 by omitting the step S4. However, it is more preferable to form the interface layer 3 in step S4 and then form the Hf-containing film 4a, which will be described below, on this interface layer 3 because the number of defects such as traps can be decreased to improve driving capability and reliability. When the interface layer 3 is formed, the interface layer 3 can be made to have a small film thickness, and it is preferably 0.3 nm to 1 nm, for example, about 0.6 nm. In step S4, the interface layer 3 can be formed by using, for example, a thermal oxidization method.

Next, as shown in FIG. 5, the Hf-containing film (Hf-containing layer, first Hf-containing film) 4a is formed on the main surface of the semiconductor substrate 1, that is, on the interface layer 3 (step S5 of FIG. 2). This Hf-containing film 4a, a rare-earth-containing film 4b and an Hf-containing film 4c described below are films for forming the above-described Hf-containing insulating film 5, which is a high dielectric constant gate insulating film.

The Hf-containing film 4a is made of an insulating material containing hafnium (Hf) and oxygen (O), and can preferably be an HfO film (hafnium oxide film, typically, HfO₂ film), an HfON film (hafnium oxynitride film), an HfSiON film (hafnium silicon oxynitride film), or an HfSiO film (hafnium silicate film). Among these, if an HfON film is used as the Hf-containing film 4a, further increase in heat resistance and decrease in leakage current can be achieved. Therefore, the Hf-containing film 4a can be regarded as an insulating film containing hafnium (Hf) and oxygen (O) as main components. The Hf-containing film 4a preferably does not contain a rare-earth element. The film thickness (formed film thickness) of the Hf-containing film 4a can be set, preferably, within a range of 0.3 nm to 1.5 nm, for example, to about 0.8 nm.

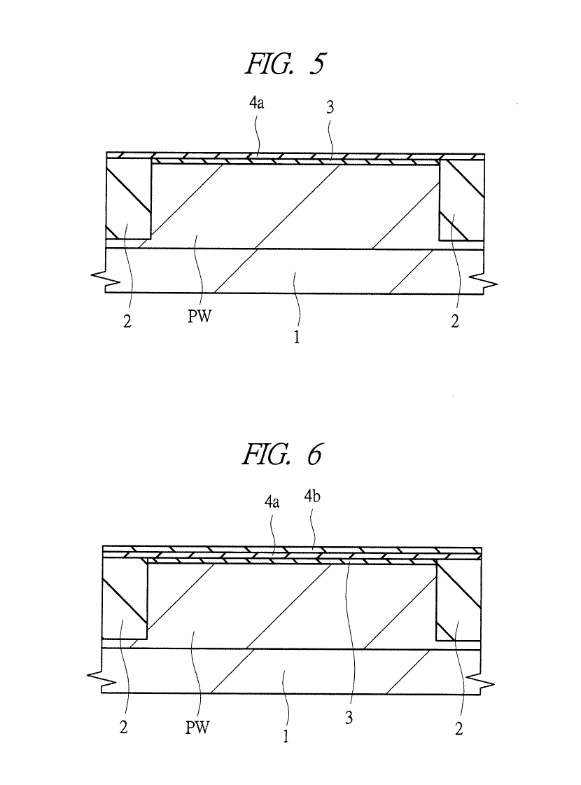

Next, as shown in FIG. 6, the rare-earth-containing film (rare-earth-containing layer) 4b is formed on the main surface of the semiconductor substrate 1, that is, on the Hf-containing film 4a (step S6 of FIG. 2). The rare-earth-containing film 4b contains a rare-earth element as a main component, and particularly preferably contains La (lanthanum). In view of stability, the rare-earth-containing film 4b is preferably a rare-earth oxide film (rare-earth oxide layer), and is particularly preferably a lanthanum oxide film (La₂O₃ is typical as lanthanum oxide). The rare-earth-containing film 4b does not contain Hf (hafnium). The rare-earth-containing film 4b can be formed by a sputtering method, an ALD (Atomic Layer Deposition) method, or the like, and the film thickness thereof (formed film thickness) can be set, preferably, within a range of 0.2 nm to 1 nm, for example, to about 0.4 nm.

Next, as shown in FIG. 7, the Hf-containing film (Hf-containing layer, second Hf-containing film) 4c is formed on the main surface of the semiconductor substrate 1, that is, on the rare-earth-containing film 4b (step S7 of FIG. 2). The Hf-containing film 4c is made of an insulating material containing hafnium (Hf) and oxygen (O), and can preferably be an HfO film (hafnium oxide film, typically, HfO₂ film), an HfON film (hafnium oxynitride film), an HfSiON film (hafnium silicon oxynitride film), or an HfSiO film (hafnium silicate film). Among these, if an HfON film is used as the Hf-containing film 4c, further increase in heat resistance and decrease in leakage current can be achieved. Therefore, the Hf-containing film 4c can be regarded as an insulating film containing hafnium (Hf) and oxygen (O) as main components. The Hf-containing film 4c preferably does not contain a rare-earth element. The film thickness (formed film thickness) of the Hf-containing film 4c can be set, preferably, within a range of 0.5 nm to 2 nm, for example, to about 1.2 nm, but it is preferably thicker than the film thickness (formed film thickness) of the Hf-containing film 4a.

For example, the process of forming the Hf-containing film 4a in step S5 and the process of forming the Hf-containing film 4c in step S7 can be performed in the following manner.

In the case of an HfSiON film, an HfSiO film is first deposited by using an ALD method or a CVD (Chemical Vapor Deposition) method, and then this HfSiO film is nitrided by a nitriding process such as a plasma nitriding process (that is, the HfSiO film is nitrided to be an HfSiON film), thereby forming an HfSiON film. After this nitriding process, the film may be subjected to a heat treatment in an inactive or oxidizing atmosphere.

In the case of an HfON film, an HfO film (typically, HfO₂ film) is first deposited by using an ALD method or a CVD method, and then this HfO film is nitrided by a nitriding process such as a plasma nitriding process (that is, the HfO film is nitrided to be an HfON film), thereby forming an HfON film. After this nitriding process, the film may be subjected to a heat treatment in an inactive or oxidizing atmosphere.

In the case of an HfO film (typically, HfO₂ film), all what is required to do is to deposit an HfO film (typically, HfO₂ film) by using an ALD method or a CVD method, and no nitriding process is required.

In the case of an HfSiO film, all what is required to do is to deposit an HfSiO film by using an ALD method or a CVD method, and no nitriding process is required.

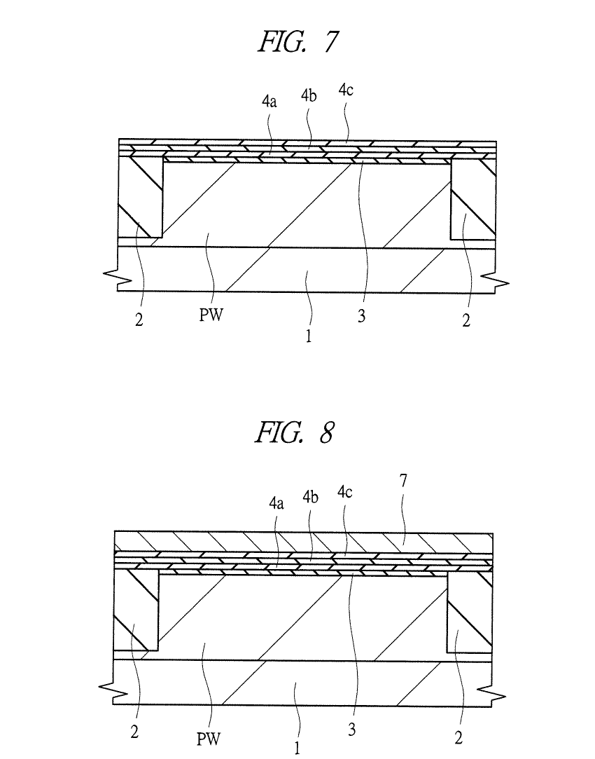

After the Hf-containing film 4c is formed in step S7, as shown in FIG. 8, the metal film (metal layer, metal gate layer) 7 for a metal gate (metal gate electrode) is formed on the main surface of the semiconductor substrate 1, that is, on the Hf-containing film 4c (step S8 of FIG. 2). The metal film 7 is preferably a titanium nitride (TiN) film, a tantalum nitride (TaN) film, a tungsten nitride (WN) film, a titanium carbide (TiC) film, a tantalum carbide (TaC) film, or a tungsten carbide (WC) film. The metal film 7 can be formed by, for example a sputtering method. The film thickness (formed film thickness) of the metal film 7 can be set to, for example, about 3 nm to 15 nm.

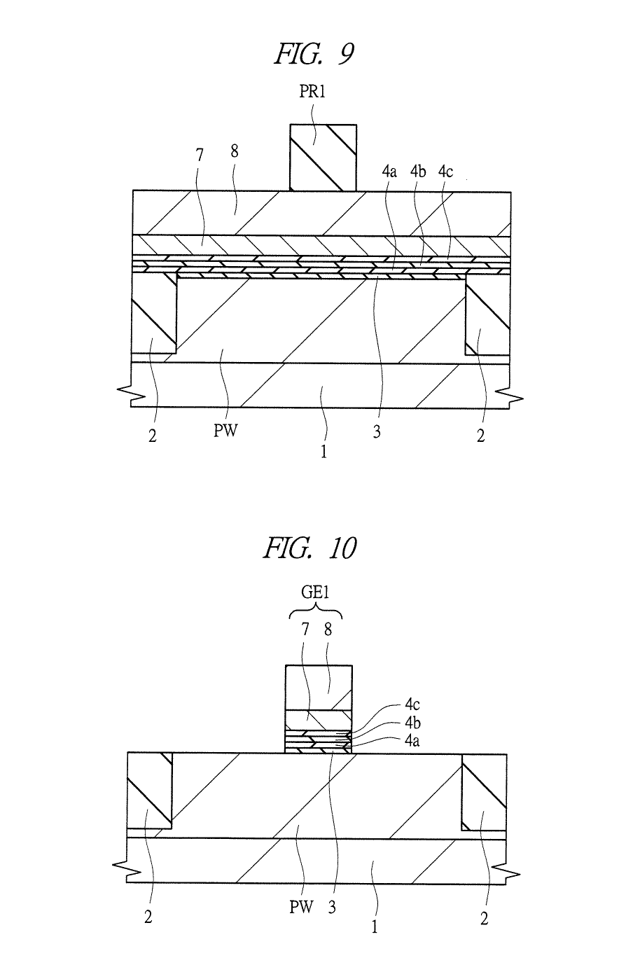

Next, as shown in FIG. 9, the silicon film 8 is formed on the main surface of the semiconductor substrate 1, that is, on the metal film 7 (step S9 of FIG. 2). The silicon film 8 can be a polycrystal silicon film or an amorphous silicon film. Even if the film is an amorphous silicon film at the time of film formation, the film becomes a polycrystal silicon film by a heat treatment (for example, activation annealing process in step S14 described below) after the film formation. The film thickness of the silicon film 8 can be set to, for example, about 100 nm.

Although it is also possible to omit the process of forming the silicon film 8 in step S9 by forming the metal film 7 to have a large thickness in step S8 (that is, the gate electrode GE1 is formed from the metal film 7 without the silicon film 8), it is more preferable to form the silicon film 8 on the metal film 7 in step S9 (that is, to form the gate electrode GE1 from a stacked film of the metal film 7 and the silicon film 8 thereon). The reason for this is that, if the metal film 7 is too thick, a problem in which the metal film 7 tends to be peeled off or a problem of a substrate damage due to overetching at the time of patterning the metal film 7 may possibly arise, but by forming a gate electrode from a stacked film of the metal film 7 and the silicon film 8, the thickness of the metal film 7 can be reduced compared with the case of forming a gate electrode only from the metal film 7, and therefore the problems described above can be solved. Also, when the silicon film 8 is formed on the metal film 7, a conventional method and process of processing a polysilicon gate electrode (gate electrode made of polysilicon) can be used, and therefore this is advantageous also in view of microfabrication capabilities, manufacturing cost, and yields.

Through the processes so far, the state is such that the interface layer 3, the Hf-containing film 4a, the rare-earth-containing film 4b, the Hf-containing film 4c, the metal film 7, and the silicon film 8 are stacked sequentially from below on the semiconductor substrate 1 (p-type well PW).

Next, as shown in FIG. 9, a photoresist pattern PR1 is formed on the silicon film 8 by using a photolithography method. Then, with using this photoresist pattern PR1 as an etching mask, the stacked film of the silicon film 8 and the metal film 7 is patterned by etching (preferably, dry etching), thereby forming the gate electrode GE1 formed of the metal film 7 and the silicon film 8 on the metal film 7 as shown in FIG. 10 (step S10 of FIG. 2). Thereafter, the photoresist pattern PR1 is removed. FIG. 10 shows the state in which the photoresist pattern PR1 has been removed.

The gate electrode GE1 is formed on the Hf-containing film 4c. More specifically, the gate electrode GE1 formed of the metal film 7 and the silicon film 8 on the metal film 7 is formed on the surface of the p-type well PW via a stacked film of the interface layer 3, the Hf-containing film 4a, the rare-earth-containing film 4b, and the Hf-containing film 4c.

It is more preferable to perform the wet etching for removing portions of the Hf-containing film 4c, the rare-earth-containing film 4b, and the Hf-containing film 4a not covered with the gate electrode GE1 after the dry etching process for patterning the silicon film 8 and the metal film 7 in step S10. The Hf-containing film 4c, the rare-earth-containing film 4b, and the Hf-containing film 4a positioned below the gate electrode GE1 are left without being removed by the dry etching in step S10 and following wet etching. On the other hand, the portions of the Hf-containing film 4c, the rare-earth-containing film 4b, and the Hf-containing film 4a not covered with the gate electrode GE1 are removed by the dry etching for patterning the silicon film 8 and the metal film 7 in step S10 and following wet etching.

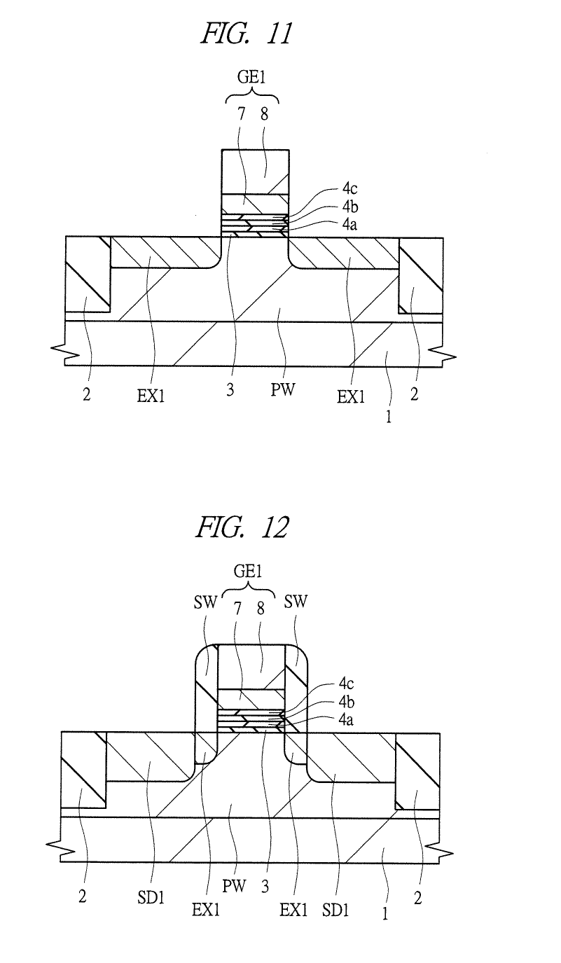

Next, as shown in FIG. 11, the n⁻-type semiconductor regions EX1 are formed on the p-type well PW (step S11 of FIG. 2). The n⁻-type semiconductor regions EX1 can be formed by performing ion implantation of n-type impurities such as phosphorus (P) or arsenic (As) into the regions of the p-type well PW on both sides of the gate electrode GE1 with using the gate electrode GE1 as a mask. Also, ion implantation for forming a halo region can be performed before or after the formation of the n⁻-type semiconductor regions EX1. When a halo region (not shown) is formed, the halo region (p-type halo region) is formed so as to enclose the n⁻-type semiconductor region EX1.

Next, as shown in FIG. 12, the sidewalls (sidewall spacer, sidewall insulating film) SW made of an insulator are formed on the sidewalls of the gate electrode GE1 (step S12 of FIG. 2). For example, a silicon oxide film and a silicon nitride film are formed sequentially from below on the semiconductor substrate 1 so as to cover the gate electrode GE1, and then a stacked film of these silicon oxide film and silicon nitride film is subjected to anisotropic etching (etchback), thereby forming the sidewalls SW made of the silicon oxide film and the silicon nitride film left on the sidewalls of the gate electrode GE1. Note that, for the simplification of the drawings, the silicon oxide film and the silicon nitride film configuring the sidewall SW are integrally shown in FIG. 12.

Next, the n⁺-type semiconductor regions SD1 are formed on the p-type well PW by ion implantation (step S13 of FIG. 2). The n⁺-type semiconductor regions SD1 can be formed by performing ion implantation of n-type impurities such as phosphorous (P) or arsenic (As) into regions of the p-type well PW on both sides of the gate electrode GE1 and the sidewalls SW with using the gate electrode GE1 and the sidewalls SW on its sidewalls as a mask. The n⁺-type semiconductor region SD1 has an impurity concentration higher than that of the n⁻-type semiconductor region EX1, and has a junction depth deeper than that of the n⁻-type semiconductor region EX1. The n⁻-type semiconductor region EX1 is formed so as to be aligned with the gate electrode GE1, and the n⁺-type semiconductor region SD1 is formed so as to be aligned with the sidewall SW. Since the n-type impurities are introduced in the ion implanting process for forming the n⁻-type semiconductor region EX1 and the ion implanting process for forming the n⁺-type semiconductor region SD1, the silicon film 8 configuring the gate electrode GE1 can be an n-type silicon film.

Note that since the n⁺-type semiconductor regions SD1 function as source and drain regions of the n-channel-type MISFET Qn, the process of forming the n⁺-type semiconductor regions SD1 in step S13 can be regarded as a process of performing ion implantation for forming source and drain regions of the n-channel-type MISFET Qn.

After the ion implantation for forming the n⁺-type semiconductor regions SD1 is performed in step S13, heat treatment (annealing process, activation annealing) for activating the introduced impurities is performed (step S14 of FIG. 2). The impurities introduced to the n⁻-type semiconductor regions EX1, n⁺-type semiconductor regions SD1, the silicon film 8, and others in the ion implantation in steps S11 and S13 can be activated by the heat treatment in step S14. The heat treatment in step S14 can be performed at a heat treatment temperature of, for example, 900° C. to 1100° C. and in an inactive gas atmosphere, more preferably, in a nitrogen gas atmosphere.

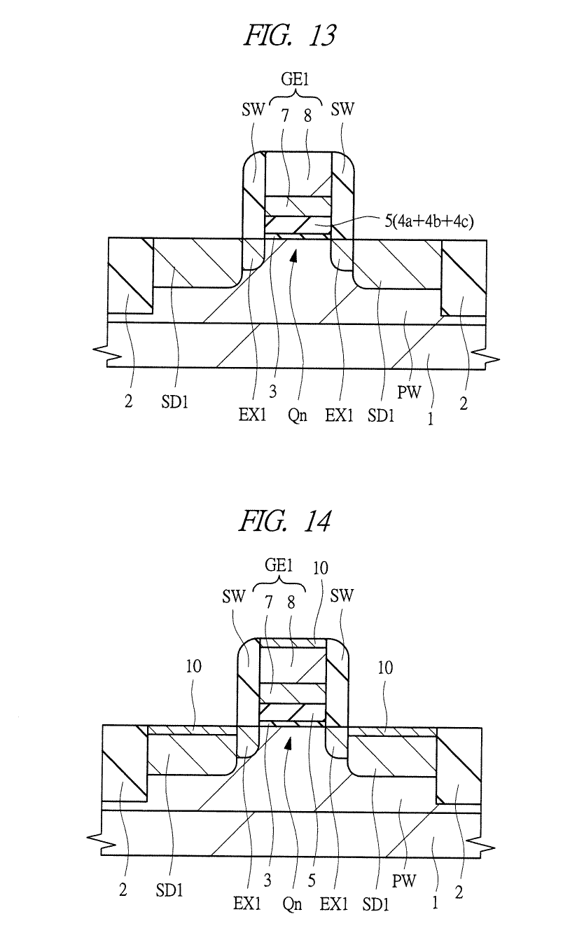

Since the heat treatment in step S14 is performed at a high temperature, the Hf-containing film 4a, the rare-earth-containing film 4b, and the Hf-containing film 4c react (mix, mixing, interdiffuse) with one another. More specifically, the Hf-containing film 4a, the rare-earth-containing film 4b, and the Hf-containing film 4c react (mix, mixing, interdiffuse) with one another to form the Hf-containing insulating film 5 as shown in FIG. 13.

The Hf-containing film 4a and the Hf-containing film 4c contain hafnium (Hf) and oxygen (O) as main components, and the rare-earth-containing film 4b contains a rare-earth element as a main component and is preferably made of rare-earth oxide. Therefore, the Hf-containing insulating film 5 formed by reaction of the Hf-containing film 4a, the rare-earth-containing film 4b, and the Hf-containing film 4c is an insulating film containing hafnium (Hf), oxygen (O), and the rare-earth element as main components. The rare-earth element contained in the Hf-containing insulating film 5 is identical to the rare-earth element contained in the rare-earth-containing film 4b.

Also, when one or both of the Hf-containing film 4a and the Hf-containing film 4c contain not only hafnium (Hf) and oxygen (O) but also nitrogen (N), the Hf-containing insulating film 5 contains not only hafnium (Hf), oxygen (O), and the rare-earth element but also nitrogen (N). Also, when one or both of the Hf-containing film 4a and the Hf-containing film 4c contain not only hafnium (Hf) and oxygen (O) but also Si (silicon), the Hf-containing insulating film 5 contains not only hafnium (Hf), oxygen (O), and the rare-earth element but also Si (silicon).

Also, the rare-earth-containing film 4b is preferably a rare-earth oxide film (particularly preferably, lanthanum oxide film) as described above. In this case, the rare-earth-containing film 4b contains oxygen (O) in addition to the rare-earth element, but since the Hf-containing films 4a and 4c also contain oxygen (O), the Hf-containing insulating film 5 contains oxygen (O) irrespectively of whether the rare-earth-containing film 4b contains oxygen (O). More specifically, although it is preferable that the rare-earth-containing film 4b contains oxygen in addition to the rare-earth element, the Hf-containing insulating film 5 contains oxygen (O) in both of the case in which the rare-earth-containing film 4b contains oxygen (O) and the case in which the rare-earth-containing film 4b does not contain oxygen (O).

Therefore, when the rare-earth-containing film 4b is a rare-earth oxide film and the rare-earth element contained in the rare-earth-containing film 4b is represented as Ln, the Hf-containing insulating film 5 is a film with the following composition depending on the type of the Hf-containing films 4a and 4c. That is, when the Hf-containing films 4a and 4c are both HfO films, the Hf-containing insulating film 5 is an HfLnO film (when Ln=La, an HfLaO film). Also, when one of the Hf-containing films 4a and 4c is an HfO film and the other is an HfON film and when the Hf-containing films 4a and 4c are both HfON films, the Hf-containing insulating film 5 is an HfLnON film (when Ln=La, an HfLaON film). Furthermore, when one of the Hf-containing films 4a and 4c is an HfO film and the other is an HfSiO film and when the Hf-containing films 4a and 4c are both HfSiO films, the Hf-containing insulating film 5 is an HfLnSiO film (when Ln=La, an HfLaSiO film). Still further, when one of the Hf-containing films 4a and 4c is an HfON film and the other is an HfSiO film, the Hf-containing insulating film 5 is an HfLnSiON film (when Ln=La, an HfLaSiON film). Still further, when at least one of the Hf-containing films 4a and 4c is an HfSiON film, even if the other of the Hf-containing films 4a and 4c is an HfO film, an HfON film, an HfSiO film, or an HfSiON film, the Hf-containing insulating film 5 is an HfLnSiON film (when Ln=La, an HfLaSiON film).

In the present embodiment, however, the Hf-containing film 4a, the rare-earth-containing film 4b, and the Hf-containing film 4c are formed sequentially from below, and they react with one another to form the Hf-containing insulating film 5. Also, the Hf-containing films 4a and 4c contain Hf (hafnium) but do not contain a rare-earth element, and the rare-earth-containing film 4b contains a rare-earth element but does not contain Hf (hafnium). For this reason, the composition of the formed Hf-containing insulating film 5 in a film thickness direction is not uniform, and the composition distribution of the Hf-containing film 4a, the rare-earth-containing film 4b, and the Hf-containing film 4c before reaction is maintained to some degree. This will be described below in more detail.

In this manner, the structure as shown in FIG. 13 is obtained, and the n-channel-type MISFET Qn is formed as a field effect transistor.

The gate electrode GE1 functions as a gate electrode (metal gate electrode) of the n-channel-type MISFET Qn, and the Hf-containing insulating film 5 below the gate electrode GE1 (and the interface layer 3 therebelow) functions as a gate insulating film of the n-channel-type MISFET Qn. Also, the n-type semiconductor region (impurities diffusion layer) functioning as a source or a drain of the n-channel-type MISFET Qn is formed of the n⁺-type semiconductor region SD1 and the n⁻-type semiconductor region EX1.

Next, as shown in FIG. 14, the metal silicide layer 10 is selectively formed on the surfaces of the n⁺-type semiconductor regions SD1 and the silicon film 8 by using a salicide (Self Aligned Silicide) technology. Specifically, after the surfaces of the n⁺-type semiconductor regions SD1 and others are purified, a metal film made of Co (cobalt), Ni (nickel), Pt (platinum), or the like is formed on the main surface of the semiconductor substrate 1 including the surfaces of the n⁺-type semiconductor regions SD1 and the silicon film 8. Then, after this metal film is caused by a heat treatment to react with upper layer portions of the n⁺-type semiconductor regions SD1 and the silicon film 8 to form the metal silicide layers 10, unreacted portions of this metal film can be removed by wet etching or the like. Although it is preferable to form the metal silicide layer 10 because it has an effect of decreasing diffusion resistance and contact resistance, its formation can be omitted if not necessary.

Next, as shown in FIG. 15, the insulating film (interlayer insulating film) 11 is formed on the main surface of the semiconductor substrate 1 so as to cover the gate electrode GE1 and the sidewall SW. The insulating film 11 is formed of, for example, a single film of a silicon oxide film, a stacked film of a thin silicon nitride film and a thick silicon oxide film thereon, or the like. After the insulating film 11 is formed, the surface of the insulating film 11 is planarized by using, for example, a CMP (Chemical Mechanical Polishing) method.

Next, with using a photoresist pattern (not shown) formed on the insulating film 11 as an etching mask, the insulating film 11 is subjected to dry etching, thereby forming the contact holes (through hole, hole) CNT in the insulating film 11. The contact holes CNT are formed in upper parts of the n⁺-type semiconductor regions SD1 and the gate electrode GE1.

Next, conductive plugs (conductor part for connection) PG made of tungsten (W) or the like are formed in the contact holes CNT. To form the plug PG, for example, a barrier conductive film (for example, titanium film, titanium nitride film, or stacked film thereof) is formed on the insulating film 11 including the inside (on bottom part and sidewall) of the contact hole CNT. Then, a main conductive film made of a tungsten film or the like is formed on this barrier conductive film so as to fill the contact hole CNT, and unnecessary portions of the main conductive film and the barrier conductive film on the insulating film 11 are removed by a CMP method, an etchback method, or the like. By this means, the plug PG can be formed. Note that, for the simplification of the drawings, the barrier conductive film and the main conductive film (tungsten film) configuring the plug PG are integrally shown in FIG. 15.

Next, as shown in FIG. 16, the stopper insulating film (insulating film for etching stopper) 12 and an insulating film (interlayer insulating film) 13 for forming wiring are sequentially formed on the insulating film 11 in which the plugs PG have been buried. The stopper insulating film 12 is a film to be an etching stopper at the time of a trench process to the insulating film 13, and a material having etching selectivity with respect to the insulating film 13 is used. For example, the stopper insulating film 12 can be a silicon nitride film, and the insulating film 13 can be a silicon oxide film.

Next, the wiring M1 of a first layer is formed by a single damascene method. First, after a wiring trench 14 is formed in a predetermined region of the insulating film 13 and the stopper insulating film 12 by dry etching using a photoresist pattern (not shown) as a mask, a barrier conductive film (for example, titanium nitride film, tantalum film, or tantalum nitride film) is formed on the main surface of the semiconductor substrate 1 (that is, on the insulating film 13 including a bottom part and a sidewall of the wiring trench 14). Subsequently, a copper seed layer is formed on the barrier conductive film by, for example, a CVD method or a sputtering method, and further a copper-plated film is formed on the seed layer by using, for example, an electrolytic plating method, thereby filling the inside of the wiring trench 14 with the copper plated film. Then, portions of the copper-plated film, the seed layer, and the barrier metal film in regions other than in the wiring trench 14 are removed by a CMP method to form the wiring M1 of the first layer having copper as a main conductive material. Note that, for the simplification of the drawings, the copper-plated film, the seed layer, and the barrier conductive film configuring the wiring M1 are integrally shown in FIG. 16.

The wiring M1 is electrically connected via the plug PG to the n⁺-type semiconductor region SD1 for the source or the drain of the n-channel-type MISFET Qn and others. Thereafter, wirings of second and upper layers are formed by a dual damascene method or the like, but the illustrations and descriptions thereof are omitted here. Also, the wiring M1 and the wirings of upper layers are not limited to damascene wirings, but can be formed by patterning a conductive film for wiring. For example, the wirings can be tungsten wirings or aluminum wirings.

In the manner described above, the semiconductor device of the present embodiment can be manufactured.

The present embodiment has a feature of using the Hf-containing film 4a, the rare-earth-containing film 4b, and the Hf-containing film 4c as films for forming the Hf-containing insulating film 5 and forming these Hf-containing film 4a, rare-earth-containing film 4b, and Hf-containing film 4c sequentially from below. By causing these Hf-containing film 4a, rare-earth-containing film 4b, and Hf-containing film 4c to react with one another, the Hf-containing insulating film 5 as a high dielectric constant gate insulating film of the n-channel-type MISFET Qn is formed. When the heat treatment at a high temperature other than the activation annealing (heat treatment) in step S14 is not performed during the manufacturing process, the reaction of the Hf-containing film 4a, the rare-earth-containing film 4b, and the Hf-containing film 4c proceeds by the activation annealing (heat treatment) in step S14. If a heat treatment is performed before the activation annealing (heat treatment) in step S14, three or two layers of the Hf-containing film 4a, the rare-earth-containing film 4b, and the Hf-containing film 4c react to some degree by the heat treatment previous to step S14 (activation annealing process), and the reaction (diffusion of atoms) further proceeds in the activation annealing process in step S14 to form the Hf-containing insulating film 5 close to a final form of the Hf-containing insulating film 5.

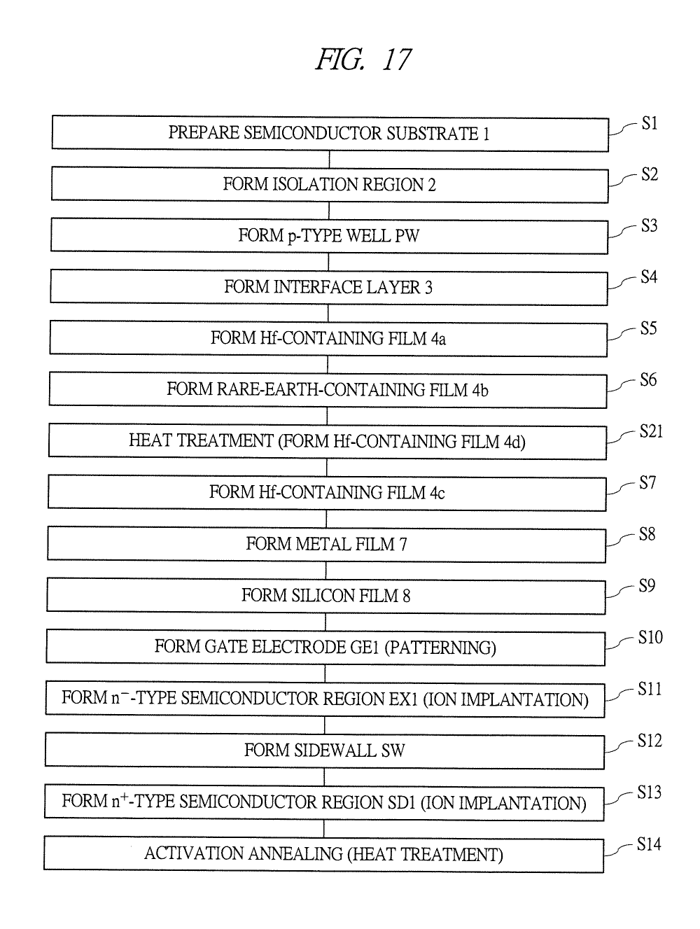

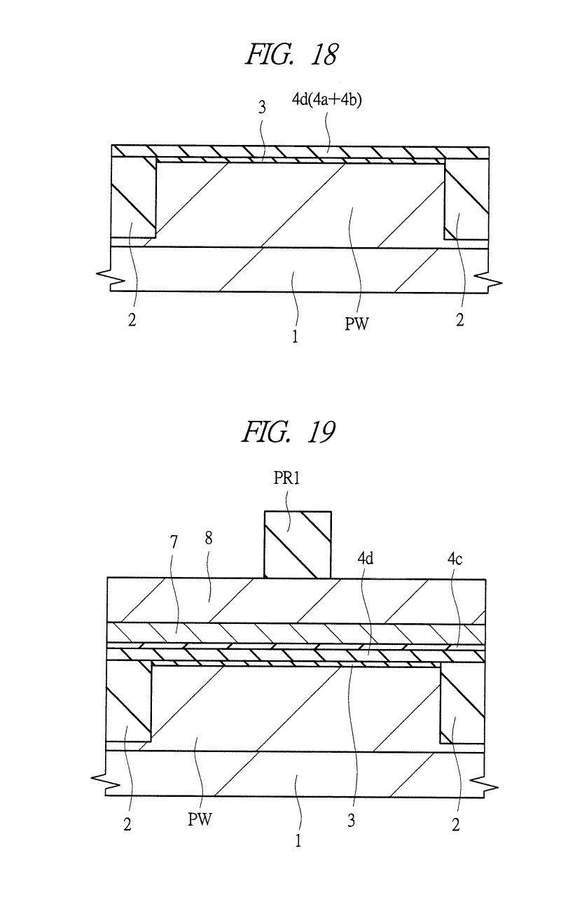

As another process of manufacturing the semiconductor device of the present embodiment, the case in which, after the rare-earth-containing film 4b is formed in step S6 described above and before the process of forming the Hf-containing film 4c in step S7 described above is performed, a heat treatment is performed to cause the rare-earth-containing film 4b and the Hf-containing film 4a to react (mix, mixing, interdiffuse) with each other is described with reference to FIG. 17 to FIG. 22. FIG. 17 is a manufacturing process flow diagram showing part of another process of manufacturing the semiconductor device of the present embodiment, and it corresponds to FIG. 2 described above. FIG. 18 to FIG. 22 are sectional views of main part of the semiconductor device of the present embodiment in the other manufacturing process.

After the processes up to the process of forming the rare-earth-containing film 4b in step S6 described above are performed to obtain the structure of FIG. 6 described above and before the process of forming the Hf-containing film 4c in step S7 described above is performed, a heat treatment is performed to the semiconductor substrate 1 to cause the rare-earth-containing film 4b and the Hf-containing film 4a to react (mix, mixing, interdiffuse) with each other (step S21 of FIG. 17). The heat treatment in this step S21 can be performed at a heat treatment temperature in a range of, for example, 600° C. to 1000° C. and in an inactive gas atmosphere (or may be performed in a nitrogen gas atmosphere). By performing the heat treatment in step S21, it is possible to promote the effect of decreasing the threshold of the MISFET achieved when the Hf-based gate insulating film (corresponding to the Hf-containing insulating film 5) contains a rare-earth element.

By this heat treatment of step S21, the Hf-containing film 4a and the rare-earth-containing film 4b react (mix, mixing, interdiffuse) with each other to form an Hf-containing film (reaction layer) 4d, which is a reaction layer (mixed layer, mixing layer) of the Hf-containing film 4a and the rare-earth-containing film 4b as shown in FIG. 18. The Hf-containing film 4a contains hafnium (Hf) and oxygen (O) as main components, and the rare-earth-containing film 4b contains a rare-earth element as a main component. Therefore, the Hf-containing film 4d formed by the reaction of the Hf-containing film 4a and the rare-earth-containing film 4b is an insulating film containing hafnium (Hf), oxygen (O), and the rare-earth element as main components. The rare-earth element contained in the Hf-containing film 4d is identical to the rare-earth element contained in the rare-earth-containing film 4b.

Also, when the Hf-containing film 4a contains not only hafnium (Hf) and oxygen (O) but also nitrogen (N), the Hf-containing film 4d contains not only hafnium (Hf), oxygen (O), and the rare-earth element but also nitrogen (N). Also, when the Hf-containing film 4a contains not only hafnium (Hf) and oxygen (O) but also Si (silicon), the Hf-containing film 4d contains not only hafnium (Hf), oxygen (O), and the rare-earth element but also Si (silicon).

Also, the rare-earth-containing film 4b is preferably a rare-earth oxide film (particularly preferably, lanthanum oxide film) as described above. In this case, the rare-earth-containing film 4b contains oxygen (O) in addition to the rare-earth element, but since the Hf-containing film 4a also contains oxygen (O), the Hf-containing film 4d contains oxygen (O) irrespectively of whether the rare-earth-containing film 4b contains oxygen (O). More specifically, although it is preferable that the rare-earth-containing film 4b contains oxygen in addition to the rare-earth element, the Hf-containing film 4d contains oxygen (O) in both of the case in which the rare-earth-containing film 4b contains oxygen (O) and the case in which the rare-earth-containing film 4b does not contain oxygen (O).

Therefore, when the rare-earth-containing film 4b is a rare-earth oxide film and the rare-earth element contained in the rare-earth-containing film 4b is represented as Ln, the Hf-containing film 4d is a film with the following composition depending on the type of the Hf-containing film 4a. That is, when the Hf-containing film 4a is an HfO film, the Hf-containing film 4d is an HfLnO film (when Ln=La, an HfLaO film). Also, when the Hf-containing film 4a is an HfON film, the Hf-containing film 4d is an HfLnON film (when Ln=La, an HfLaON film). Furthermore, when the Hf-containing film 4a is an HfSiO film, the Hf-containing film 4d is an HfLnSiO film (when Ln=La, an HfLaSiO film). Still further, when the Hf-containing film 4a is an HfSiON film, the Hf-containing film 4d is an HfLnSiON film (when Ln=La, an HfLaSiON film).

However, the Hf-containing film 4a and the rare-earth-containing film 4b are formed sequentially from below, and they react with each other to form the Hf-containing film 4d. Also, the Hf-containing film 4a contains Hf (hafnium) but does not contain a rare-earth element, and the rare-earth-containing film 4b contains a rare-earth element but does not contain Hf (hafnium). For this reason, the composition of the formed Hf-containing film 4d in a film thickness direction is not uniform, and the composition distribution of the Hf-containing film 4a and the rare-earth-containing film 4b before the reaction is maintained to some degree. This will be described below in more detail.

The subsequent processes are basically the same as the process of forming the Hf-containing film 4c in step S7 described above and subsequent processes (processes of FIG. 7 to FIG. 16).

More specifically, after the heat treatment in step S21 is performed, the Hf-containing film 4c is formed in step 7. When the heat treatment process in step S21 is not performed, the Hf-containing film 4c is formed on the rare-earth-containing film 4b as shown in FIG. 7 described above. By contrast, when the heat treatment process in step S21 is performed, the Hf-containing film 4c is formed on the Hf-containing film 4d as shown in FIG. 18. Thereafter, as shown in FIG. 19, the metal film 7 is formed on the Hf-containing film 4c in step S8, and the silicon film 8 is formed on the metal film 7 in step S9. These are the same irrespectively of the presence or absence of step S21.

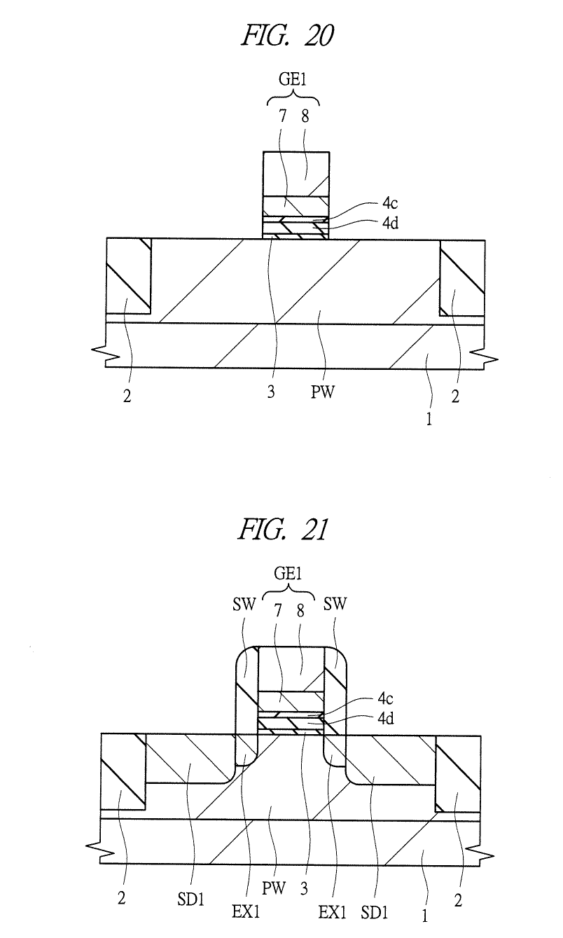

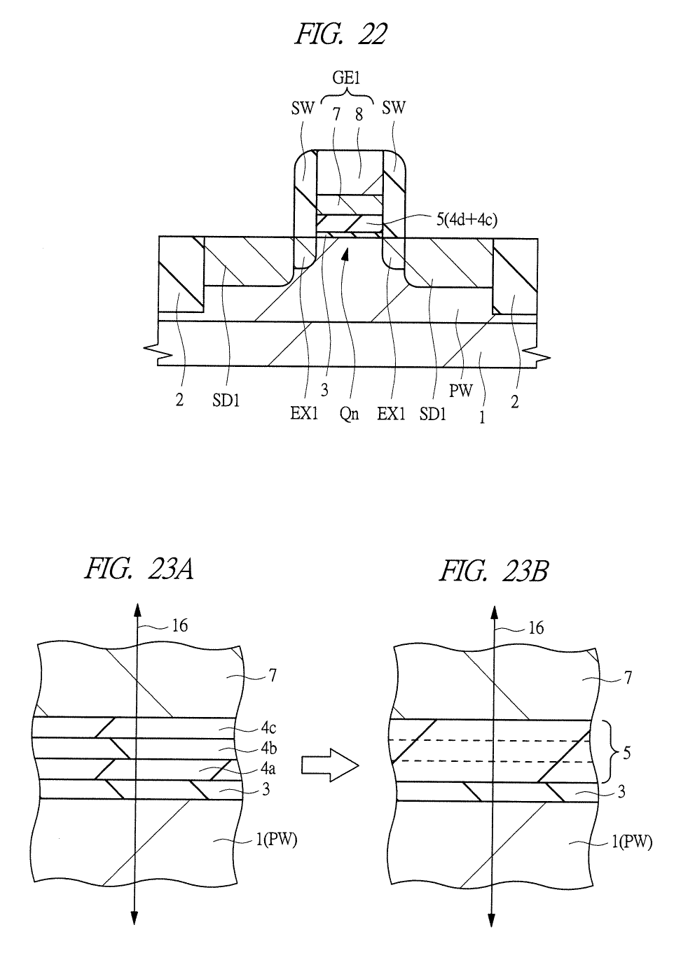

Next, as shown in FIG. 19, after a photoresist pattern PR1 is formed on the silicon film 8, with using this photoresist pattern PR1 as an etching mask, the stacked film of the silicon film 8 and the metal film 7 is patterned in step S10. In this manner, as shown in FIG. 20, the gate electrode GE1 formed of the metal film 7 and the silicon film 8 on the metal film 7 is formed, and then the photoresist pattern PR1 is removed. Thereafter, the n⁻-type semiconductor region EX1 is formed in step S11, the sidewall SW is formed in step S12, and the n⁺-type semiconductor region SD1 is formed in step S13, thereby obtaining the structure of FIG. 21. Then, by performing a heat treatment in step S14, the impurities introduced to the n⁻-type semiconductor region EX1, the n⁺-type semiconductor region SD1, the silicon film 8, and others by the ion implantation in steps S11 and S13 are activated, and at this time, the Hf-containing film 4d and the Hf-containing film 4c react (mix, mixing, interdiffuse) with each other. More specifically, the Hf-containing film 4d and the Hf-containing film 4c react (mix, mixing, interdiffuse) with each other to form the Hf-containing insulating film 5 as shown in FIG. 22. FIG. 22 corresponds to FIG. 13 described above. The subsequent processes are the same as those described above with reference to FIG. 14 to FIG. 16, and the descriptions thereof are omitted here.

When the heat treatment process in step S21 is not performed, the Hf-containing film 4a, the rare-earth-containing film 4b, and the Hf-containing film 4c react with one another to form the Hf-containing insulating film 5 as shown in FIG. 13 described above. On the other hand, when the heat treatment process in step S21 is performed, since the Hf-containing film 4a and the rare-earth-containing film 4b react with each other by the heat treatment in step S21 to form the Hf-containing film 4d, which is a reaction layer of both films, this Hf-containing film 4d and the Hf-containing film 4c react with each other in the heat treatment in step S14 to form the Hf-containing insulating film 5 as shown in FIG. 13 described above. A correlation between the types of the Hf-containing film 4a, the rare-earth-containing film 4b, and the Hf-containing film 4c (whether the film is any of an HfO film, an HfON film, an HfSiO film, and an HfSiON film) and the type of the Hf-containing insulating film 5 to be formed (whether the film becomes any of an HfLnO film, an HfLnON film, an HfLnSiO film, and an HfLnSiON film) is the same irrespectively of the presence or absence of the heat treatment in step S21, and since it has already been described above, the descriptions thereof are omitted here.

Since the Hf-containing film 4a and the rare-earth-containing film 4b formed thereon react with each other to form the Hf-containing film 4d, the composition of the formed Hf-containing film 4d in the film thickness direction is not uniform, and the composition distribution of the Hf-containing film 4a and the rare-earth-containing film 4b before the reaction is maintained to some degree. Also, since this Hf-containing film 4d and the Hf-containing film 4c formed thereon react with each other to form the Hf-containing insulating film 5, the composition of the formed Hf-containing insulating film 5 in the film thickness direction is not uniform, and the composition distribution of the Hf-containing film 4a, the rare-earth-containing film 4b, and the Hf-containing film 4c before the reaction is maintained to some degree. This will be described below in more detail.

Next, features of the present embodiment are described in more detail.

In the present embodiment, the gate electrode GE1 of the n-channel-type MISFET Qn has the metal film 7 positioned above the gate insulating film (here, the interface layer 3 and the Hf-containing insulating film 5), and is a so-called metal gate electrode. For this reason, since a depletion phenomenon of the gate electrode can be suppressed and parasitic capacitance can be eliminated, the size reduction of a MISFET element (reduction in the thickness of the gate insulating film) can be achieved.

Also, in the present embodiment, the Hf-containing insulating film 5 whose dielectric constant is higher than that of silicon oxide is used as a gate insulating film of the n-channel-type MISFET Qn. More specifically, the Hf-containing insulating film 5, which is a material film whose dielectric constant (relative permittivity) is higher than that of silicon oxide, that is, a so-called High-k film (high dielectric constant film) is used as a gate insulating film of the n-channel-type MISFET Qn. For this reason, compared with the case in which a silicon oxide film is used as a gate insulating film of the n-channel-type MISFET Qn, the physical film thickness of the Hf-containing insulating film 5 can be increased, and therefore a leakage current can be decreased.

Furthermore, in the present embodiment, a rare-earth element (particularly preferably, lanthanum) is introduced to the Hf-containing insulating film 5, which is an Hf-based high dielectric constant gate insulating film of the n-channel-type MISFET Qn. Therefore, the threshold of the n-channel-type MISFET Qn can be decreased.

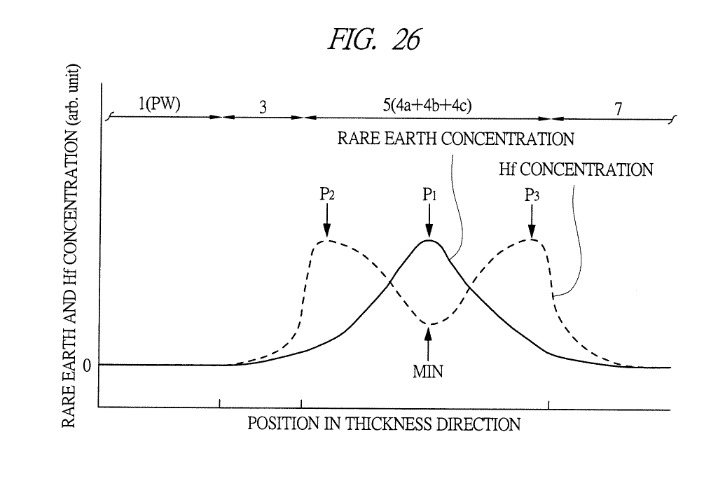

In the present embodiment, the Hf-containing insulating film 5 is formed by forming the Hf-containing film 4a containing hafnium and oxygen as main components, the rare-earth-containing film 4b containing a rare-earth element as a main component, and the Hf-containing film 4c containing hafnium and oxygen as main components sequentially from below and causing them to react one another. For this reason, the concentration distributions of the rare-earth element and Hf in the thickness direction of the Hf-containing insulating film 5 are inevitably as shown in FIG. 26, which will be described below. This is described below.

FIG. 23 is an explanatory diagram of the semiconductor device of the present embodiment, and it shows a partially-enlarged sectional view of a region near the gate insulating film. Note that FIG. 23 corresponds to the case in which the heat treatment in step S21 is not performed (the case of the process flow of FIG. 2). The Hf-containing insulating film 5 is formed by causing the Hf-containing film 4a, the rare-earth-containing film 4b, and the Hf-containing film 4c to react (mix, mixing, interdiffuse) with one another. FIG. 23A shows the state before the Hf-containing film 4a, the rare-earth-containing film 4b, and the Hf-containing film 4c react with one another, and FIG. 23B shows the state in which the Hf-containing film 4a, the rare-earth-containing film 4b, and the Hf-containing film 4c react with one another to become the Hf-containing insulating film 5 (state of FIG. 13 and subsequent drawings described above). The manufactured semiconductor device corresponds to the state of FIG. 23B.

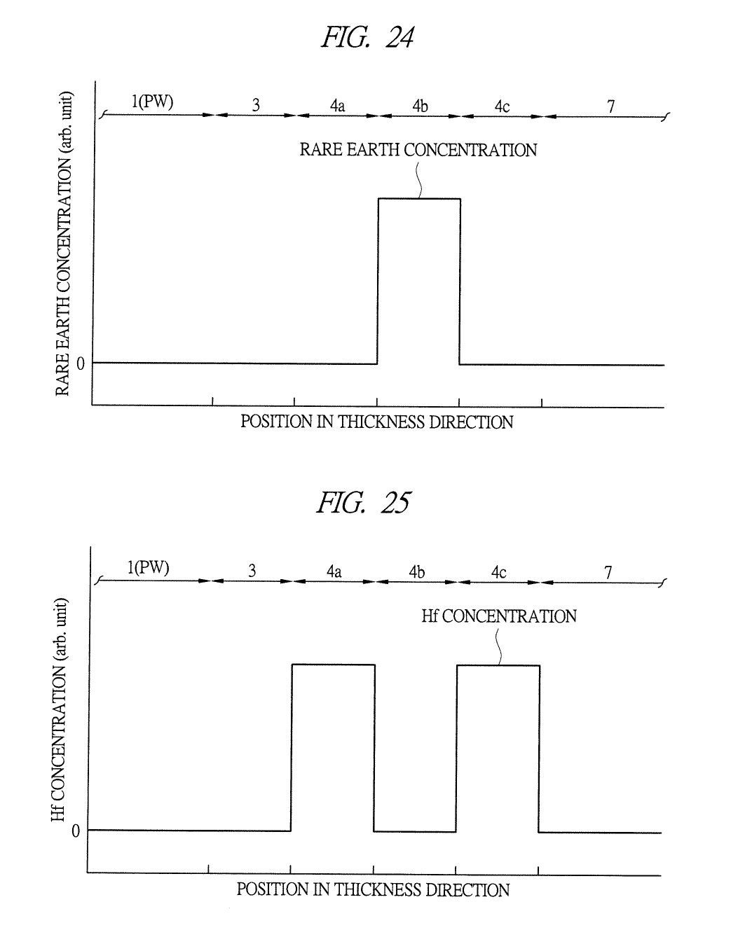

FIG. 24 is a graph showing a rare-earth concentration distribution in the thickness direction in the state of FIG. 23A, and FIG. 25 is a graph showing an Hf concentration distribution in the thickness direction in the state of FIG. 23A. FIG. 26 is a graph showing a rare-earth concentration distribution and an Hf concentration distribution in the thickness direction in the state of FIG. 23A. More specifically, the concentration distribution of the rare-earth element at positions along a line 16 of FIG. 23A corresponds to FIG. 24, the concentration distribution of Hf at positions along the line 16 of FIG. 23A corresponds to FIG. 25, and the concentration distribution of the rare-earth element and the concentration distribution of Hf at positions along the line 16 of FIG. 23B correspond to FIG. 26. Here, the position of the line 16 in FIG. 23A and the position of the line 16 in FIG. 23B are the same. For this reason, the horizontal axis of each of the graphs of FIG. 24 and FIG. 25 corresponds to the positions along the line 16 in FIG. 23A, the horizontal axis of the graph of FIG. 26 corresponds to the positions along the line 16 in FIG. 23B, the vertical axis of the graph of FIG. 24 corresponds to the rare-earth concentration (concentration of rare-earth element), the vertical axis of the graph of FIG. 25 corresponds to the Hf concentration, and the vertical axis of the graph of FIG. 26 corresponds to the rare-earth concentration and the Hf concentration. In FIG. 26, the concentration distribution of the rare-earth element is represented by a solid line, and the concentration distribution of Hf is represented by a dotted line. Note that the rare-earth concentration and the Hf concentration on the vertical axis of each of the graphs of FIG. 24 to FIG. 26 are represented with an arbitrary unit. Also, in the present application, the thickness direction or the film thickness direction corresponds to a direction perpendicular to the main surface of the semiconductor substrate 1. The direction of the line 16 in FIG. 23A and FIG. 23B corresponds to the thickness direction (that is, direction perpendicular to the main surface of the semiconductor substrate 1).

In the present embodiment, as can be seen also from FIG. 23, the Hf-containing film 4a, the rare-earth-containing film 4b, and the Hf-containing film 4c are formed sequentially from below and they are caused to react with one another, thereby forming the Hf-containing insulating film 5, which is a high dielectric constant gate insulating film. As can be seen also from FIG. 24, although the rare-earth-containing film 4b contains a rare-earth element, the Hf-containing films 4a and 4c do not contain a rare-earth element. Furthermore, as can be seen also from FIG. 25, although the Hf-containing films 4a and 4c contain Hf (hafnium), the rare-earth-containing film 4b does not contain Hf (hafnium). The rare-earth concentration in the thickness direction in the rare-earth-containing film 4b is approximately constant, the Hf concentration in the thickness direction in the Hf-containing film 4a is approximately constant, and the Hf concentration in the thickness direction in the Hf-containing film 4c is approximately constant.

If the Hf-containing film 4a, the rare-earth-containing film 4b, and the Hf-containing film 4c are completely mixed together when the Hf-containing insulating film 5 is formed, the concentration distributions of the respective elements in the thickness direction in the Hf-containing insulating film 5 are supposed to be uniform. In practice, however, it is difficult to completely mix the Hf-containing film 4a, the rare-earth-containing film 4b, and the Hf-containing film 4c together. For this reason, the concentration distributions of the respective elements in the thickness direction in the actually-formed Hf-containing insulating film 5 are not uniform, and the distribution is nonuniform with the composition distributions of the Hf-containing film 4a, the rare-earth-containing film 4b, and the Hf-containing film 4c before the reaction being maintained to some degree.

First, the rare-earth concentration distribution (concentration distribution of the rare-earth element) in the thickness direction of the Hf-containing insulating film 5 is described. As can be seen also from FIG. 24, among the Hf-containing film 4a, the rare-earth-containing film 4b, and the Hf-containing film 4c, only the rare-earth-containing film 4b, which is an intermediate layer, contains a rare-earth element. For this reason, as shown in FIG. 26, the rare-earth concentration distribution in the thickness direction of the Hf-containing insulating film 5 is not uniform (constant), and has a peak (maximum value) P₁ in a center region in the thickness direction of the Hf-containing insulating film 5. More specifically, in the concentration distribution of the rare-earth element in the thickness direction of the Hf-containing insulating film (first gate insulating film) 5, the concentration of the rare-earth element near a lower surface and an upper surface of the Hf-containing insulating film 5 is lower than that in the center region of the Hf-containing insulating film 5. As can be seen by comparing FIG. 24 and FIG. 26, in the Hf-containing insulating film 5, this peak P₁ is formed in a region that was the rare-earth-containing film 4b before it becomes the Hf-containing insulating film 5 (that is, the region that was originally the rare-earth-containing film 4b). The reason for this is as follows.

That is, when the Hf-containing film 4a, the rare-earth-containing film 4b, and the Hf-containing film 4c react with one another to form the Hf-containing insulating film 5, the rare-earth element is diffused from the rare-earth-containing film 4b to an Hf-containing film 4a side and an Hf-containing film 4c side. However, merely by a heat treatment such as activation annealing (heat treatment in step S14), the rare-earth element is not uniformly distributed in the thickness direction of the Hf-containing insulating film 5, and after the activation annealing (heat treatment in step S14), the heat treatment at a temperature equal to or higher than the temperature of the activation annealing (heat treatment in step S14) is not performed to the semiconductor substrate 1. For this reason, in the Hf-containing insulating film 5, the rare-earth concentration is low in the regions that were originally the Hf-containing films 4a and 4c (lower layer portion and upper layer portion of the Hf-containing insulating film 5), compared with the region that was originally the rare-earth-containing film 4b (intermediate layer portion in the thickness direction of the Hf-containing insulating film 5). Therefore, in the Hf-containing insulating film 5, the peak P₁ described above is formed in the region that was originally the rare-earth-containing film 4b (intermediate layer portion of the Hf-containing insulating film 5), and more specifically, the peak P₁ described above is formed near the center part in the thickness direction of the region that was originally the rare-earth-containing film 4b (intermediate layer portion of the Hf-containing insulating film 5). Also, the rare-earth concentration is gradually decreased toward the semiconductor substrate 1 side and the gate electrode GE1 (metal film 7) side from this peak P₁. In other words, the rare-earth concentration in the thickness direction of the Hf-containing insulating film 5 forms a distribution with one mountain, and reaches the maximum at the peak P₁ in the center region in the thickness direction of the Hf-containing insulating film 5. Also, the rare-earth concentration is monotonously decreased from the position of the peak P₁ (center region in the thickness direction) toward the semiconductor substrate 1 side, and the rare-earth concentration is monotonously decreased from the position of the peak P₁ (center region in the thickness direction) toward the metal film 7 side.

Therefore, the concentration distribution of the rare-earth element in the thickness direction of the Hf-containing insulating film 5 has the peak P₁ in the center region in the thickness direction of the Hf-containing insulating film 5, and the concentration of the rare-earth element on the lower surface of the Hf-containing insulating film 5 (that is, interface between the Hf-containing insulating film 5 and the interface layer 3) and its vicinity and on the upper surface of the Hf-containing insulating film 5 (that is, interface between the Hf-containing insulating film 5 and the metal film 7) and its vicinity is lower than that in the center region (peak P₁ described above) in the thickness direction of the Hf-containing insulating film 5.

Note that it is difficult to strictly measure a concentration distribution in a film thickness direction of an extremely thin film by analyses, and the concentration distribution shown in each of the graphs of FIG. 24 to FIG. 26 and FIG. 50 described below does not represent actual measured values obtained by analyses, but each graph schematically shows a concentration distribution inevitably formed when considered theoretically.

Next, the Hf concentration distribution of the Hf-containing insulating film 5 in the thickness direction is described. As can be seen also from FIG. 25, among the Hf-containing film 4a, the rare-earth-containing film 4b, and the Hf-containing film 4c, the Hf-containing film 4a and the Hf-containing film 4c contain Hf, but the rare-earth-containing film 4b which is an intermediate layer does not contain Hf. For this reason, as shown in FIG. 26, the Hf concentration distribution in the thickness direction of the Hf-containing insulating film 5 is not uniform (constant), but has double peaks (peak P₂ and peak P₃). Note that the fact that the concentration distribution has double peaks means that the concentration distribution has peaks (here, peak P₂ and peak P₃), which are maximum values, at two positions and does not have any peak (maximum value) other than the peaks at the two positions. As can been seen by comparing FIG. 25 and FIG. 26, in the Hf-containing insulating film 5, the peak P₂ which is one of the double peaks is formed in a region in the Hf-containing insulating film 5 that was originally the Hf-containing film 4a (lower layer portion of the Hf-containing insulating film 5), and the peak P₃ which is the other of the double peaks is formed in a region in the Hf-containing insulating film 5 that was originally the Hf-containing film 4c (upper layer portion of the Hf-containing insulating film 5). The reason for this is as follows.

That is, when the Hf-containing film 4a, the rare-earth-containing film 4b, and the Hf-containing film 4c react with one another to form the Hf-containing insulating film 5, Hf (hafnium) is diffused from the Hf-containing film 4a to the rare-earth-containing film 4b side and from the Hf-containing film 4c to the rare-earth-containing film 4b side. However, merely by heat treatment such as activation annealing (the heat treatment in step S14), Hf is not uniformly distributed in the thickness direction of the Hf-containing insulating film 5, and after the activation annealing (heat treatment in step S14), the heat treatment at a temperature equal to or higher than the temperature of the activation annealing (heat treatment in step S14) is not performed to the semiconductor substrate 1. For this reason, in the Hf-containing insulating film 5, the Hf concentration is low in the region that was originally the rare-earth-containing film 4b (intermediate layer portion of the Hf-containing insulating film 5 in the thickness direction), compared with the regions that were originally the Hf-containing films 4a and 4c (lower layer portion and upper layer portion of the Hf-containing insulating film 5). Therefore, in the Hf-containing insulating film 5, the peak P₂ described above is formed in the region that was originally the Hf-containing film 4a (lower layer portion of the Hf-containing insulating film 5), and the peak P₃ described above is formed in the region that was originally the Hf-containing film 4c (upper layer portion of the Hf-containing insulating film 5). Also, on the semiconductor substrate 1 side from this peak P₂ and the gate electrode GE1 side from this peak P₃, the Hf concentration is gradually or rapidly decreased. Further, at a position between the peak P₂ and the peak P₃ (position in the thickness direction), the Hf concentration takes a minimum value MIN. From the peak P₂ to this minimum value MIN and from the peak P₃ to this minimum value MIN, the Hf concentration is gradually decreased. More specifically, the rare-earth concentration in the thickness direction of the Hf-containing insulating film 5 forms a distribution with two mountains, and has double peaks (P₂ and P₃) in the thickness direction of the Hf-containing insulating film 5. The Hf concentration is monotonously decreased from the position of the peak P₂ toward the semiconductor substrate 1 side, the Hf concentration is monotonously decreased from the position of the peak P₂ toward the minimum value MIN, the Hf concentration is monotonously decreased from the position of the peak P₃ toward the minimum value MIN, and the Hf concentration is monotonously decreased from the position of the peak P₃ toward the metal film 7 side.

Also, as described above, in the Hf-containing insulating film 5, the peak P₁ described above is formed in a region that was originally the rare-earth-containing film 4b (intermediate layer portion of the Hf-containing insulating film 5), the peak P₂ described above is formed in a region that was originally the Hf-containing film 4a (lower layer portion of the Hf-containing insulating film 5), and the peak P₃ described above is formed in a region that was originally the Hf-containing film 4c (upper layer portion of the Hf-containing insulating film 5). For this reason, as shown in FIG. 26, the peak P₁ described above is positioned between the position of the peak P₂ described above and the position of the peak P₃ described above in the thickness direction of the Hf-containing insulating film 5. More specifically, the concentration distribution of the rare-earth element in the thickness direction of the Hf-containing insulating film 5 has the peak P₁ at a position between the double peaks of the concentration distribution of Hf (hafnium) (that is, between the position of the peak P₂ and the position of the peak P₃) in the thickness direction of the Hf-containing insulating film 5. Also, in the thickness direction of the Hf-containing insulating film 5, the Hf concentration distribution has the minimum value MIN described above at the position where the rare-earth concentration distribution has the peak P₁ described above or its vicinity.

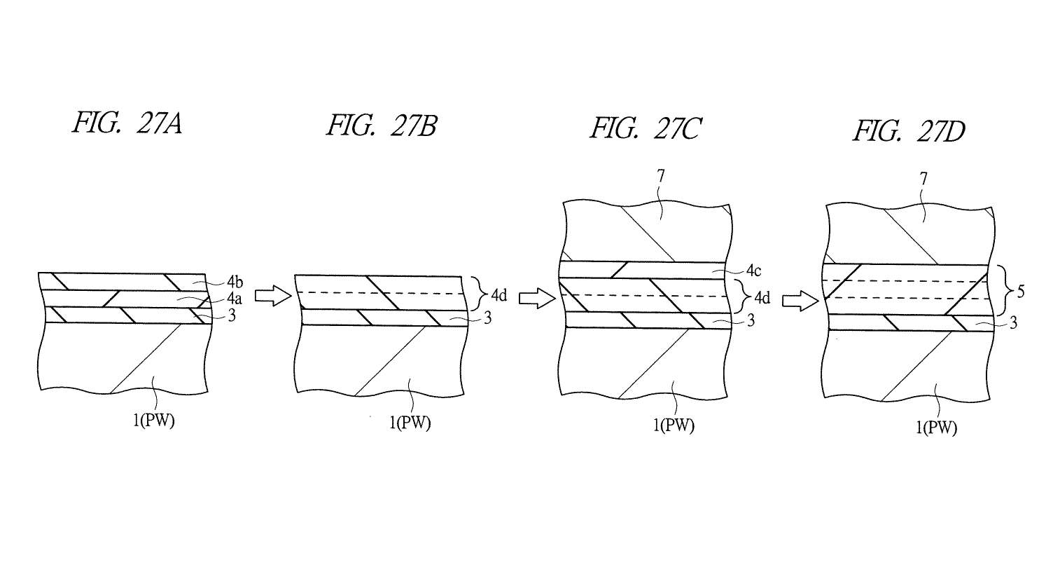

FIG. 27 is an explanatory diagram of the semiconductor device of the present embodiment, and it shows a partially-enlarged sectional view of a region near the gate insulating film as with FIG. 23 described above. While FIG. 23 corresponds to the case in which the heat treatment in step S21 is not performed (the case of the process flow of FIG. 2), FIG. 27 corresponds to the case in which the heat treatment in step S21 is performed (the case of the process flow of FIG. 17). FIG. 27A shows the state before the Hf-containing film 4a and the rare-earth-containing film 4b react with each other (the state of FIG. 6 described above), FIG. 27B shows the state in which the Hf-containing film 4a and the rare-earth-containing film 4b react with each other to become the Hf-containing film 4d (the state of FIG. 18 described above), and FIG. 27D shows the state in which the Hf-containing film 4d and the Hf-containing film 4c react with each other to become the Hf-containing insulating film 5 (the state of FIG. 22 and subsequent drawings described above). The manufactured semiconductor device corresponds to the state of FIG. 27D, and FIG. 23B and FIG. 27D are the same.

In the case of the process flow of FIG. 17, as can be seen also from FIG. 27, the Hf-containing film 4a and the rare-earth-containing film 4b are formed sequentially from below and are caused to react with each other to form the Hf-containing film 4d, and by causing this Hf-containing film 4d and the Hf-containing film 4c formed thereon to react with each other, the Hf-containing insulating film 5 which is a high dielectric constant gate insulating film is formed. Also in this case, the rare-earth-containing film 4b contains a rare-earth element, but the Hf-containing films 4a and 4c do not contain a rare-earth element. Furthermore, the Hf-containing films 4a and 4c contain Hf (hafnium), but the rare-earth-containing film 4b does not contain Hf (hafnium).

If the Hf-containing film 4d and the Hf-containing film 4c are completely mixed together when the Hf-containing insulating film 5 is formed, the concentration distributions of the respective elements in the thickness direction in the Hf-containing insulating film 5 are supposed to be uniform. In practice, however, it is difficult to completely mix the Hf-containing film 4d and the Hf-containing film 4c together. It is also difficult to completely mix the Hf-containing film 4a and the rare-earth-containing film 4b together by the heat treatment in step S21. For this reason, the concentration distributions of the respective elements in the thickness direction in the actually-formed Hf-containing insulating film 5 are not uniform, and the distribution is nonuniform with the composition distribution of the Hf-containing film 4a, the rare-earth-containing film 4b, and the Hf-containing film 4c before the reaction being maintained to some degree.

More specifically, even when the Hf-containing film 4a and the rare-earth-containing film 4b are once caused to react with each other and then this reaction layer (Hf-containing film 4d) and the Hf-containing film 4c are caused to react with each other to form the Hf-containing insulating film 5 like in the process of FIG. 17, the rare-earth concentration distribution and the Hf concentration distribution in the thickness direction of the Hf-containing insulating film 5 are similar to the concentration distributions when the Hf-containing film 4a, the rare-earth-containing film 4b, and Hf-containing film 4c are caused to react with one another to form the Hf-containing insulating film 5 like in the process of FIG. 2. In other words, irrespectively of the presence or absence of the heat treatment process in step S21, the rare-earth concentration distribution and the Hf concentration distribution in the thickness direction of the formed Hf-containing insulating film 5 are as shown in FIG. 26. The specific description of the concentration distributions shown in FIG. 26 has been already made above, and thus is omitted here.

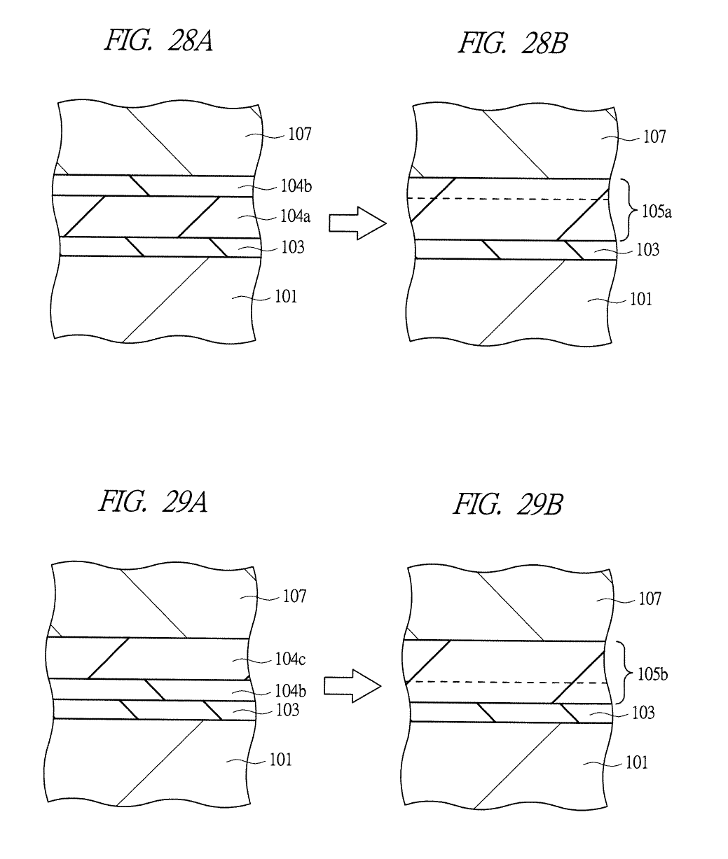

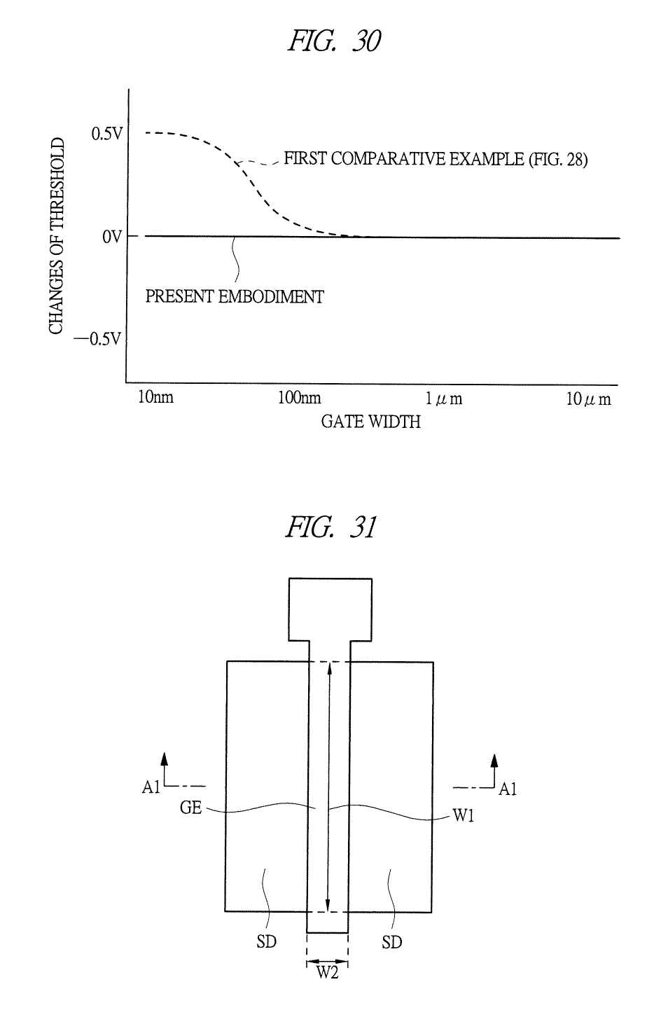

FIG. 28 is an explanatory diagram of a semiconductor device of a first comparative example, and it shows a partially-enlarged sectional view of a region near the gate insulating film and corresponds to FIG. 23 described above of the present embodiment. In the semiconductor device of the first comparative example of FIG. 28, as shown in FIG. 28A, an interface layer (silicon oxide film) 103, a hafnium oxide film 104a, and a rare-earth oxide film 104b are formed sequentially from below on a semiconductor substrate 101, and a metal film 107 configuring a metal gate electrode is formed on the rare-earth oxide film 104b. Then, by a heat treatment at a high temperature such as activation annealing, the hafnium oxide film 104a and the rare-earth oxide film 104b react with each other to form a high dielectric constant gate insulating film 105a containing hafnium (Hf), oxygen (O), and a rare-earth element as main components as shown in FIG. 28B.

FIG. 29 is an explanatory diagram of a semiconductor device of a second comparative example, and it shows a partially-enlarged sectional view of a region near the gate insulating film and corresponds to FIG. 23 described above of the present embodiment. In the semiconductor device of the second comparative example of FIG. 29, as shown in FIG. 29A, an interface layer (silicon oxide film) 103, a rare-earth oxide film 104b, and a hafnium oxide film 104c are formed sequentially from below on a semiconductor substrate 101, and a metal film 107 configuring a metal gate electrode is formed on the hafnium oxide film 104c. Then, by a heat treatment at a high temperature such as activation annealing, the rare-earth oxide film 104b and the hafnium oxide film 104c react with each other to form a high dielectric constant gate insulating film 105b containing hafnium (Hf), oxygen (O), and a rare-earth element as main components as shown in FIG. 29B.

The first comparative example of FIG. 28 corresponds to the case in which the Hf-containing film 4c is not formed in the present embodiment, and the second comparative example of FIG. 29 corresponds to the case in which the Hf-containing film 4a is not formed in the present embodiment.

As a high dielectric constant gate insulating film, the Hf-based gate insulating film containing hafnium (Hf) and oxygen (O) as main components is extremely excellent in terms of high heat resistance, high dielectric constant, and high stability. In an n-channel-type MISFET, when a rare-earth element (particularly preferably, lanthanum) is introduced to this Hf-based gate insulating film, the threshold of the n-channel-type MISFET can be decreased.

However, it has been found by the studies of the inventors that, when a rare-earth element is introduced to the Hf-based gate insulating film, this rare-earth element tends to be diffused to a metal gate electrode and semiconductor substrate side, and it possibly causes various inconveniences.

First, in the semiconductor device of the first comparative example of FIG. 28, the following problems arise. That is, in the semiconductor device of the first comparative example of FIG. 28, to form the high dielectric constant gate insulating film 105a, two layers, that is, the hafnium oxide film 104a and the rare-earth oxide film 104b formed thereon are used, and these two layers are caused to react with each other. In this case, since the metal film 107 for a metal gate is positioned just above the rare-earth oxide film 104b, the rare-earth element tends to be diffused into the metal film 107. When the rare-earth element is diffused into the metal film 107, since the effective work function of the metal gate electrode (metal film 107) is changed, the threshold of the n-channel-type MISFET is shifted from a designed value (desired value), which invites the variations (fluctuations) of the threshold and a decrease in performance of the semiconductor device having the MISFET.

Also, the rare-earth concentration distribution in the thickness direction of the high dielectric constant gate insulating film 105a is not uniform, and the distribution is nonuniform with the composition distribution of the hafnium oxide film 104a and the rare-earth oxide film 104b before the reaction being maintained to some degree. The rare-earth concentration is substantially high near the interface between the high dielectric constant gate insulating film 105a and the metal film 107. Since the rare-earth element has a high reactivity and also tends to be crystallized, if a rare-earth element is present at an interface between the high dielectric constant gate insulating film 105a and the metal gate electrode (metal film 107) with a high concentration, an oxidizer such as oxygen, moisture, or an OH radical tends to be immersed from a side surface of the metal gate electrode through the interface between the high dielectric constant gate insulating film 105a and the metal gate electrode (metal film 107), which invites the oxidization of the metal gate electrode (metal film 107). If the metal gate electrode (metal film 107) is oxidized, the effective work function of the metal gate electrode (metal film 107) is changed. As a result, the threshold of the n-channel-type MISFET is shifted from a designed value (desired value), which invites the variations (fluctuations) of the threshold and a decrease in performance of the semiconductor device having the MISFET.

Next, in the semiconductor device of the second comparative example of FIG. 29, the following problems arise. That is, in the semiconductor device of the second comparative example of FIG. 29, to form the high dielectric constant gate insulating film 105b, two layers, that is, the rare-earth oxide film 104b and the hafnium oxide film 104c formed thereon are used, and these two layers are caused to react with each other. In this case, since the rare-earth oxide film 104b is formed just above the interface layer 103, the rare-earth element tends to be diffused into the semiconductor substrate 101. When the rare-earth element is diffused into the semiconductor substrate 101, the mobility of the channel is decreased to decrease the characteristics of the MISFET, which invites the decrease in performance of the semiconductor device having the MISFET. Also, since the interface layer 103 is provided to control the interface between the high dielectric constant gate insulating film 105b and the semiconductor substrate 101, it is not preferable to form the rare-earth oxide film 104b directly on the interface layer 103.

As described above, in the first comparative example of FIG. 28 in which the metal film 107 for a metal gate is formed just above the rare-earth oxide film 104b and the second comparative example of FIG. 29 in which the interface layer 103 is positioned just below the rare-earth oxide film 104b, there is a possibility that the inconveniences due to diffusion of the rare-earth element occur. For this reason, in order to achieve a further improvement in performance of the semiconductor device including a MISFET having a high dielectric constant gate insulating film and a metal gate electrode, it is desired to suppress the inconveniences due to diffusion of the rare-earth element to a metal gate electrode and semiconductor substrate side.

For its achievement, in the present embodiment, as described above, to form the Hf-containing insulating film 5, which is a high dielectric constant gate insulating film containing hafnium (Hf), oxygen (O), and a rare-earth element as main components, three layers, that is, the Hf-containing film 4a, the rare-earth-containing film 4b, and the Hf-containing film 4c to be formed sequentially from below are used and caused to react with each other, and the Hf-containing insulating film 5 is formed.

For this reason, in the present embodiment, the rare-earth-containing film 4b is not formed just above the interface layer 3 but is formed on the Hf-containing film 4a, and therefore the diffusion of the rare-earth element contained in the rare-earth-containing film 4b into the semiconductor substrate 1 (p-type well PW) can be suppressed or prevented. Therefore, a decrease in channel mobility due to diffusion of the rare-earth element into the semiconductor substrate 1 (p-type well PW) can be suppressed or prevented, and characteristics (performance) of the n-channel-type MISFET Qn can be improved. Therefore, the performance of the semiconductor device including the n-channel-type MISFET can be improved. In this manner, in the present embodiment, the problems that occur in the second comparative example of FIG. 29 can be solved and the performance of the semiconductor device can be improved.

Still further, in the present embodiment, the metal film 7 for a metal gate electrode is not formed just above the rare-earth-containing film 4b, but the metal film 7 is formed on the Hf-containing film 4c. Therefore, the diffusion of the rare-earth element into the metal film 7 for a metal gate electrode can be suppressed or prevented. If the rare-earth element is diffused into the metal film 7, the effective work function of the metal gate electrode (metal film 7) is changed, and the threshold is shifted from a designed value (desired value). In the present embodiment, however, the diffusion of the rare-earth element into the metal film 7 can be suppressed or prevented, and therefore the threshold of the n-channel-type MISFET Qn can be set to the designed value (desired value). Also, variations (fluctuations) of the threshold can be decreased. Therefore, the characteristics (performance) of the n-channel-type MISFET can be improved, and the performance of the semiconductor device having the n-channel-type MISFET can be improved.

Still further, the rare-earth concentration distribution in the thickness direction in the Hf-containing insulating film 5 is not uniform, and the distribution is nonuniform with the composition distribution of the Hf-containing film 4a, the rare-earth-containing film 4b, and the Hf-containing film 4c before the reaction being maintained to some degree. For this reason, in the present embodiment, compared with the first comparative example of FIG. 28 described above, in reflection of the formation of the metal film 7 on the Hf-containing film 4c not containing a rare-earth element, the rare-earth concentration near the interface between the high dielectric constant gate insulating film (Hf-containing insulating film 5) and the metal film 7 can be substantially lowered. Since the rare-earth concentration at the interface between the Hf-containing insulating film 5 (high dielectric constant gate insulating film) and the metal film 7 (metal gate electrode) can be lowered, the immersion of an oxidizer such as oxygen, moisture, or an OH radical from a side surface of the gate electrode GE1 through the interface between the Hf-containing insulating film 5 and the metal film 7 can be suppressed or prevented, and the oxidation of the metal film 7 can be suppressed or prevented. For this reason, although the effective work function of the metal film 7 is changed if the metal film 7 is oxidized, since the oxidation of the metal film 7 can be suppressed or prevented in the present embodiment, the threshold of the n-channel-type MISFET can be set to the designed value (desired value). Also, since the variations (fluctuations) of the threshold can be decreased, the characteristics (performance) of the n-channel-type MISFET can be improved, and the performance of the semiconductor device having the n-channel-type MISFET can be improved. As described above, in the present embodiment, the problems that occur in the first comparative example of FIG. 28 can be solved and the performance of the semiconductor device can be improved.

Still further, when comparing the problems that occur when the rare-earth element is diffused into the metal film 7 (corresponding to problems that occur in the first comparative example described above) and the problems that occur when the rare-earth element is diffused into the semiconductor substrate 1 (corresponding to problems that occur in the second comparative example described above), the former contributes to a decrease in performance of the semiconductor device more than the latter. For this reason, the film thickness (formed film thickness in step S7) of the Hf-containing film 4c is preferably larger than the film thickness (formed film thickness in step S5) of the Hf-containing film 4a. By making the film thickness (formed film thickness) of the Hf-containing film 4c larger than the film thickness (formed film thickness) of the Hf-containing film 4a, the diffusion of the rare-earth element into the metal film 7 can be adequately prevented while suppressing an increase in film thickness of the Hf-containing insulating film 5, and the performance of the semiconductor device having the n-channel-type MISFET can be efficiently improved.

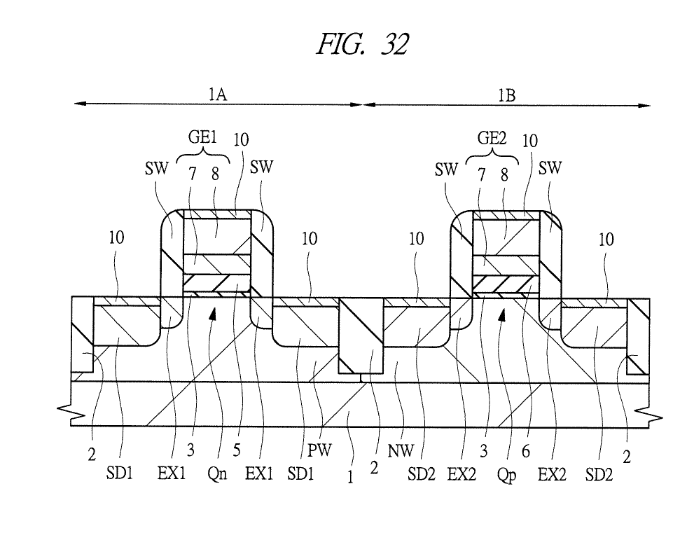

FIG. 30 is a graph showing narrow channel characteristics of an n-channel-type MISFET. FIG. 31 is an explanatory diagram of a gate width. The horizontal axis of the graph of FIG. 30 corresponds to the gate width of the n-channel-type MISFET, and the vertical axis of the graph of FIG. 30 corresponds to an amount of change of the threshold. Note that the amount of change of the threshold on the vertical axis of the graph of FIG. 30 corresponds to the shift of the threshold from a reference value when a gate width is changed, and a threshold when the gate width is sufficiently large (gate width is approximately 1 μm or larger) is set as the reference value. Also, FIG. 31 shows a planar layout of a gate electrode GE (corresponding to the gate electrode GE1 of the present embodiment) and source and drain regions SD (corresponding to regions obtained by combining the n⁻-type semiconductor regions EX1 and the n⁺-type semiconductor regions SD1). The sectional view of FIG. 1 described above approximately corresponds to a sectional view at the position of a line A1-A1 of FIG. 31. A gate width is indicated by a reference character W1 in FIG. 31, and a gate length is indicated by a reference character W2 in FIG. 31. In a semiconductor device with a gate length of 32 nm to 22 nm, a gate width equal to or smaller than 100 nm may be used in some cases.

In FIG. 30, the case in which the Hf-containing film 4a, the rare-earth-containing film 4b, and the Hf-containing film 4c are formed sequentially from below and they react with one another to form the Hf-containing insulating film 5 as with the present embodiment is represented by a solid line and is denoted by “present embodiment”. Also, in FIG. 30, the case in which two layers, that is, the hafnium oxide film 104a and the rare-earth oxide film 104b are formed sequentially from below and they react with each other to form the high dielectric constant gate insulating film 105a as with the first comparative example of FIG. 28 described above is represented by a dotted line and is denoted by “first comparative example (FIG. 28)”.

As shown in FIG. 30, in the first comparative example of FIG. 28 described above, when the gate width is large, the threshold voltage can be decreased by introducing the rare-earth element to the high dielectric constant gate insulating film 105a. However, in the first comparative example of FIG. 28 described above, when the gate width is small, the threshold voltage is increased due to the effect of the oxidation of the metal film 107 for the reason described above, and the effect of decreasing the threshold by introducing the rare-earth element to the high dielectric constant gate insulating film 105a disappears in appearance.

By contrast, in the present embodiment, as shown in FIG. 30, even when the gate width W1 is small, let alone when the gate width W1 is large, the threshold voltage can be decreased by introducing the rare-earth element to the high dielectric constant gate insulating film (Hf-containing insulating film 5). For this reason, the effect of decreasing the threshold by introducing the rare-earth element to the high dielectric constant gate insulating film (Hf-containing insulating film 5) can be achieved irrespectively of the size of the gate width W1. Therefore, the performance of the semiconductor device having the n-channel-type MISFET can be improved.

### Second Embodiment

In the first embodiment described above, the case in which the present invention is applied to a semiconductor device having an n-channel-type MISFET has been described. In the present embodiment, the case in which the present invention is applied to a semiconductor device having a CMISFET (Complementary Metal Insulator Semiconductor Field Effect Transistor) is described.

FIG. 32 is a sectional view of main parts of a semiconductor device of the present embodiment, here, a semiconductor device having a CMISFET.

As shown in FIG. 32, the semiconductor device of the present embodiment has an n-channel-type MISFET Qn formed in an nMIS formation region (first region) 1A of a semiconductor substrate 1 and a p-channel-type MISFET Qp formed in a pMIS formation region (second region) 1B of the semiconductor substrate 1. The structure of the n-channel-type MISFET Qn in the present embodiment is basically the same as the n-channel-type MISFET Qn in the first embodiment described above.

More specifically, the semiconductor substrate 1 made of p-type single crystal silicon or the like has the nMIS formation region 1A and the pMIS formation region 1B defined by isolation regions 2 and electrically isolated from each other. A p-type well PW is formed in the nMIS formation region 1A of the semiconductor substrate 1, and an n-type well NW is formed in the pMIS formation region 1B of the semiconductor substrate 1. On a surface of the p-type well PW in the nMIS formation region 1A, a gate electrode (metal gate electrode) GE1 of the n-channel-type MISFET Qn is formed via an Hf-containing insulating film (first gate insulating film) 5 functioning as a gate insulating film of the n-channel-type MISFET Qn. Also, on a surface of the n-type well NW in the pMIS formation region 1B, a gate electrode (metal gate electrode) GE2 of the p-channel-type MISFET Qp is formed via an Hf-containing insulating film (second gate insulating film) 6 functioning as a gate insulating film of the p-channel-type MISFET Qp.

Also, the Hf-containing insulating film 5 and the Hf-containing insulating film 6 can be formed directly on a surface (silicon surface) of the semiconductor substrate 1 (p-type well PW and n-type well NW) (that is, an interface layer 3 can be omitted). However, it is more preferable to provide the interface layer 3 (insulating layer, insulating film) 3 similar to that of the first embodiment described above at an interface between the Hf-containing insulating film 5 and the semiconductor substrate 1 and between the Hf-containing insulating film 6 and the semiconductor substrate 1 (p-type well PW and n-type well NW). The reason why the interface layer 3 is provided between the Hf-containing insulating film 5 and the semiconductor substrate 1 (p-type well PW) and between the Hf-containing insulating film 6 and the semiconductor substrate 1 (n-type well NW) is similar to that of the first embodiment described above, and therefore is not described here.

Each of the Hf-containing insulating film 5 and the Hf-containing insulating film 6 is an insulating material film whose dielectric constant (relative permittivity) is higher than that of silicon oxide, that is, a so-called High-k film (high dielectric constant film). The Hf-containing insulating film 5 functioning as a gate insulating film (high dielectric constant gate insulating film) of the n-channel-type MISFET Qn is similar to that of the first embodiment described above, and therefore is not specifically described here. The Hf-containing insulating film 6 functioning as a gate insulating film (high dielectric constant gate insulating film) of the p-channel-type MISFET Qp is described.

The Hf-containing insulating film 6 has a feature of being made of an insulating material containing Hf (hafnium) and O (oxygen) as main components and further containing Al (aluminum). This Hf-containing insulating film 6 contains Hf (hafnium), O (oxygen), and Al (aluminum) as essential constituent elements, and it can further contain one or both of N (nitrogen) and Si (silicon) other than those. The reason why the Hf-containing insulating film 6 contains Al (aluminum) is to decrease the threshold of the p-channel-type MISFET Qp. Therefore, an HfAlO film, an HfAlON film, an HfAlSiON film, or an HfAlSiO film can be suitably used as the Hf-containing insulating film 6.

Here, the HfAlO film is an insulating material film made of hafnium (Hf), aluminum (Al), and oxygen (O), and the HfAlON film is an insulating material film made of hafnium (Hf), aluminum (Al), oxygen (O), and nitrogen (N). Also, the HfAlSiON film is an insulating material film made of hafnium (Hf), aluminum (Al), silicon (Si), oxygen (O), and nitrogen (N), and the HfAlSiO film is an insulating material film made of hafnium (Hf), aluminum (Al), silicon (Si), and oxygen (O).

Each of the gate electrodes GE1 and GE2 is configured of a stacked film (stacked structure) of a metal film (metal gate film) 7 in contact with a gate insulating film (Hf-containing insulating film 5 in the nMIS formation region 1A and Hf-containing insulating film 6 in the pMIS formation region 1B) and a silicon film 8 on this metal film 7. The gate electrode GE1 has the metal film 7 in contact with the Hf-containing insulating film 5, which is a gate insulating film (high dielectric constant gate insulating film), and the gate electrode GE2 has the metal film 7 in contact with the Hf-containing insulating film 6, which is a gate insulating film (high dielectric constant gate insulating film). Each of the gate electrodes GE1 and GE2 is a so-called metal gate electrode. The metal film 7 is similar to that of the first embodiment described above, and therefore is not described here.

As with the first embodiment, also in the present embodiment, a concentration (percentage content) of the rare-earth element of the Hf-containing insulating film 5 is not uniform (constant) in a film thickness direction of the Hf-containing insulating film 5. The concentration (percentage content) of the rare-earth element is low in a region on a semiconductor substrate 1 side (that is, a region in contact with the interface layer 3) and a region on a gate electrode GE1 side (that is, a region in contact with the metal film 7), and the concentration (percentage content) of the rare-earth element is high in a center region (center part) in the film thickness direction. Also, in the present embodiment, the Hf-containing insulating film 6 contains aluminum (Al), but a concentration (percentage content) of Al of the Hf-containing insulating film 6 is not uniform (constant) in a film thickness direction of the Hf-containing insulating film 6. The concentration (percentage content) of Al is low in a region on a semiconductor substrate 1 side (that is, a region in contact with the interface layer 3) and a region on a gate electrode GE2 side (that is, a region in contact with the metal film 7), and the concentration (percentage content) of Al is high in a center region (center part) in the film thickness direction. This will be described below in more detail.

In the p-type well PW in the nMIS formation region 1A, as source and drain regions with an LDD structure of the n-channel-type MISFET Qn, n⁻-type semiconductor regions (extension regions, LDD regions) EX1 and n⁺-type semiconductor regions (source and drain regions) SD1 with an impurity concentration higher than that of the n⁻-type semiconductor regions EX1 are formed. Also, in the n-type well NW in the pMIS formation region 1B, as source and drain regions with an LDD structure of the p-channel-type MISFET Qp, p⁻-type semiconductor regions (extension regions, LDD regions) EX2 and p⁺-type semiconductor regions (source and drain regions) SD2 with an impurity concentration higher than that of the p⁻-type semiconductor regions EX2 are formed. The n⁺-type semiconductor region SD1 has an impurity concentration higher than that of the n⁻-type semiconductor region EX1, and has a junction depth deeper than that of the n⁻-type semiconductor region EX1. The p⁺-type semiconductor region SD2 has an impurity concentration higher than that of the p⁻-type semiconductor region EX2, and has a junction depth deeper than that of the p⁻-type semiconductor region EX2.

On a sidewall of each of the gate electrodes GE1 and GE2, a sidewall (sidewall spacer, sidewall insulating film) SW made of an insulator is formed. In the nMIS formation region 1A, the n⁻-type semiconductor region EX1 is formed so as to be aligned with the gate electrode GE1, and the n⁺-type semiconductor region SD1 is formed so as to be aligned with the sidewall SW provided on the sidewall of the gate electrode GE1. Also, in the pMIS formation region 1B, the p⁻-type semiconductor region EX2 is formed so as to be aligned with the gate electrode GE2, and the p⁺-type semiconductor region SD2 is formed so as to be aligned with the sidewall SW provided on the sidewall of the gate electrode GE2. More specifically, the n⁻-type semiconductor region EX1 is positioned under the sidewall SW formed on the sidewall of the gate electrode GE1 and is interposed between a channel region of the n-channel-type MISFET Qn and the n⁺-type semiconductor region SD1, and the p⁻-type semiconductor region EX2 is positioned under the sidewall SW formed on the sidewall of the gate electrode GE2 and is interposed between a channel region of the p-channel-type MISFET Qp and the p⁺-type semiconductor region SD2.

On the surfaces of the n⁺-type semiconductor regions SD1, the p⁺-type semiconductor regions SD2, and the silicon films 8, a metal silicide layer (metal silicide film) 10 similar to that of the first embodiment described above is formed. Although the formation of the metal silicide layer 10 can be omitted, if the metal silicide layer 10 is formed on the surfaces of n⁺-type semiconductor region SD1, the p⁺-type semiconductor region SD2, and the silicon film 8, diffusion resistance and contact resistance can be reduced. When the metal silicide layer 10 is formed on the surface of the silicon film 8, it can be regarded that the metal silicide layer 10 is formed on the gate electrodes GE1 and GE2 formed of a stacked film (stacked structure) of the metal film 7 and the silicon film 8 on the metal film 7. In another aspect, it can be regarded that the gate electrodes GE1 and GE2 are configured of a stacked film (stacked structure) of the metal film 7, the silicon film 8 on the metal film 7, and the metal silicide layer 10 on the silicon film 8 by including the metal silicide layer 10 in the gate electrodes GE1 and GE2.

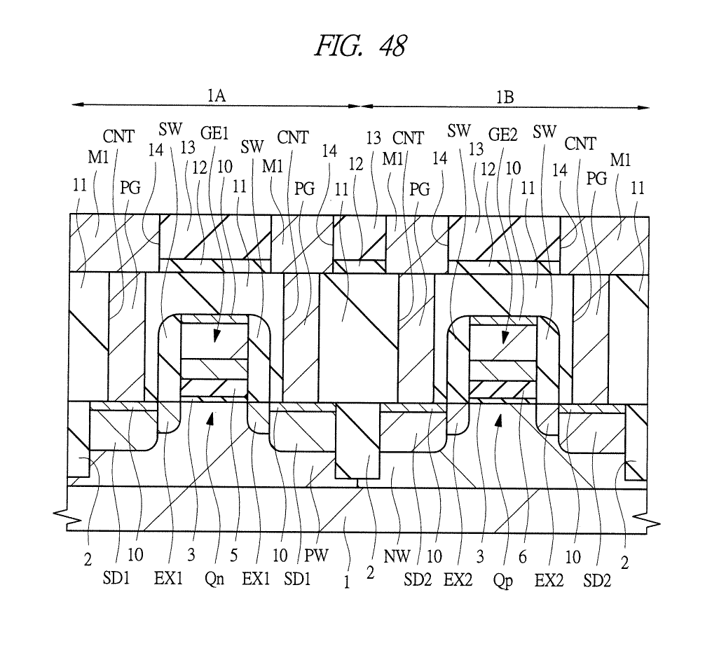

Furthermore, although an insulating film (interlayer insulating film) 11, a contact hole CNT, a plug PG, a stopper insulating film 12, an insulating film 13 and a wiring M1 (refer to FIG. 47 and FIG. 48 described below) described below and further a multilayer wiring structure in an upper layer are formed, the illustration and the description thereof are omitted here.

Next, a process of manufacturing the semiconductor device of the present embodiment as shown in FIG. 32 is described with reference to the drawings.

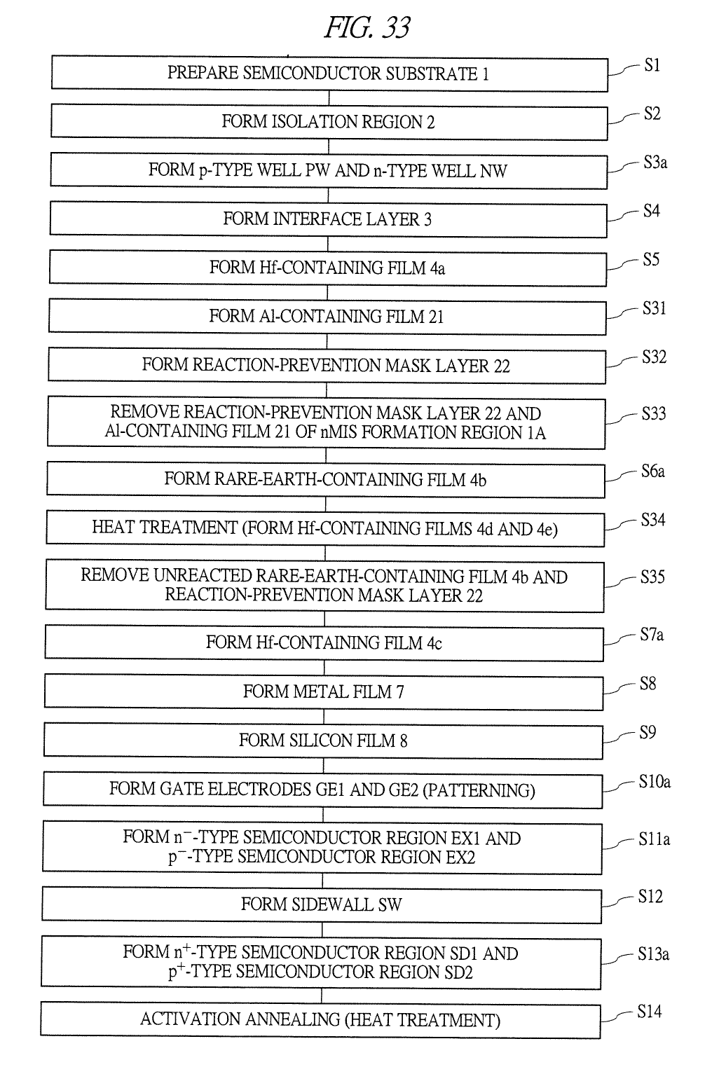

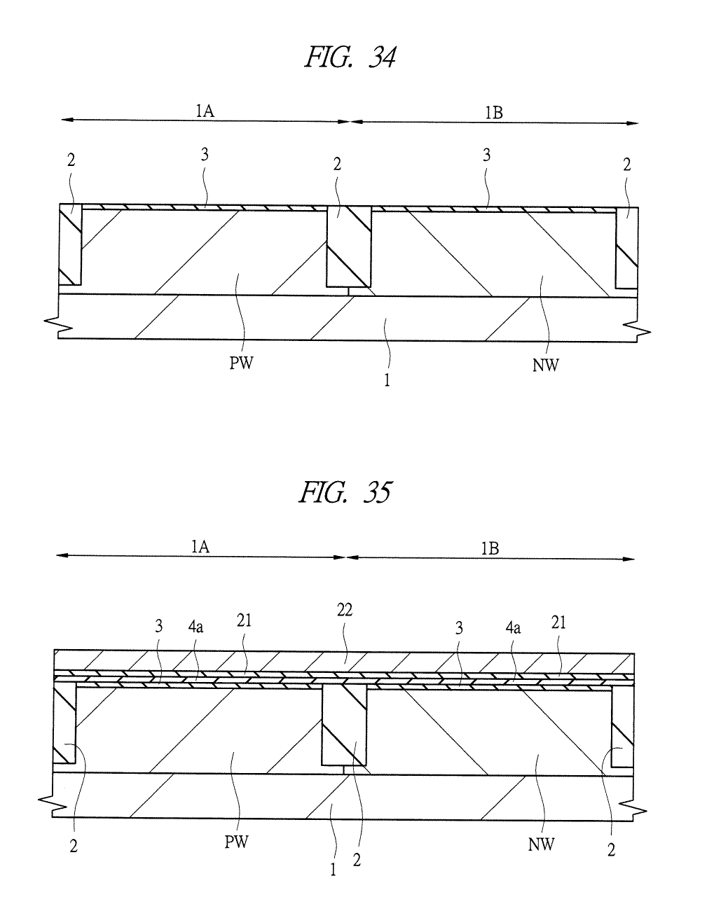

FIG. 33 is a manufacturing process flow diagram showing part of the process of manufacturing the semiconductor device of the present embodiment, and it corresponds to FIG. 2 of the first embodiment described above. FIG. 34 to FIG. 48 are sectional views of main parts of the semiconductor device of the present embodiment in the manufacturing process.

First, as shown in FIG. 34, the semiconductor substrate (semiconductor wafer) 1 similar to that of the first embodiment described above is prepared (made available) (step S1 of FIG. 33). The semiconductor substrate 1 on which the semiconductor device of the present embodiment is to be formed has the nMIS formation region 1A which is a region where an n-channel-type MISFET is to be formed and the pMIS formation region 1B which is a region where a p-channel-type MISFET is to be formed. Then, in the same manner as that of the first embodiment described above, the isolation regions 2 are formed on a main surface of the semiconductor substrate 1 (step S2 of FIG. 33).

Next, the p-type well PW is formed in the region of the semiconductor substrate 1 where the n-channel-type MISFET is to be formed (nMIS formation region 1A), and the n-type well NW is formed in the region where the p-channel-type MISFET is to be formed (pMIS formation region 1B) (step S3a of FIG. 33). In this step S3a, the p-type well PW is formed by performing ion implantation of p-type impurities such as boron (B), and the n-type well NW is formed by performing ion implantation of n-type impurities such as phosphorus (P) or arsenic (As). Also, before or after the p-type well PW and the n-type well NW are formed, ion implantation (so-called channel-dope ion implantation) for adjusting the threshold of the MISFET to be formed later can be performed if necessary to an upper layer part of the semiconductor substrate 1.

Next, a surface of the semiconductor substrate 1 is purified (cleaned) by removing a natural oxide film on the surface of the semiconductor substrate 1 by wet etching using hydrofluoric acid (HF) solution, or the like. By this means, the surface (silicon surface) of the semiconductor substrate 1 (p-type well PW and n-type well NW) is exposed.

Next, on the surface of the semiconductor substrate 1 (that is, the surfaces of the p-type well PW and the n-type well NW), the interface layer 3 similar to that of the first embodiment described above is formed in the same manner (step S4 of FIG. 33). Although this process of forming the interface layer 3 in step S4 can be omitted, it is more preferable to perform the process of forming the interface layer 3 in step S4, and the reason for this is similar to that of the first embodiment described above.

Next, as shown in FIG. 35, the Hf-containing film (Hf-containing layer) 4a similar to that of the first embodiment described above is formed on the main surface of the semiconductor substrate 1, that is, on the interface layer 3 (step S5 of FIG. 33). The material, film thickness, and film forming method of the Hf-containing film 4a are similar to those of the first embodiment described above, and therefore are not described here. In step S5, the Hf-containing film 4a is formed on the entire main surface of the semiconductor substrate 1, and is therefore formed in both of the nMIS formation region 1A and the pMIS formation region 1B. In the present embodiment, the Hf-containing film 4a is a film for forming the Hf-containing insulating films 5 and 6 described above, which are high dielectric constant gate insulating films of the n-channel-type MISFET Qn and the p-channel-type MISFET Qp.

Next, an Al-containing film (Al-containing layer) 21 is formed on the main surface of the semiconductor substrate 1, that is, on the Hf-containing film 4a (step S31 of FIG. 33). The Al-containing film 21 is a film for forming the Hf-containing insulating film 6 described above, which is a high dielectric constant gate insulating film of the p-channel-type MISFET Qp.

The Al-containing film 21 is a material film containing Al (aluminum). As the Al-containing film 21, an aluminum oxide film (AlO film, typically Al₂O₃ film) is most preferable in view of stability. Other than that, an aluminum oxynitride film (AlON film), an aluminum film (Al film), or the like can be used. The Al-containing film 21 can be formed by, for example, a sputtering method or an ALD method, and its film thickness (formed film thickness) can be set, preferably, within a range of 0.2 nm to 1 nm, for example, to about 0.5 nm.

Next, a reaction-prevention mask layer (mask layer) 22 is formed on the main surface of the semiconductor substrate 1, that is, on the Al-containing film 21 (step 32 of FIG. 33). This reaction-prevention mask layer 22 is provided to prevent the rare-earth-containing film 4b to be formed later from reacting with the Hf-containing film 4a and the Al-containing film 21 in the pMIS formation region 1B. In consideration of the function of this reaction prevention, a metal nitride film or a metal carbide film is preferable as the reaction-prevention mask layer 22, and a titanium nitride (TiN) film is particularly preferable. The reaction-prevention mask layer 22 can be formed by using a sputtering method or the like, and its film thickness can be set to, for example, about 5 nm to 20 nm. In step S32, the reaction-prevention mask layer 22 is formed on the entire main surface of the semiconductor substrate 1, and is therefore formed on the Al-containing film 21 in both of the nMIS formation region 1A and the pMIS formation region 1B.

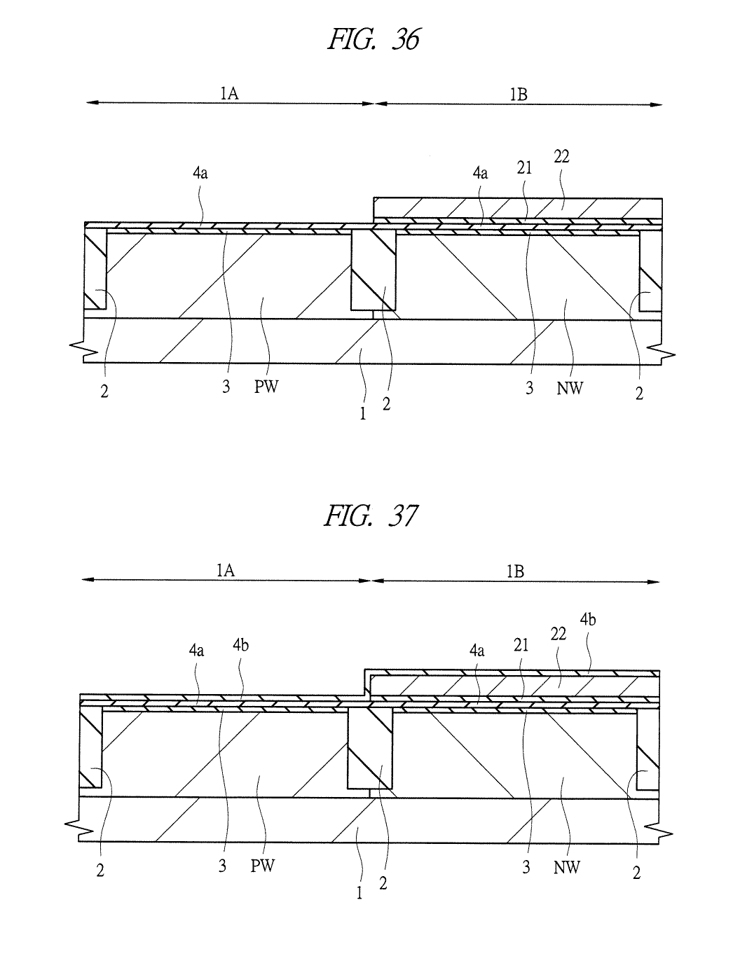

Next, as shown in FIG. 36, the reaction-prevention mask layer 22 and the Al-containing film 21 in the nMIS formation region 1A are selectively removed by etching (preferably, wet etching or by using both of dry etching and wet etching), and portions of the reaction-prevention mask layer 22 and the Al-containing film 21 in the pMIS formation region 1B are left (step S33 of FIG. 33). In this manner, the Hf-containing film 4a is exposed in the nMIS formation region 1A, and on the other hand, the state in which the Al-containing film 21 and the reaction-prevention mask layer 22 thereon are formed on the Hf-containing film 4a is maintained in the pMIS formation region 1B.

Specifically, in step S33, after a photoresist pattern (not shown) for covering the pMIS formation region 1B and exposing the nMIS formation region 1A is formed on the reaction-prevention mask layer 22, the reaction-prevention mask layer 22 in the nMIS formation region 1A is removed by etching with using this photoresist pattern as an etching mask. Subsequently, the Al-containing film 21 in the nMIS formation region 1A is removed by etching. Thereafter, the photoresist pattern is removed.

Next, as shown in FIG. 37, the rare-earth-containing film 4b is formed on the main surface of the semiconductor substrate 1 (step S6a of FIG. 33). The rare-earth-containing film 4b is a film for forming the Hf-containing insulating film 5 described above, which is a high dielectric constant gate insulating film of the n-channel-type MISFET Qn.

Since the portions of the reaction-prevention mask layer 22 and the Al-containing film 21 in the nMIS formation region 1A are removed and the portions of the reaction-prevention mask layer 22 and the Al-containing film 21 in the pMIS formation region 1B are left in the etching process in step S33 described above, the rare-earth-containing film 4b is formed on the Hf-containing film 4a in the nMIS formation region 1A and on the reaction-prevention mask layer 22 in the pMIS formation region 1B in step S6a. For this reason, the rare-earth-containing film 4b and the Hf-containing film 4a are in contact with each other in the nMIS formation region 1A, but the rare-earth-containing film 4b and the Al-containing film 21 (and Hf-containing film 4a) are in a state of not being in contact with each other in the pMIS formation region 1B because the reaction-prevention mask layer 22 is interposed therebetween. The material, film thickness, and film forming method of the rare-earth-containing film 4b are similar to those of the first embodiment described above, and therefore are not described here.

Next, a heat treatment is performed to the semiconductor substrate 1 (step S34 of FIG. 33). The heat treatment in step S34 can be performed preferably at a heat treatment temperature within a range of 600° C. to 1000° C. and in an inactive gas atmosphere (or may be performed in a nitrogen gas atmosphere).

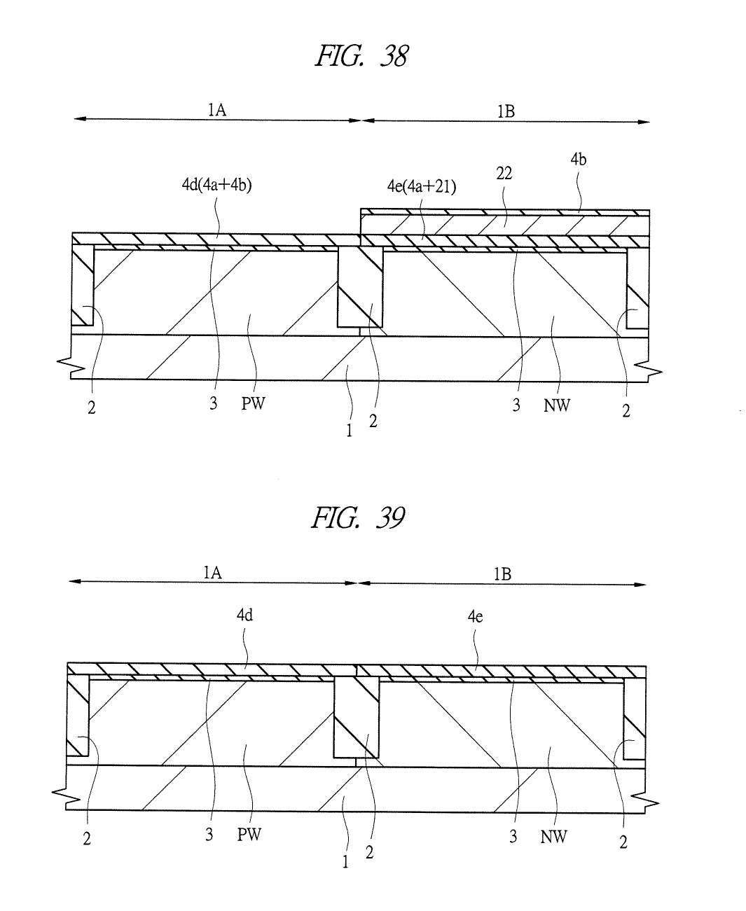

By this heat treatment in step S34, the Hf-containing film 4a and the rare-earth-containing film 4b react (mix, mixing, interdiffuse) with each other in the nMIS formation region 1A to form an Hf-containing film (reaction layer) 4d, which is a reaction layer (mixed layer, mixing layer) of the Hf-containing film 4a and the rare-earth-containing film 4b, as shown in FIG. 38. Also, by this heat treatment in step S34, the Hf-containing film 4a and the Al-containing film 21 react (mix, mixing, interdiffuse) with each other in the pMIS formation region 1B to form an Hf-containing film (reaction layer) 4e, which is a reaction layer (mixed layer, mixing layer) of the Hf-containing film 4a and the Al-containing film 21, as shown in FIG. 38.

The Hf-containing film 4d formed in the nMIS formation region 1A by the heat treatment in step S34 is similar to the Hf-containing film 4d formed in step S21 in the first embodiment described above, and therefore is not described here.

The Hf-containing film 4a contains hafnium (Hf) and oxygen (O) as main components, and the Al-containing film 21 contains Al (aluminum) as a main component. Therefore, the Hf-containing film 4e formed by the reaction of the Hf-containing film 4a and the Al-containing film 21 in the pMIS formation region 1B is an insulating film containing hafnium (Hf), oxygen (O), and aluminum (Al) as main components.

Also, when the Hf-containing film 4a contains not only hafnium (Hf) and oxygen (O) but also nitrogen (N), the Hf-containing film 4e contains not only hafnium (Hf), oxygen (O), and aluminum (Al) but also nitrogen (N). Also, when the Hf-containing film 4a contains not only hafnium (Hf) and oxygen (O) but also Si (silicon), the Hf-containing film 4e contains not only hafnium (Hf), oxygen (O), and aluminum (Al) but also Si (silicon).

Note that, since the rare-earth-containing film 4b and the Al-containing film 21 (and Hf-containing film 4a) are not in contact with each other in the pMIS formation region 1B because the reaction-prevention mask layer 22 is interposed therebetween, the Al-containing film 21 and the Hf-containing film 4a do not react with the rare-earth-containing film 4b, and the rare-earth element configuring the rare-earth-containing film 4b is not introduced (diffused) to the Hf-containing film 4e in the pMIS formation region 1B.

For this reason, when the Al-containing film 21 is an aluminum oxide film or an aluminum film, the Hf-containing film 4e is a film with the following composition depending on the type of the Hf-containing film 4a. That is, when the Hf-containing film 4a is an HfO film, the Hf-containing film 4e is an HfAlO film. When the Hf-containing film 4a is an HfON film, the Hf-containing film 4e is an HfAlON film. Furthermore, when the Hf-containing film 4a is an HfSiO film, the Hf-containing film 4e is an HfAlSiO film. Still further, when the Hf-containing film 4a is an HfSiON film, the Hf-containing film 4e is an HfAlSiON film. When the Al-containing film 21 is an aluminum oxynitride film, the Hf-containing film 4e is a film with the following composition depending on the type of the Hf-containing film 4a. That is, when the Hf-containing film 4a is an HfO film, the Hf-containing film 4e is an HfAlON film. When the Hf-containing film 4a is an HfON film, the Hf-containing film 4e is an HfAlON film. Furthermore, when the Hf-containing film 4a is an HfSiO film, the Hf-containing film 4e is an HfAlSiON film. Still further, when the Hf-containing film 4a is an HfSiON film, the Hf-containing film 4e is an HfAlSiON film.

However, the Hf-containing film 4a and the Al-containing film 21 are formed sequentially from below, and they react with each other to form the Hf-containing film 4e. The Hf-containing film 4a contains Hf (hafnium) but does not contain Al (aluminum), and the Al-containing film 21 contains Al (aluminum) but does not contain Hf (hafnium). For this reason, the composition of the Hf-containing film 4e formed in the pMIS formation region 1B is not uniform in a film thickness direction, and the composition distribution of the Hf-containing film 4a and the Al-containing film 21 before the reaction is maintained to some degree. This will be described below in more detail.

Also, as with step S21 of the first embodiment described above, also in step S34 of the present embodiment, the Hf-containing film 4a and the rare-earth-containing film 4b are formed sequentially from below, and they react with each other to form the Hf-containing film 4d. Therefore, as with the Hf-containing film 4d of the first embodiment described above, the composition of the Hf-containing film 4d formed in the nMIS formation region 1A is not uniform in the film thickness direction, and the composition distribution of the Hf-containing film 4a and the rare-earth-containing film 4b before the reaction is maintained to some degree.

Furthermore, since the rare-earth-containing film 4b is formed on the reaction-prevention mask layer 22 in the pMIS formation region 1B, this rare-earth-containing film 4b in the pMIS formation region 1B hardly reacts with the reaction-prevention mask layer 22 and is left. More specifically, a material stable even at the heat treatment temperature in the heat treatment process in step S24 and difficult to react with any of the Hf-containing film 4a, the Al-containing film 21, and the rare-earth-containing film 4b is selected as a material of the reaction-prevention mask layer 22. As a material like this, metal nitride and metal carbide are appropriate, and titanium nitride (TiN) is particularly suitable.

Still further, when the interface layer 3 is formed in step S4 before the Hf-containing film 4a is formed in step S5, it is preferable that the reaction between the Hf-containing film 4a and the interface layer 3 therebelow is suppressed at the time of the heat treatment in step S34 so as to leave the silicon oxide film or the silicon oxynitride film as the interface layer 3. By this means, a good device in which the degradation in driving force and reliability is suppressed can be fabricated.

After the heat treatment process in step S34 is performed, as shown in FIG. 39, a portion of the rare-earth-containing film 4b not reacting in the heat treatment process in step S34 (unreacted portion of the rare-earth-containing film 4b) is removed by etching (preferably, wet etching), and then the reaction-prevention mask layer 22 is removed by etching (preferably, wet etching) (step S25 of FIG. 33). In this manner, the Hf-containing film 4d is exposed in the nMIS formation region 1A, and the Hf-containing film 4e is exposed in the pMIS formation region 1B.

Also, it is preferable to perform the heat treatment process in step S34 in the present embodiment, but as another embodiment, the heat treatment process in step S34 can be omitted if at least part of the rare-earth-containing film 4b can be left in a layered shape on the Hf-containing film 4a of the n-channel-type MISFET Qn when the rare-earth-containing film 4b and the reaction-prevention mask layer 22 in the pMIS formation region 1B are removed in step S35.

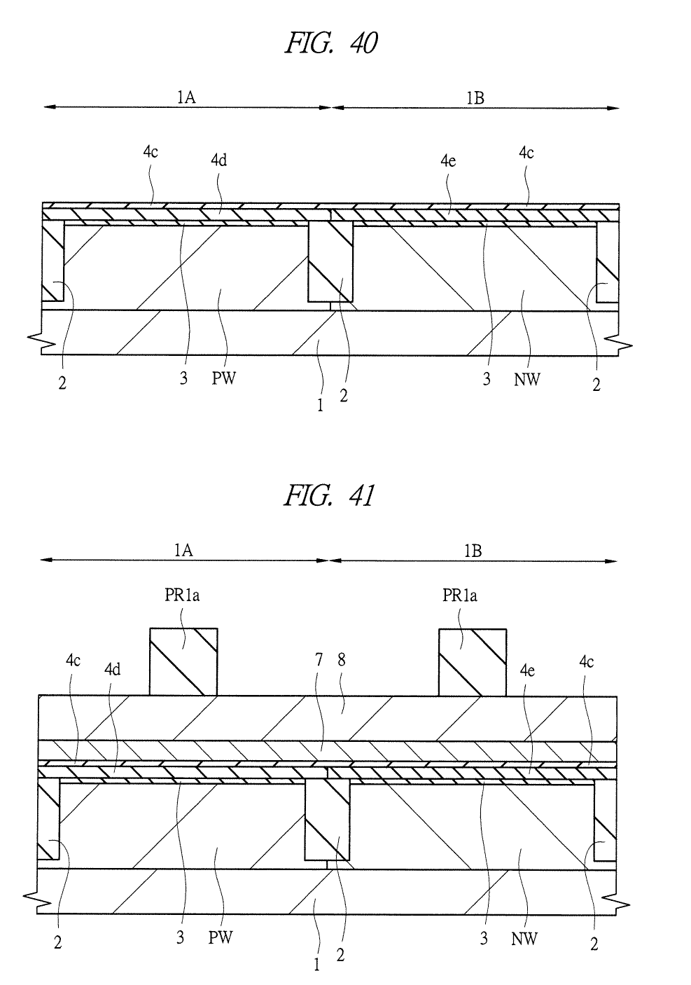

Next, as shown in FIG. 40, the Hf-containing film 4c is formed on the main surface of the semiconductor substrate 1, that is, on the Hf-containing film 4d in the nMIS formation region 1A and the Hf-containing film 4e in the pMIS formation region 1B (step S7a of FIG. 33). The material, film thickness, and film forming method of the Hf-containing film 4c are similar to those of the first embodiment described above, and therefore are not described here. In step S7a, the Hf-containing film 4c is formed on the Hf-containing film 4d in the nMIS formation region 1A, and the Hf-containing film 4c is formed on the Hf-containing film 4e in the pMIS formation region 1B. In the present embodiment, the Hf-containing film 4c is a film for forming the Hf-containing insulating films 5 and 6 described above, which are high dielectric constant gate insulating films of the n-channel-type MISFET Qn and the p-channel-type MISFET Qp.

Next, as shown in FIG. 41, the metal film 7 for a metal gate (metal gate electrode) is formed on the main surface of the semiconductor substrate 1, that is, on the Hf-containing film 4c (step S8 of FIG. 33). The material, film thickness, and film forming method of the metal film 7 are similar to those of the first embodiment described above, and therefore are not described here.

Next, a silicon film 8 similar to that of the first embodiment described above is formed on the main surface of the semiconductor substrate 1, that is, on the metal film 7 (step S9 of FIG. 33). It is possible to omit this process of forming the silicon film 8 in step S9, but it is more preferable to perform the process of forming the silicon film 8 in step S9, and the reason for this is similar to that of the first embodiment described above.

Through the processes so far, the interface layer 3, the Hf-containing film 4d, the Hf-containing film 4c, the metal film 7, and the silicon film 8 are in the state of being stacked sequentially from below on the semiconductor substrate 1 (p-type well PW) in the nMIS formation region 1A, and the interface layer 3, the Hf-containing film 4e, the Hf-containing film 4c, the metal film 7, and the silicon film 8 are in the state of being stacked sequentially from below on the semiconductor substrate 1 (n-type well NW) in the pMIS formation region 1B.

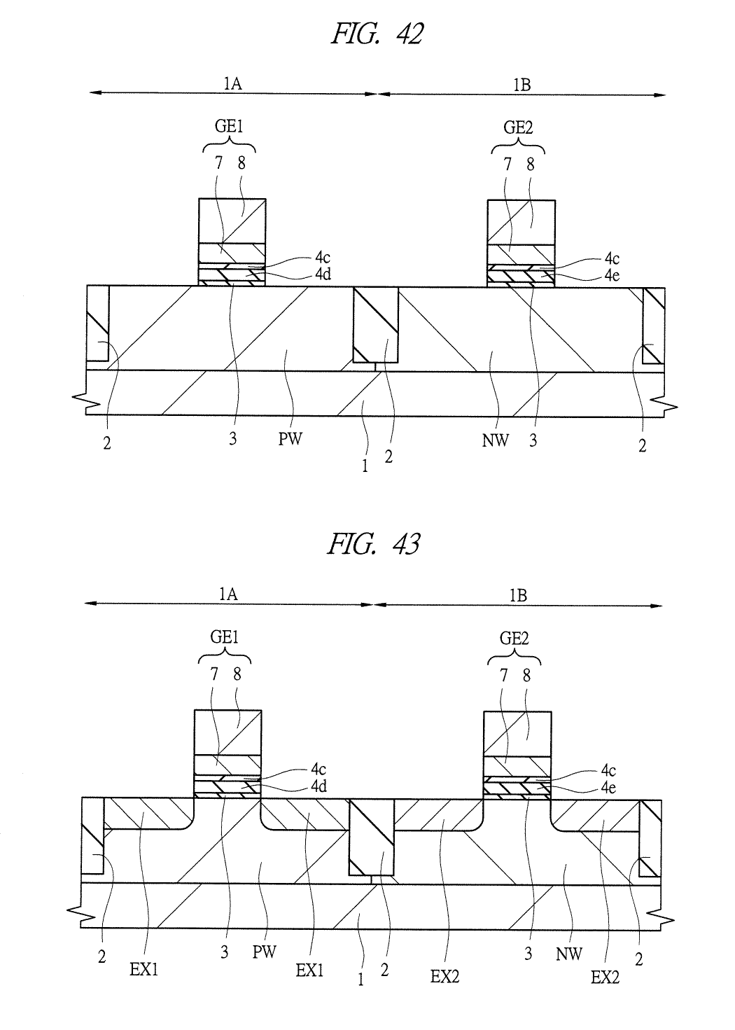

Next, as shown in FIG. 41, a photoresist pattern PR1a is formed on the silicon film 8 by using a photolithography method. Then, with using this photoresist pattern PR1a as an etching mask, the stacked film of the silicon film 8 and the metal film 7 is patterned by etching (preferably, dry etching), thereby forming the gate electrodes GE1 and GE2 formed of the metal film 7 and the silicon film 8 on the metal film 7 as shown in FIG. 42 (step S10a of FIG. 33). Thereafter, the photoresist pattern PR1a is removed. FIG. 42 shows the state in which the photoresist pattern PR1a has been removed.

The gate electrode GE1 is formed on the Hf-containing film 4c in the nMIS formation region 1A, and the gate electrode GE2 is formed on the Hf-containing film 4c in the pMIS formation region 1B. More specifically, the gate electrode GE1 formed of the metal film 7 and the silicon film 8 on the metal film 7 is formed on the surface of the p-type well PW in the nMIS formation region 1A via a stacked film of the interface layer 3, the Hf-containing film 4d, and the Hf-containing film 4c, and the gate electrode GE2 formed of the metal film 7 and the silicon film 8 on the metal film 7 is formed on the surface of the n-type well NW in the pMIS formation region 1B via a stacked film of the interface layer 3, the Hf-containing film 4e, and the Hf-containing film 4c.

It is more preferable to perform wet etching for removing portions of the Hf-containing film 4c, the Hf-containing film 4d, and the Hf-containing film 4e not covered with the gate electrodes GE1 and GE2 after the dry etching process for patterning the silicon film 8 and the metal film 7 in step S10a. The Hf-containing film 4c and the Hf-containing film 4d positioned below the gate electrode GE1 and the Hf-containing film 4c and the Hf-containing film 4e positioned below the gate electrode GE2 are left without being removed by the dry etching in step S10a and wet etching thereafter. On the other hand, the portions of the Hf-containing film 4c and the Hf-containing film 4d not covered with the gate electrode GE1 and the portions of the Hf-containing film 4c and the Hf-containing film 4e not covered with the gate electrode GE2 are removed by the dry etching for patterning the silicon film 8 and the metal film 7 in step S10a and wet etching thereafter.

Next, as shown in FIG. 43, the n⁻-type semiconductor regions EX1 are formed by performing ion implantation of n-type impurities such as phosphorus (P) or arsenic (As) in the regions on both sides of the gate electrode GE1 of the p-type well PW in the nMIS formation region 1A, and the p⁻-type semiconductor regions EX2 are formed by performing ion implantation of p-type impurities such as boron (B) in the regions on both sides of the gate electrode GE2 of the n-type well NW in the pMIS formation region 1B (step S10a of FIG. 33). At the time of the ion implantation for forming the n⁻-type semiconductor regions EX1, the pMIS formation region 1B is covered with a photoresist film (not shown) as an ion implantation inhibiting mask, and the ion implantation is performed to the semiconductor substrate 1 (p-type well PW) of the nMIS formation region 1A with using the gate electrode GE1 as a mask. Also, at the time of the ion implantation for forming the p⁻-type semiconductor regions EX2, the nMIS formation region 1A is covered with another photoresist film (not shown) as an ion implantation inhibiting mask, and the ion implantation is performed to the semiconductor substrate 1 (n-type well NW) of the pMIS formation region 1B with using the gate electrode GE2 as a mask. Either of the n⁻-type semiconductor regions EX1 and p⁻-type semiconductor regions EX2 may be formed first.

Also, ion implantation for forming a halo region can be performed before or after the formation of the n⁻-type semiconductor regions EX1 and the p⁻-type semiconductor regions EX2. When a halo region (not shown) is formed, the halo region (p-type halo region) is formed so as to enclose the n⁻-type semiconductor region EX1 in the nMIS formation region 1A, and the halo region (n-type halo region) is formed so as to enclose the p⁻-type semiconductor region EX2 in the pMIS formation region 1B.

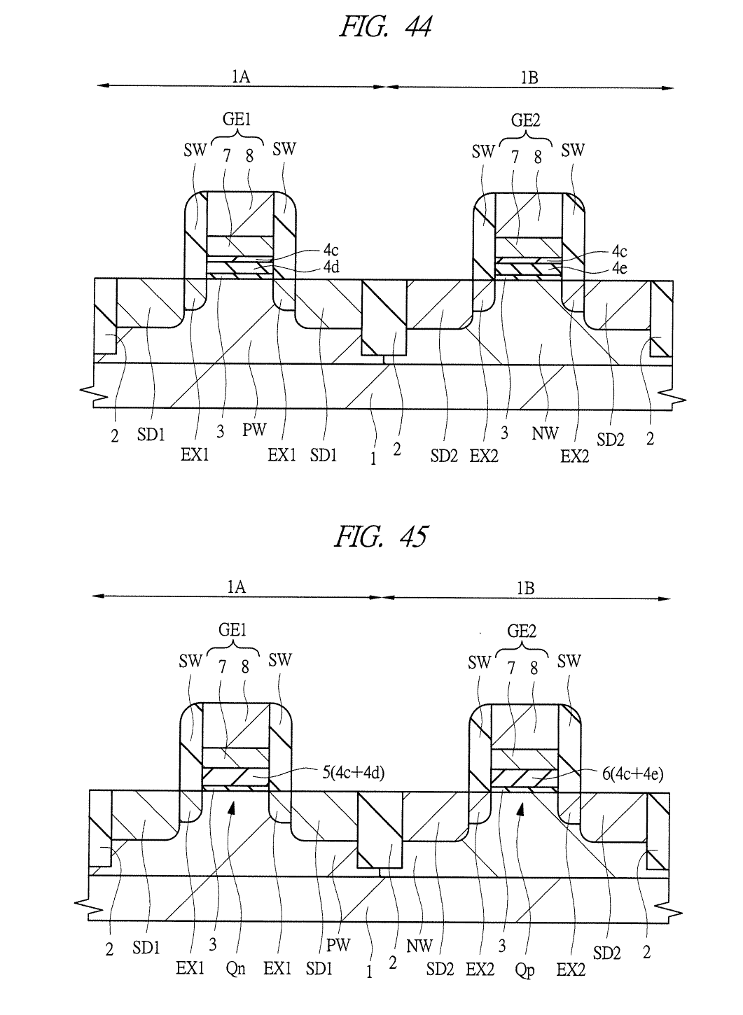

Next, as shown in FIG. 44, the sidewalls SW made of an insulator are formed on the sidewalls of the gate electrodes GE1 and GE2 in the same manner as that of the first embodiment described above (step S12 of FIG. 33).

Next, the n⁺-type semiconductor regions SD1 are formed by ion implantation in the p-type well PW in the nMIS formation region 1A, and the p⁺-type semiconductor regions SD2 are formed by another ion implantation in the n-type well NW in the pMIS formation region 1B (step S13 of FIG. 33).

The n⁺-type semiconductor regions SD1 can be formed by performing ion implantation of n-type impurities such as phosphorous (P) or arsenic (As) in the regions on both sides of the gate electrode GE1 and the sidewalls SW of the p-type well PW in the nMIS formation region 1A. The n⁺-type semiconductor region SD1 has an impurity concentration higher than that of the n⁻-type semiconductor region EX1, and has a junction depth deeper than that of the n⁻-type semiconductor region EX1. At the time of the ion implantation for forming the n⁺-type semiconductor regions SD1, the pMIS formation region 1B is covered with a photoresist film (not shown) as an ion implantation inhibiting mask, and the ion implantation is performed to the semiconductor substrate 1 (p-type well PW) of the nMIS formation region 1A with using the gate electrode GE1 and the sidewalls SW on its sidewalls as a mask. For this reason, the n⁻-type semiconductor regions EX1 are formed so as to be aligned with the gate electrode GE1, and the n⁺-type semiconductor regions SD1 are formed so as to be aligned with the sidewalls SW on the sidewalls of the gate electrode GE1.

The p⁺-type semiconductor regions SD2 can be formed by performing ion implantation of p-type impurities such as boron (B) in the regions on both sides of the gate electrode GE2 and the sidewalls SW of the n-type well NW in the pMIS formation region 1B. The p⁺-type semiconductor region SD2 has an impurity concentration higher than that of the p⁻-type semiconductor region EX2, and has a junction depth deeper than that of the p⁻-type semiconductor region EX2. At the time of the ion implantation for forming the p⁺-type semiconductor regions SD2, the nMIS formation region 1A is covered with another photoresist film (not shown) as an ion implantation inhibiting mask, and the ion implantation is performed to the semiconductor substrate 1 (n-type well NW) in the pMIS formation region 1B with using the gate electrode GE2 and the sidewalls SW on its sidewalls as a mask. For this reason, the p⁻-type semiconductor regions EX2 are formed so as to be aligned with the gate electrode GE2, and the p⁺-type semiconductor regions SD2 are formed so as to be aligned with the sidewalls SW on the sidewalls of the gate electrode GE2. Either of the n⁺-type semiconductor regions SD1 and p⁺-type semiconductor regions SD2 may be formed first.

The silicon film 8 configuring the gate electrode GE1 in the nMIS formation region 1A can be an n-type silicon film by introducing n-type impurities in the ion implanting process for forming the n⁻-type semiconductor regions EX1 and the ion implanting process for forming the n⁺-type semiconductor regions SD1. Also, the silicon film 8 configuring the gate electrode GE2 in the pMIS formation region 1B can be a p-type silicon film by introducing p-type impurities in the ion implanting process for forming the p-type semiconductor regions EX2 and the ion implanting process for forming the p⁺-type semiconductor regions SD2.

Note that the n⁺-type semiconductor regions SD1 function as source and drain regions of the n-channel-type MISFET Qn and the p⁺-type semiconductor regions SD2 function as source and drain regions of the p-channel-type MISFET Qp. For this reason, the process of forming the n⁺-type semiconductor regions SD1 in step S13a can be regarded as a process of performing ion implantation for forming the source and drain regions of the n-channel-type MISFET Qn, and the process of forming the p⁺-type semiconductor regions SD2 in step S13a can be regarded as a process of performing ion implantation for forming the source and drain regions of the p-channel-type MISFET Qp.

After the ion implantation for forming the n⁺-type semiconductor regions SD1 and the ion implantation for forming the p⁺-type semiconductor region SD2 are performed in step S13a, a heat treatment (annealing process, activation annealing) for activating the introduced impurities is performed (step S14 of FIG. 33). The impurities introduced to the n⁻-type semiconductor regions EX1, the p⁻-type semiconductor regions EX2, the n⁺-type semiconductor regions SD1, the p⁺-type semiconductor regions SD2, the silicon film 8, and others in the ion implantation in steps S11a and S13a can be activated by the heat treatment in step S14. The conditions of the heat treatment in step S14 are similar to those of the first embodiment described above, and therefore are not described here.

Since the heat treatment in step S14 is a heat treatment at a high temperature, the Hf-containing film 4d and the Hf-containing film 4c react (mix, mixing, interdiffuse) with each other in the nMIS formation region 1A, and the Hf-containing film 4e and the Hf-containing film 4c react (mix, mixing, interdiffuse) with each other in the pMIS formation region 1B. More specifically, as shown in FIG. 45, the Hf-containing film 4d and the Hf-containing film 4c react (mix, mixing, interdiffuse) with each other in the nMIS formation region 1A to form the Hf-containing insulating film 5, and the Hf-containing film 4e and the Hf-containing film 4c react (mix, mixing, interdiffuse) with each other in the pMIS formation region 1B to form the Hf-containing insulating film 6.

The Hf-containing insulating film 5 formed in the nMIS formation region 1A by the heat treatment in step S14 is similar to the Hf-containing insulating film 5 formed in step S14 in the first embodiment described above, and therefore is not described here.

In the pMIS formation region 1B, the Hf-containing film 4a and the Al-containing film react with each other by the heat treatment in step S34, and the Hf-containing film 4e, which is a reaction layer of both films, is formed. In the heat treatment in step S14, this Hf-containing film 4e and the Hf-containing film 4c react with each other to form the Hf-containing insulating film 6. For this reason, the Hf-containing insulating film 6 is an insulating film containing the element configuring the Hf-containing film 4a, the element configuring the Al-containing film 4b, and the element configuring the Hf-containing film 4c, and this is the same irrespectively of the presence or absence of the heat treatment in step S34. Since the Hf-containing film 4a and the Hf-containing film 4c contain hafnium (Hf) and oxygen (O) as main components and the Al-containing film 21 contains aluminum (Al) as a main component, the Hf-containing insulating film 6 is an insulating film containing hafnium (Hf), oxygen (O), and aluminum (Al) as main components.

Also, when one or both of the Hf-containing film 4a and the Hf-containing film 4c contain not only hafnium (Hf) and oxygen (O) but also nitrogen (N), the Hf-containing insulating film 6 contains not only hafnium (Hf), oxygen (O), and aluminum (Al) but also nitrogen (N). Also, when one or both of the Hf-containing film 4a and the Hf-containing film 4c contain not only hafnium (Hf) and oxygen (O) but also Si (silicon), the Hf-containing insulating film 6 contains not only hafnium (Hf), oxygen (O), and aluminum (Al) but also Si (silicon).

Also, the Al-containing film 21 is preferably an aluminum oxide film as described above, but an aluminum oxynitride film or an aluminum film can also be used. Since the Hf-containing films 4a and 4c contain oxygen (O), in any of the cases where the Al-containing film 21 is the aluminum oxide film, the aluminum oxynitride film, or the aluminum film, the Hf-containing insulating film 6 contains oxygen (O). Also, when the Al-containing film 21 is an aluminum oxynitride film, the Hf-containing insulating film 6 contains nitrogen (N).

For this reason, when the Al-containing film 21 is an aluminum oxide film or an aluminum film, the Hf-containing insulating film 6 is a film with the following composition depending on the type of the Hf-containing films 4a and 4c. That is, when the Hf-containing films 4a and 4c are both HfO films, the Hf-containing insulating film 6 is an HfAlO film. Also, when one of the Hf-containing films 4a and 4c is an HfO film and the other is an HfON film and when the Hf-containing films 4a and 4c are both HfON films, the Hf-containing insulating film 6 is an HfAlON film. Furthermore, when one of the Hf-containing films 4a and 4c is an HfO film and the other is an HfSiO film and when the Hf-containing films 4a and 4c are both HfSiO films, the Hf-containing insulating film 6 is an HfAlSiO film. Still further, when one of the Hf-containing films 4a and 4c is an HfON film and the other is an HfSiO film, the Hf-containing insulating film 6 is an HfAlON film. Still further, when at least one of the Hf-containing films 4a and 4c is an HfSiON film, even if the other of the Hf-containing films 4a and 4c is any an HfO film, an HfON film, an HfSiO film, and an HfSiON film, the Hf-containing insulating film 6 is an HfAlSiON film.

Also, when the Al-containing film 21 is an aluminum oxynitride film, the Hf-containing insulating film 6 is a film with the following composition depending on the type of the Hf-containing films 4a and 4c. That is, when the Hf-containing films 4a and 4c are both HfO films, when one of the Hf-containing films 4a and 4c is an HfO film and the other is an HfON film, and when the Hf-containing films 4a and 4c are both HfON films, the Hf-containing insulating film 6 is an HfAlON film. Also, when at least one of the Hf-containing films 4a and 4c is an HfSiO film or an HfSiON film, even if the other of the Hf-containing films 4a and 4c is any of an HfO film, an HfON film, an HfSiO film, and an HfSiON film, the Hf-containing insulating film 6 is an HfAlSiON film.

However, the Hf-containing film 4a, the rare-earth-containing film 4b, and the Hf-containing film 4c are formed sequentially from below, and they react with one another to form the Hf-containing insulating film 6. The Hf-containing films 4a and 4c contain Hf (hafnium) but do not contain any of a rare-earth element and aluminum (Al), and the Al-containing film 21 contains Al (aluminum) but does not contain Hf (hafnium). For this reason, the composition of the formed Hf-containing insulating film 6 in a film thickness direction is not uniform, and the composition distribution of the Hf-containing film 4a, the Al-containing film 21, and Hf-containing film 4c before the reaction is maintained to some degree. This will be described below in more detail.

In this manner, the structure as shown in FIG. 45 is obtained, and the n-channel-type MISFET Qn is formed as a field effect transistor in the nMIS formation region 1A, and the p-channel-type MISFET Qp is formed as a field effect transistor in the pMIS formation region 1B.

The gate electrode GE1 functions as a gate electrode (metal gate electrode) of the n-channel-type MISFET Qn, and the Hf-containing insulating film 5 (and the interface layer 3 therebelow) below the gate electrode GE1 functions as a gate insulating film of the n-channel-type MISFET Qn. Also, an n-type semiconductor region (impurity diffusion layer) functioning as a source or a drain of the n-channel-type MISFET Qn is formed of the n⁺-type semiconductor region SD1 and the n⁻-type semiconductor region EX1. Further, the gate electrode GE2 functions as a gate electrode (metal gate electrode) of the p-channel-type MISFET Qp, and the Hf-containing insulating film 6 (and the interface layer 3 therebelow) below the gate electrode GE2 functions as a gate insulating film of the p-channel-type MISFET Qp. Also, a p-type semiconductor region (impurity diffusion layer) functioning as a source or a drain of the p-channel-type MISFET Qp is formed of the p⁺-type semiconductor region SD2 and the p⁻-type semiconductor region EX2.

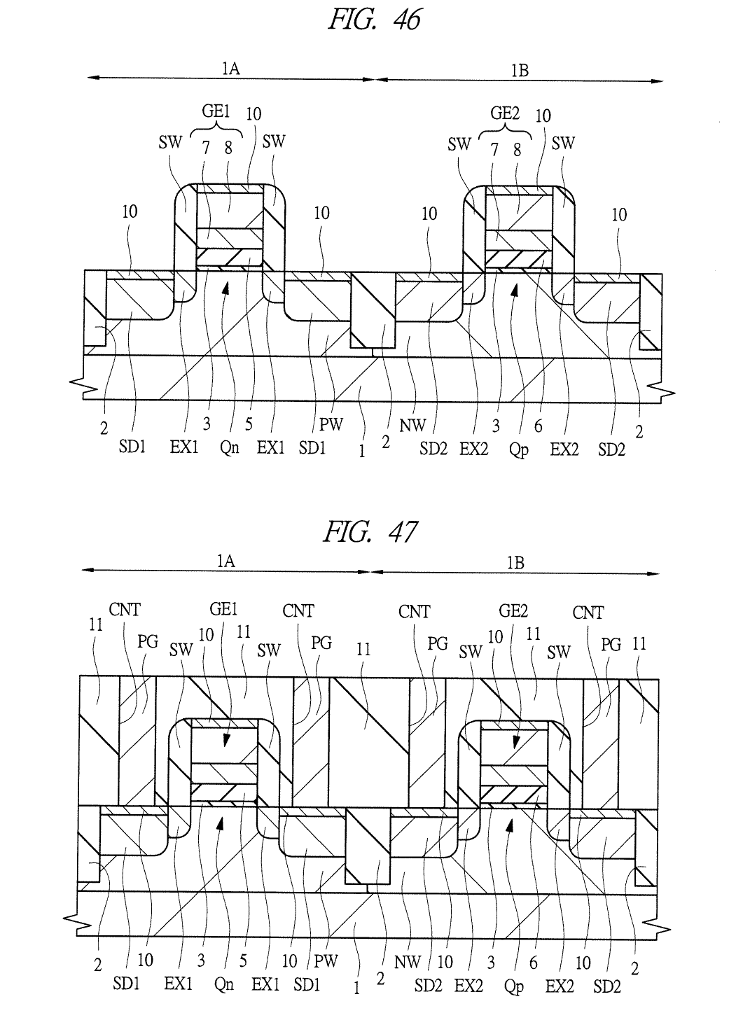

Next, as shown in FIG. 46, the metal silicide layer 10 similar to that of the first embodiment described above is selectively formed on the surfaces of the n⁺-type semiconductor regions SD1, the p⁺-type semiconductor regions SD2, and the silicon films 8 (silicon films 8 configuring the gate electrodes GE1 and GE2) by using a salicide process similar to that of the first embodiment described above. Specifically, after the surfaces of the n⁺-type semiconductor regions SD1, the p⁺-type semiconductor regions SD2, and others are cleaned, a metal film made of Co (cobalt), Ni (nickel), Pt (platinum), or the like is formed on the main surface of the semiconductor substrate 1 including the surfaces of the n⁺-type semiconductor regions SD1, the p⁺-type semiconductor regions SD2, and the silicon films 8. Then, this metal film is caused to react with upper layer portions of the n⁺-type semiconductor regions SD1, the p⁺-type semiconductor regions SD2, and the silicon films 8 to form the metal silicide layers 10, and then an unreacted portion of this metal film can be removed by wet etching or the like. The metal silicide layer 10 has an effect of decreasing diffusion resistance and contact resistance, but its formation can be omitted if not necessary.

The subsequent processes are approximately similar to those of the first embodiment described above. That is, as shown in FIG. 47, the insulating film 11 similar to that of the first embodiment described above is formed on the main surface of the semiconductor substrate 1 so as to cover the gate electrodes GE1 and GE2 and the sidewalls SW. Then, after the contact holes CNT are formed in the insulating film 11 in the same manner as that of the first embodiment described above, the plugs PG are formed in the contact holes CNT in the same manner as that of the first embodiment described above. The contact holes CNT and the plugs PG filling them are formed on the n⁺-type semiconductor regions SD1, the p⁺-type semiconductor regions SD2, the gate electrodes GE1 and GE2, and others. Thereafter, as shown in FIG. 48, the stopper insulating film 12 and the insulating film 13 for forming wiring similar to those of the first embodiment described above are sequentially formed on the insulating film 11 in which the plugs PG have been buried, and then, the wiring M1 of a first layer is formed by a single damascene method in the same manner that of the first embodiment described above. The wiring M1 is formed so as to fill a wiring trench 14 formed in the insulating film 13 and the stopper insulating film 12. The wiring M1 is electrically connected via the plugs PG to the n⁺-type semiconductor regions SD1 and the p⁺-type semiconductor regions SD2 for the source and drain of the n-channel-type MISFET Qn and the p-channel-type MISFET Qp, and others. Thereafter, wirings of second and upper layers are formed by a dual damascene method or the like, but the illustrations and descriptions thereof are omitted here. Furthermore, as with the first embodiment described above, also in the present embodiment, the wiring M1 and the wirings of upper layers are not limited to damascene wirings, but can be formed by patterning a conductive film for wiring. For example, the wirings can be tungsten wirings or aluminum wirings.

The structure in the nMIS formation region 1A of the semiconductor device of the present embodiment is the same as the structure of the region where the n-channel-type MISFET Qn of the semiconductor device of the first embodiment described above is formed. Also, the process of manufacturing the nMIS formation region 1A of the semiconductor device of the present embodiment is basically the same as the manufacturing process in the process flow of FIG. 17 of the first embodiment described above. More specifically, the process flow obtained by adding the steps S31, S32, S33, and S35 described above to the process flow of FIG. 17 described above corresponds to the process of manufacturing the nMIS formation region 1A of the semiconductor device of the present embodiment, and the heat treatment process in step S34 of the present embodiment corresponds to the heat treatment process in step S21 of the first embodiment described above. The steps S31, S32, S33, and S35 described above are processes for forming the p-channel-type MISFET Qp in the pMIS formation region 1B, and do not substantially contribute to the formation of the n-channel-type MISFET Qn in the nMIS formation region 1A. For this reason, the process of manufacturing the nMIS formation region 1A in the present embodiment (process of forming the n-channel-type MISFET Qn) can be substantially regarded as the same as that of the first embodiment described above.

For this reason, effects similar to those of the first embodiment described above can be achieved in the present embodiment with respect to the n-channel-type MISFET Qn in the nMIS formation region 1A. Therefore, effects overlapping those of the first embodiment described above are not repeatedly described, and effects unique to the present embodiment are described here.

In the present embodiment, by introducing the rare-earth element to the Hf-containing insulating film 5, which is an Hf-based gate insulating film of the n-channel-type MISFET Qn, the threshold of the n-channel-type MISFET Qn can be decreased, and by introducing Al (aluminum) to the Hf-containing insulating film 6, which is an Hf-based gate insulating film of the p-channel-type MISFET Qp, the threshold of the p-channel-type MISFET Qp can be decreased. Accordingly, the thresholds of both of the n-channel-type MISFET Qn and the p-channel-type MISFET Qp can be decreased.

As described in the first embodiment described above, when the rare-earth element is introduced to the Hf-based gate insulating film, since this rare-earth element tends to be diffused to a metal gate electrode and semiconductor substrate side, various inconveniences described above occur. This phenomenon is unique to the case in which the rare-earth element is introduced to the Hf-based gate insulating film, and similar inconveniences do not occur when Al (aluminum) is introduced to the Hf-based gate insulating film. This is because the rare-earth element tends to be diffused to a metal gate electrode and semiconductor substrate side, but Al is less prone to be diffused to a metal gate electrode and semiconductor substrate side.

As described also in the first embodiment described above, to form the Hf-containing insulating film 5, which is a high dielectric constant gate insulating film of the n-channel-type MISFET Qn, three layers, that is, the Hf-containing film 4a, the rare-earth-containing film 4b, and the Hf-containing film 4c are used, and these are formed in the order of the Hf-containing film 4a, the rare-earth-containing film 4b, and the Hf-containing film 4c, thereby preventing inconveniences (problems) due to the diffusion of the rare-earth element to the metal gate electrode and semiconductor substrate side and achieving the improvement in characteristics (performance). On the other hand, since this problem does not arise in the p-channel-type MISFET Qp, in terms of the characteristics (performance), three layers, that is, the Hf-containing film 4a, the Al-containing film 21, and the Hf-containing film 4c may be used to form the Hf-containing insulating film 6, or two layers, that is, the Hf-containing film 4a and the Al-containing film 21 may be used to form the Hf-containing insulating film 6.

However, in consideration of the simplification of the CMISFET manufacturing process (decrease in the number of manufacturing processes), to form the Hf-containing insulating film 6 of the p-channel-type MISFET Qp, it is preferable that three layers, that is, the Hf-containing film 4a, the Al-containing film 21, and the Hf-containing film 4c are used and these are formed in the order of the Hf-containing film 4a, the Al-containing film 21, and the Hf-containing film 4c like in the present embodiment. More specifically, in accordance with the use of the three layers, that is, the Hf-containing film 4a, the rare-earth-containing film 4b, and the Hf-containing film 4c to form the Hf-containing insulating film 5 of the n-channel-type MISFET Qn, three layers, that is, the Hf-containing film 4a, the Al-containing film 21, and the Hf-containing film 4c are used to form the Hf-containing insulating film 6 of the p-channel-type MISFET Qp, and these are formed in the order of the Hf-containing film 4a, the Al-containing film 21, and the Hf-containing film 4c.

For example, when only two layers, that is, the Hf-containing film 4a and the Al-containing film 21 are used to form an Hf-based gate insulating film of the p-channel-type MISFET Qp unlike the present embodiment, a process of selectively removing the Hf-containing film 4c in the pMIS formation region 1B is required after the Hf-containing film 4c is formed in step 7a, which increases the number of processes for manufacturing the semiconductor device.

In the present embodiment, among the Hf-containing film 4a, the rare-earth-containing film 4b, and the Hf-containing film 4c used to form the Hf-containing insulating film 5 of the n-channel-type MISFET Qn, the Hf-containing film 4a and the Hf-containing film 4c are not removed in the pMIS formation region 1B but are used also for forming the Hf-containing insulating film 6. Therefore, the number of processes for manufacturing a CMISFET can be decreased.

Therefore, in the present embodiment, in a semiconductor device having a CMISFET, as described in the first embodiment described above, the characteristics (performance) of the n-channel-type MISFET can be improved. In addition, since the Hf-containing insulating film 6 is formed by using three layers, that is, the Hf-containing film 4a, the Al-containing film 21, and the Hf-containing film 4c in accordance with the use of the three layers, that is, the Hf-containing film 4a, the rare-earth-containing film 4b, and the Hf-containing film 4c to form the Hf-containing insulating film 5, the thresholds of both of the p-channel-type MISFET and the n-channel-type MISFET can be decreased, and the number of processes for manufacturing the CMISFET can be decreased.

Also, in the present embodiment, in the nMIS formation region 1A, the Hf-containing film 4a, the rare-earth-containing film 4b, and the Hf-containing film 4c are formed sequentially from below, and they react with one another to form the Hf-containing insulating film 5. Also, in the pMIS formation region 1B, the Hf-containing film 4a, the Al-containing film 21, and the Hf-containing film 4c are formed sequentially from below, and they react with one another to form the Hf-containing insulating film 6. For this reason, the concentration distributions of the rare-earth element and Hf in the thickness direction of the Hf-containing insulating film 5 are inevitably as shown in FIG. 26 described above, and the concentration distributions of Al and Hf in the thickness direction of the Hf-containing insulating film 6 are as shown in FIG. 50 described below. This is described in the following.

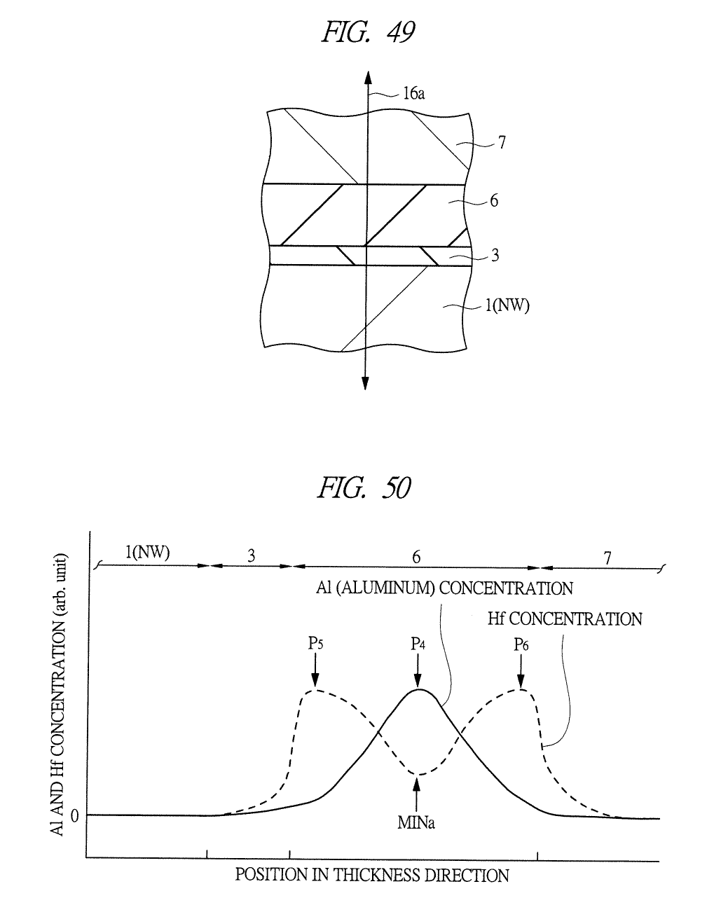

FIG. 49 is an explanatory diagram of the p-channel-type MISFET Qp of the pMIS formation region 1B in the semiconductor device of the present embodiment, and it shows a partially-enlarged sectional view of a region near the gate insulating film. FIG. 50 is a graph showing an Al concentration distribution and an Hf concentration distribution in the thickness direction, and the Al concentration distribution and the Hf concentration distribution at a position along a line 16a of FIG. 49 correspond to FIG. 50. Therefore, the horizontal axis of the graph of FIG. 50 corresponds to positions along the line 16a in FIG. 49, and the vertical axis of the graph of FIG. 50 corresponds to Al concentration and Hf concentration. In FIG. 50, the Al concentration distribution is represented by a solid line, and the Hf concentration distribution is represented by a dotted line. Note that the Al concentration distribution and the Hf concentration distribution on the vertical axis of the graph of FIG. 50 are represented with an arbitrary unit. The direction of the line 16a in FIG. 49 is a thickness direction (that is, direction perpendicular to the main surface of the semiconductor substrate 1).

The Al-containing film 21 contains Al (aluminum), but the Hf-containing films 4a and 4c do not contain any of a rare-earth element and Al (aluminum). Also, the Hf-containing films 4a and 4c contain Hf (hafnium), but the Al-containing film 21 does not contain Hf (hafnium). It is difficult to completely mix the Hf-containing film 4a and the Al-containing film 21 together when the Hf-containing film 4e is formed, and it is difficult to completely mix the Hf-containing film 4e and the Hf-containing film 4c together when the Hf-containing insulating film 6 is formed. Therefore, the concentration distribution of each element in a thickness direction in the actually-formed Hf-containing insulating film 6 is not uniform, and the distribution is nonuniform with the composition distribution of the Hf-containing film 4a, the Al-containing film 21, and the Hf-containing film 4c before the reaction being maintained to some degree.

The structure and manufacturing method of the n-channel-type MISFET Qn in the nMIS formation region 1A in the semiconductor device of the present embodiment are basically the same as those of the first embodiment described above. Therefore, when the concentration distributions of the rare-earth element and Hf along the line 16 in FIG. 23 described above are plotted on a graph with respect to the n-channel-type MISFET Qn in the nMIS formation region 1A, the graph is similar to the graph of FIG. 26 described above. On the other hand, with respect to the p-channel-type MISFET Qp in the pMIS formation region 1B in the semiconductor device of the present embodiment, if the rare-earth-containing film 4b is replaced by the Al-containing film 21, the layer structure from the interface layer 3 to the metal film 7 and the manufacturing method thereof are basically the same as those of the n-channel-type MISFET Qn in the nMIS formation region 1A. For this reason, the Al concentration distribution in the thickness direction of the insulating film 6 shown in FIG. 50 is similar to the rare-earth concentration distribution in the thickness direction of the insulating film 5 shown in FIG. 26 described above, and the Hf concentration distribution in the thickness direction of the insulating film 6 shown in FIG. 50 is similar to the Hf concentration distribution in the thickness direction of the insulating film 5 shown in FIG. 26 described above.

Therefore, as shown in FIG. 50, the Al concentration distribution in the thickness direction of the Hf-containing insulating film 6 is not uniform (constant), and has a peak (maximum value) P₄ in a center region in the thickness direction of the Hf-containing insulating film 6. More specifically, in the concentration distribution of Al (aluminum) in the thickness direction of the Hf-containing insulating film (second gate insulating film) 6, the concentration of Al (aluminum) near a lower surface and an upper surface of the Hf-containing insulating film 6 is lower than that in a center region of the Hf-containing insulating film 6. The reason why Al has the concentration distribution like this is basically the same as the reason for the fact that the rare-earth concentration distribution in the thickness direction of the Hf-containing insulating film 5 has the peak P₁ in the center region in the thickness direction of the Hf-containing insulating film 5 as described in the first embodiment if considered with the rare-earth element (rare-earth-containing film 4b) being replaced by Al (Al-containing film 21).

More specifically, in the Hf-containing insulating film 6, the Al concentration is low in the regions that were originally the Hf-containing films 4a and 4c (lower layer portion and upper layer portion of the Hf-containing insulating film 6), compared with a region that was originally the Al-containing film 21 (intermediate layer portion of the Hf-containing insulating film 6). For this reason, in the Hf-containing insulating film 6, the peak P₄ described above is formed in the region that was originally the Al-containing film 21 (intermediate layer portion of the Hf-containing insulating film 6), and more specifically, the peak P₄ described above is formed near the center portion in the thickness direction of the region that was originally the Al-containing film 21 (intermediate layer portion of the Hf-containing insulating film 6). Also, on the semiconductor substrate 1 side and the gate electrode GE2 side from this peak P₄, the Al concentration is in the state of being gradually decreased. More specifically, the Al concentration distribution in the thickness direction of the Hf-containing insulating film 6 is a distribution with one mountain, and has the peak P₄ in the center region in the thickness direction of the Hf-containing insulating film 6 where the Al concentration becomes maximum. The Al concentration is monotonously decreased from the position of the peak P₄ (center region in the thickness direction) toward the semiconductor substrate 1 side, and the Al concentration is monotonously decreased from the position of the peak P₄ (center region in the thickness direction) toward the metal film 7 side.

Therefore, the concentration distribution of Al in the thickness direction of the Hf-containing insulating film 6 has the peak P₄ in the center region in the thickness direction of the Hf-containing insulating film 6, and the concentration of Al (aluminum) on the lower surface of the Hf-containing insulating film 6 (that is, interface between the Hf-containing insulating film 6 and the interface layer 3) and its vicinity and on the upper surface of the Hf-containing insulating film 6 (that is, interface between the Hf-containing insulating film 6 and the metal film 7) and its vicinity is lower than that in the center region (peak P₄ described above) in the thickness direction of the Hf-containing insulating film 6.

Also, as shown in FIG. 50, the Hf concentration distribution in the thickness direction of the Hf-containing insulating film 6 is not uniform (constant), but has double peaks (peak P₅ and peak P₆) in the thickness direction of the Hf-containing insulating film 6. In the Hf-containing insulating film 6, the peak P₅ which is one of the double peaks is formed in a region in the Hf-containing insulating film 6 that was originally the Hf-containing film 4a (lower layer portion of the Hf-containing insulating film 6), and the peak P₆ which is the other of the double peaks is formed in a region in the Hf-containing insulating film 6 that was originally the Hf-containing film 4c (upper layer portion of the Hf-containing insulating film 6). The reason why the Hf concentration distribution in the thickness direction of the Hf-containing insulating film 6 has double peaks is basically the same as the reason why the Hf concentration distribution in the thickness direction of the Hf-containing insulating film 5 has double peaks. Also, on the semiconductor substrate 1 side and the gate electrode GE2 side from this peak P₅, the Hf concentration is gradually or rapidly decreased. Also, the Hf concentration takes a minimum value MINa at a position between the peak P₅ and the peak P₆ (position in the thickness direction), and the Hf concentration is in the state of being gradually decreased from the peak P₅ to this minimum value MINa and from the peak P₆ to this minimum value MINa.

More specifically, the Hf concentration distribution in the thickness direction of the Hf-containing insulating film 6 is a distribution with two mountains, and has double peaks (P₅ and P₆). The Hf concentration is monotonously decreased from the position of the peak P₅ toward the semiconductor substrate 1 side, the Hf concentration is monotonously decreased from the position of the peak P₅ toward the minimum value MINa, the Hf concentration is monotonously decreased from the position of the peak P₆ toward the minimum value MINa, and the Hf concentration is monotonously decreased from the position of the peak P₆ toward the metal film 7 side.

Also, in the Hf-containing insulating film 6, the peak P₄ described above is formed in the region that was originally the Al-containing film 21 (intermediate layer portion of the Hf-containing insulating film 6), the peak P₅ described above is formed in the region that was originally the Hf-containing film 4a (lower layer portion of the Hf-containing insulating film 6), and the peak P₆ described above is formed in the region that was originally the Hf-containing film 4c (upper layer portion of the Hf-containing insulating film 6). For this reason, as shown in FIG. 50, the peak P₄ described above is positioned between the position of the peak P₅ described above and the position of the peak P₆ described above in the thickness direction of the Hf-containing insulating film 6. More specifically, the concentration distribution of Al (aluminum) in the thickness direction of the Hf-containing insulating film 6 has the peak P₄ at a position between the double peaks (that is, between the position of the peak P₅ and the position of the peak P₆) of the concentration distribution of Hf (hafnium) in the thickness direction of the Hf-containing insulating film 6. Also, in the thickness direction of the Hf-containing insulating film 6, the Hf concentration distribution has the minimum value MINa described above at or near the position where the Al concentration distribution has the peak P₄ described above.

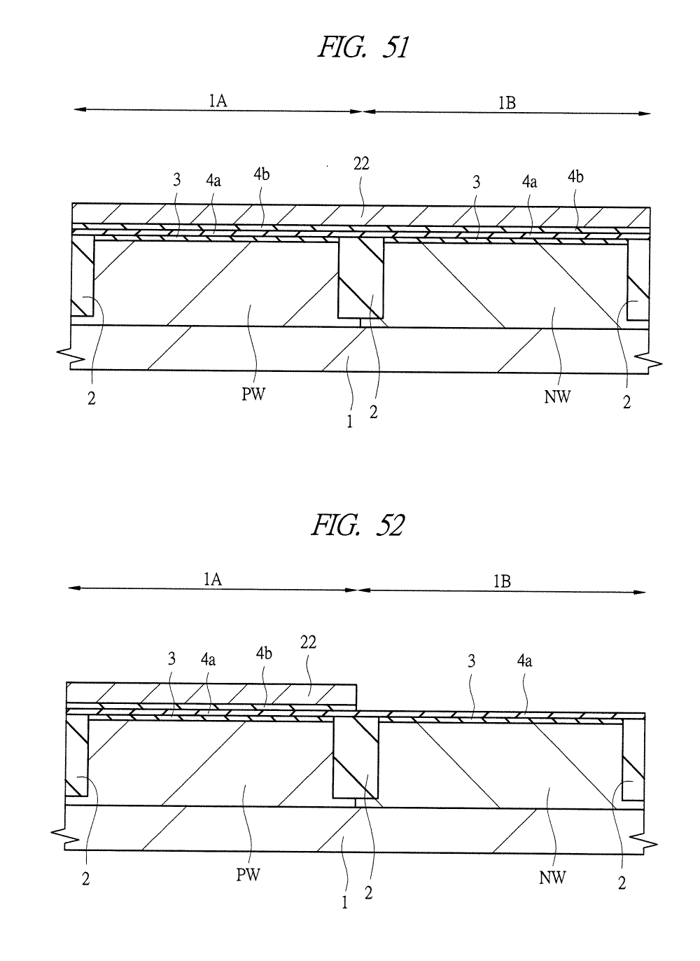

Furthermore, in the present embodiment, the manufacturing process in the case where the reaction-prevention mask layer 22 is provided in the pMIS formation region 1B to prevent the reaction between the Hf-containing film 4a and the rare-earth-containing film 4b in the pMIS formation region 1B (manufacturing process described with reference to FIG. 34 to FIG. 48) has been described. In another embodiment (modification example), the reaction-prevention mask layer 22 can be provided in the nMIS formation region 1A to prevent the reaction between the Hf-containing film 4a and the Al-containing film 21 in the nMIS formation region 1A, and a manufacturing process in that case is described with reference to FIG. 51 to FIG. 55. Note that differences from the manufacturing process described with reference to FIG. 34 to FIG. 48 are mainly described. FIG. 51 and FIG. 52 are sectional views of main parts of the semiconductor device of the present embodiment in another manufacturing process.

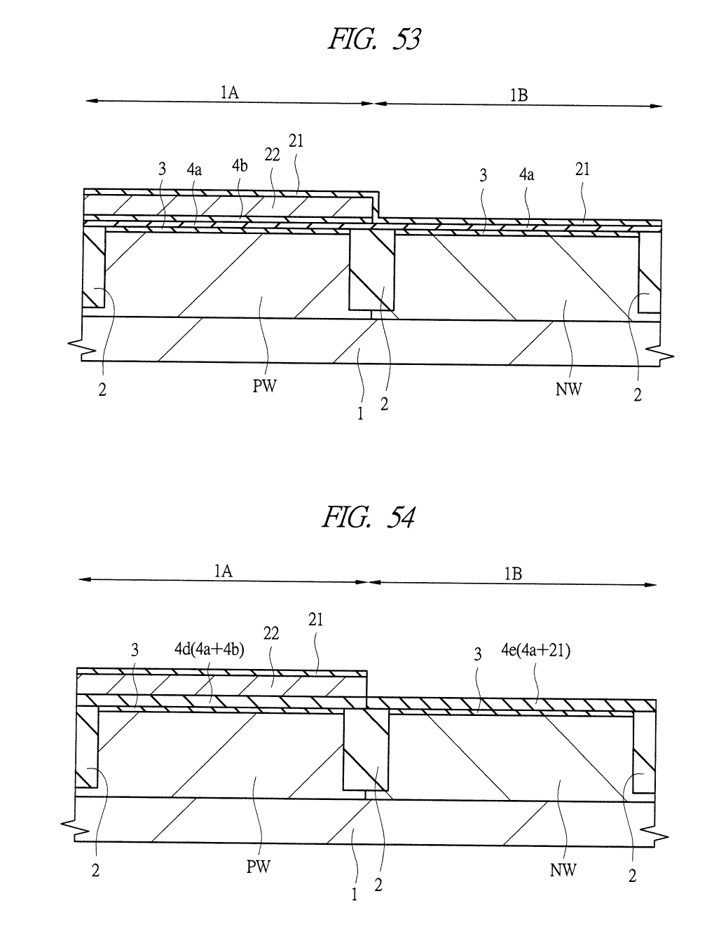

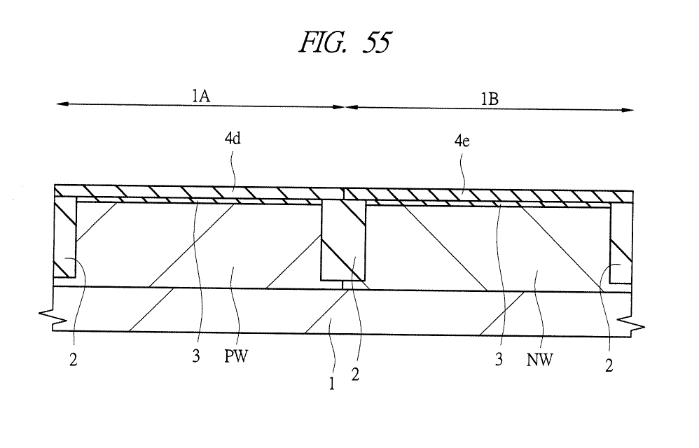

After the processes up to the process of forming the Hf-containing film 4a in step S5 of the process flow of FIG. 33 described above are performed, the rare-earth-containing film 4b is formed in place of the Al-containing film 21 on the Hf-containing film 4a in step S31 described above (refer to FIG. 51), and the reaction-prevention mask layer 22 is formed on this rare-earth-containing film 4b in step S32 described above (refer to FIG. 51). Then, in step S33 described above, portions of the reaction-prevention mask layer 22 and the rare-earth-containing film 4b in the pMIS formation region 1B are removed and portions of the reaction-prevention mask layer 22 and the rare-earth-containing film 4b in the nMIS formation region 1A are left (refer to FIG. 52). Then, in step S6a described above, the Al-containing film 21 is formed in place of the rare-earth-containing film 4b. More specifically, the Al-containing film 21 is formed on the reaction-prevention mask layer 22 in the nMIS formation region 1A and the Hf-containing film 4a in the pMIS formation region 1B (refer to FIG. 53). At this stage, in the nMIS formation region 1A, the interface layer 3, the Hf-containing film 4a, the rare-earth-containing film 4b, the reaction-prevention mask layer 22, and the Al-containing film 21 are stacked sequentially from below on the p-type well PW, and in the pMIS formation region 1B, the interface layer 3, the Hf-containing film 4a, and the Al-containing film 21 are stacked sequentially from below on the n-type well NW. Then, by the heat treatment in step S34 described above, the Hf-containing film 4a and the rare-earth-containing film 4b in the nMIS formation region 1A react (mix, mixing, interdiffuse) with each other to form the Hf-containing film 4d, which is a reaction layer of both films, and the Hf-containing film 4a and the Al-containing film 21 in the pMIS formation region 1B react (mix, mixing, interdiffuse) with each other to form the Hf-containing film 4e, which is a reaction layer of both films (refer to FIG. 54). At this time, the reaction-prevention mask layer 22 is interposed between the Al-containing film 21 and the rare-earth-containing film 4b (and the Hf-containing film 4a) in the nMIS formation region 1A, and it functions to prevent the reaction of the Al-containing film 21 in the nMIS formation region 1A with the rare-earth-containing film 4b and the Hf-containing film 4a. Thereafter, in step S35 described above, an unreacted portion of the Al-containing film 21 on the reaction-prevention mask layer 22 is removed, and further the reaction-prevention mask layer 22 is removed (refer to FIG. 55). Through the processes so far, the structure similar to that of FIG. 39 described above can be obtained. As the subsequent processes, the processes described with reference to FIG. 40 to FIG. 48 (process of forming the Hf-containing film 4c in step 7a described above and subsequent processes) can be performed. The structure of the semiconductor device thus manufactured is similar to that of FIG. 32 described above.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention is effectively applied to a semiconductor device and its manufacturing technology.

### DESCRIPTION OF REFERENCE SIGNS

1: semiconductor substrate
1A: nMIS formation region
1B: pMIS formation region
2: isolation region
3: interface layer
4a, 4c: Hf-containing film
4b: rare-earth-containing film
5, 6: Hf-containing insulating film (high dielectric constant gate insulating film)
7: metal film
8: silicon film
10: metal silicide film
11: insulating film
12: stopper insulating film
13: insulating film
14: wiring trench
21: Al-containing film
22: reaction-prevention mask layer
CNT: contact hole
EX1: n⁻-type semiconductor region
EX2: p⁻-type semiconductor region
GE1, GE2: gate electrode (metal gate electrode)
M1: wiring
MIN, MINa: minimum value
NW: n-type well
P₁, P₂, P₃, P₄, P₅, P₆: peak
PG: plug
PR1, PR1a: photoresist pattern
PW: p-type well
Qn: n-channel-type MISFET
Qp: p-channel-type MISFET
SD1: n⁺-type semiconductor region
SD2: p⁺-type semiconductor region
SW: sidewall

1. A semiconductor device including an n-channel-type first MISFET comprising:
a semiconductor substrate;
a first gate insulating film of the first MISFET formed on the semiconductor substrate; and
a first metal gate electrode of the first MISFET formed on the first gate insulating film,
wherein the first gate insulating film contains hafnium, a rare-earth element, and oxygen as main components, and
in a concentration distribution of the rare-earth element in a thickness direction of the first gate insulating film, a concentration of the rare-earth element near a lower surface and near an upper surface of the first gate insulating film is lower than a concentration in a center region of the first gate insulating film.

2. The semiconductor device according to claim 1,
wherein the concentration distribution of the rare-earth element in the thickness direction of the first gate insulating film has a peak in the center region in the thickness direction of the first gate insulating film.

3. The semiconductor device according to claim 2,
wherein a concentration distribution of the hafnium in the thickness direction of the first gate insulating film has double peaks, and
the concentration distribution of the rare-earth element in the thickness direction of the first gate insulating film has a peak between the double peaks of the concentration distribution of the hafnium in the thickness direction of the first gate insulating film.

4. The semiconductor device according to claim 3, further comprising semiconductor regions for a source and a drain of the first MISFET, the semiconductor regions being formed in the semiconductor substrate.

5. The semiconductor device according to claim 4,
wherein the rare-earth element contained in the first gate insulating film is lanthanum.

6. The semiconductor device according to claim 5, further comprising an interface layer made of silicon oxide or silicon oxynitride formed at an interface between the first gate insulating film and the semiconductor substrate.

7. The semiconductor device according to claim 6, further comprising:
a p-channel-type second MISFET;
a second gate insulating film of the second MISFET formed on the semiconductor substrate; and
a second metal gate electrode of the second MISFET formed on the second gate insulating film,
wherein the second gate insulating film contains hafnium, aluminum, and oxygen as main components, and
in a concentration distribution of the aluminum in a thickness direction of the second gate insulating film, a concentration of the aluminum near a lower surface and near an upper surface of the second gate insulating film is lower than a concentration in a center region of the second gate insulating film.

8. The semiconductor device according to claim 7,
wherein a concentration distribution of the hafnium in the thickness direction of the second gate insulating film has double peaks, and
the concentration distribution of the aluminum in the thickness direction of the second gate insulating film has a peak between the double peaks of the concentration distribution of the hafnium in the thickness direction of the second gate insulating film.

9. A method of manufacturing a semiconductor device including an n-channel-type MISFET having a gate insulating film containing hafnium, a rare-earth element, and oxygen as main components and a metal gate electrode, the method comprising:
(a) a step of preparing a semiconductor substrate;
(b) a step of forming on the semiconductor substrate a first Hf-containing film for forming the gate insulating film, the first Hf-containing film containing hafnium and oxygen as main components;
(c) a step of forming on the first Hf-containing film a rare-earth-containing film for forming the gate insulating film, the rare-earth-containing film containing a rare-earth element as a main component;
(d) a step of forming on the rare-earth-containing film a second Hf-containing film for forming the gate insulating film, the second Hf-containing film containing hafnium and oxygen as main components;
(e) a step of forming on the second Hf-containing film a metal film; and
(f) after the step (e), a step of forming the metal gate electrode by patterning the metal film.

10. The method of manufacturing the semiconductor device according to claim 9, further comprising,
after the step (e) and before the step (f),
(e1) a step of forming a silicon film on the metal film,
wherein, in the step (f), the metal gate electrode is formed by patterning the silicon film and the metal film.

11. The method of manufacturing the semiconductor device according to claim 10, further comprising:
after the step (f),
(g) a step of performing ion implantation for forming source and drain regions of the MISFET to the semiconductor substrate; and
(h) after the step (g), a step of performing a first heat treatment for activating impurities introduced in the ion implantation in the step (g).

12. The method of manufacturing the semiconductor device according to claim 11,
wherein the rare-earth-containing film formed in the step (c) is a rare-earth oxide film.

13. The method of manufacturing the semiconductor device according to claim 12,
wherein the rare-earth-containing film formed in the step (c) is a lanthanum oxide film.

14. The method of manufacturing the semiconductor device according to claim 13,
wherein the first Hf-containing film formed in the step (b) is an HfO film, an HfON film, an HfSiO film, or an HfSiON film, and
the second Hf-containing film formed in the step (d) is an HfO film, an HfON film, an HfSiO film, or an HfSiON film.

15. The method of manufacturing the semiconductor device according to claim 14, further comprising,
before the step (b),
(b1) a step of forming on the semiconductor substrate a third insulating film made of silicon oxide or silicon oxynitride,
wherein in the step (b), the first Hf-containing film is formed on the third insulating film.

16. The method of manufacturing the semiconductor device according to claim 15,
wherein by the first heat treatment in the step (h), the first Hf-containing film, the rare-earth-containing film, and the second Hf-containing film react with one another to form the gate insulating film.

17. The method of manufacturing the semiconductor device according to claim 16,
wherein the second Hf-containing film formed in the step (d) is thicker than the first Hf-containing film formed in the step (b).

18. The method of manufacturing the semiconductor device according to claim 11, further comprising,
after the step (c) and before the step (d),
(c1) a step of performing a second heat treatment to cause the first Hf-containing film and the rare-earth-containing film to react with each other,
wherein in the step (d), the second Hf-containing film is formed on a reaction layer of the first Hf-containing film and the rare-earth containing film, and
by the first heat treatment in the step (h), the reaction layer and the second Hf-containing film react with each other to form the gate insulating film.

19. A method of manufacturing a semiconductor device including an n-channel-type MISFET in a first region of a semiconductor substrate and a p-channel-type MISFET in a second region of the semiconductor substrate, the n-channel-type MISFET having a first gate insulating film containing hafnium, a rare-earth element, and oxygen as main components and a first metal gate electrode, and the p-channel-type MISFET having a second gate insulating film containing hafnium, aluminum, and oxygen as main components and a second metal gate electrode, the method comprising:
(a) a step of preparing a semiconductor substrate;
(b) a step of forming in the first region and the second region on the semiconductor substrate a first Hf-containing film for forming the first and second gate insulating films, the first Hf-containing film containing hafnium and oxygen as main components;
(c) a step of forming on the first Hf-containing film formed in the first region and the second region an Al-containing film for forming the second gate insulating film, the Al-containing film containing aluminum as a main component;
(d) a step of forming a mask layer on the Al-containing film formed in the first region and the second region;
(e) after the step (d), a step of removing the mask layer and the Al-containing film in the first region and leaving the mask layer and the Al-containing film in the second region;
(f) after the step (e), a step of forming a rare-earth-containing film for forming the first gate insulating film on the first Hf-containing film in the first region and on the mask layer in the second region, the rare-earth-containing film containing a rare-earth element as a main component;
(g) after the step (f), a step of removing the rare-earth-containing film on the mask layer and the mask layer in the second region;
(h) after the step (g), a step of forming a second Hf-containing film for forming the first and second gate insulating films on the rare-earth-containing film in the first region and on the Al-containing film in the second region, the second Hf-containing film containing hafnium and oxygen as main components;
(i) after the step (h), a step of forming a metal film on the second Hf-containing film in the first region and the second region; and
(j) after the step (i), a step of patterning the metal film to form the first metal gate electrode in the first region and the second metal gate electrode in the second region.

20. The method of manufacturing the semiconductor device according to claim 19, further comprising,
after the step (f) and before the step (g),
(f1) a step of performing a heat treatment to cause the first Hf-containing film and the rare-earth-containing film in the first region to react with each other and cause the first Hf-containing film and the Al-containing film in the second region to react with each other,
wherein in the step (h), the second Hf-containing film in the first region is formed on a reaction layer of the first Hf-containing film and the rare-earth-containing film, and the second Hf-containing film in the second region is formed on a reaction layer of the first Hf-containing film and the Al-containing film.

21. The method of manufacturing the semiconductor device according to claim 20, further comprising:
after the step (j),
(k) a step of performing ion implantation for forming source and drain regions of the re-channel-type MISFET to the semiconductor substrate in the first region and performing ion implantation for forming source and drain regions of the p-channel-type MISFET to the semiconductor substrate in the second region; and
(l) after the step (k), a step of performing a heat treatment for activating impurities introduced in the ion implantations in the step (k).

22. The method of manufacturing the semiconductor device according to claim 21,
wherein the first Hf-containing film formed in the step (b) is an HfO film, an HfON film, an HfSiO film, or an HfSiON film,
the Al-containing film formed in the step (c) is an aluminum oxide film, an aluminum oxynitride film, or an aluminum film,
the rare-earth-containing film formed in the step (f) is a rare-earth oxide film, and
the second Hf-containing film formed in the step (h) is an HfO film, an HfON film, an HfSiO film, or an HfSiON film.

23. The method of manufacturing the semiconductor device according to claim 22,
wherein the rare-earth-containing film formed in the step (f) is a lanthanum oxide film.

24. The method of manufacturing the semiconductor device according to claim 23,
wherein the mask layer formed in the step (d) is a metal nitride film or a metal carbide film.
